(19) United States
(12) Patent Application Publication
(10) Pub. No.: US 2026/0202963 A1
(43) Pub. Date: Jul. 16, 2026

(54) Compaction-Derived Telemetry, Analytics, and Control in Anonymized Encoding Systems

(71) Applicant: AtomBeam Technologies Inc., Moraga, CA (US)

(72) Inventors: Joshua Cooper, Columbia, SC (US); Charles Yeomans, Orinda, CA (US)

(21) Appl. No.: 19/546,616

(22) Filed: Feb. 23, 2026

Related U.S. Application Data
(63) Continuation-in-part of application No. 19/422,108, filed on Dec. 16, 2025.
Application No. 19/422,108 is a continuation of application No. 18/737,962, filed on Jun. 8, 2024, now Pat. No. 12,498,853.
Application No. 18/737,962 is a continuation-in-part of application No. 18/469,520, filed on Sep. 18, 2023, now Pat. No. 12,079,474.
Application No. 18/469,520 is a continuation of application No. 18/178,556, filed on Mar. 6, 2023, now Pat. No. 11,762,557.
Application No. 18/178,556 is a continuation-in-part of application No. 17/727,913, filed on Apr. 25, 2022, now Pat. No. 11,620,051.
Application No. 17/727,913 is a continuation of application No. 17/404,699, filed on Aug. 17, 2021, now Pat. No. 11,385,794.
(60) Provisional application No. 63/332,525, filed on Apr. 19, 2022.

(51) Int. Cl. G06F 3/06; H03M 7/30

(52) U.S. Cl. CPC G06F 3/0608; G06F 3/0623; G06F 3/0659; G06F 3/067; H03M 7/6005; H03M 7/6011

(57) ABSTRACT

Systems and methods for compaction-derived telemetry generation and analysis that transform anonymized encoding operations from passive data processing mechanisms into active sources of privacy-preserving analytical signals, enabling detection of encryption attempts, data exfiltration, dataset evolution, and other operationally significant conditions while maintaining full compliance with data protection requirements and preserving the integrity of anonymization guarantees. The compaction-derived telemetry generation and analysis systems and methods disclosed herein enable interpretation of telemetry signals to infer dataset evolution, security-relevant conditions, and anomalous behaviors, and the use of such interpretations to drive closed-loop control actions, all without reconstructing, inspecting, or accessing underlying plaintext data, thereby preserving privacy and regulatory compliance while enabling novel analytic and security capabilities.

### CROSS-REFERENCE TO RELATED APPLICATIONS

Priority is claimed in the application data sheet to the following patents or patent applications, each of which is expressly incorporated herein by reference in its entirety:
19/422,108
18/737,962
18/469,520
18/178,556
17/727,913
17/404,699
63/332,525

### BACKGROUND OF THE INVENTION

### Field of the Invention

The present invention is in the field of computer data encoding, and in particular the generation and analysis of anonymized encoded datasets.

### Discussion of the State of the Art

As computers have become integral to modern life, particularly over the past fifteen years, data storage has emerged as a critical limiting factor on a global scale. Prior to approximately 2010, the growth in physical storage capacity consistently outpaced increases in storage demand, leading many to believe that storage constraints were a problem of the past. However, beginning around 2010, the explosive growth of social media platforms, cloud data centers, and data-intensive industries such as biotechnology and advanced manufacturing drove digital data creation to unprecedented levels. Global data storage demand reached the zettabyte scale, representing one trillion gigabytes, and projections indicate demand will exceed fifty zettabytes in the coming years. In stark contrast, global manufacturing capacity for physical storage devices has struggled to keep pace, producing roughly one zettabyte of new capacity annually as of recent years. The rate at which data is being generated has fundamentally outstripped our ability to manufacture sufficient storage infrastructure to contain it.

The conventional approaches to addressing storage limitations have proven inadequate. Expanding physical storage capacity through increased manufacturing simply cannot bridge the widening gap between supply and demand, as production has already fallen behind consumption. Data compression technologies, which have long been employed to reduce storage requirements, also face fundamental limitations. Traditional lossless compression algorithms typically achieve compression ratios of approximately two to one for mixed data types, effectively doubling available storage capacity. However, as the composition of global data shifts increasingly toward multimedia content such as audio, video, and images, the effectiveness of lossless compression diminishes substantially. Lossy compression techniques can achieve higher compression ratios but necessarily degrade data quality by selectively discarding information, making them unsuitable for applications requiring data integrity. Even under optimistic assumptions, conventional compression cannot resolve the underlying mismatch between data generation and storage availability, and these techniques exhibit widely varying performance depending on the nature of the input data.

Beyond storage constraints, transmission bandwidth has emerged as an equally critical bottleneck in modern computing infrastructure. Large datasets demand substantial network bandwidth for transfer between data centers, while the proliferation of billions of low-bandwidth devices connecting to global networks places additional strain on transmission infrastructure. These bandwidth limitations impose significant constraints on the development and deployment of networked computing applications, including distributed systems and emerging paradigms such as the Internet of Things. The ability to efficiently encode and transmit data has become as important as the ability to store it, yet existing compression and encoding methods were not designed to address the simultaneous demands of storage efficiency and transmission performance across diverse data types.

The advancing threat of quantum computing has introduced additional concerns regarding data security for both stored data and data in transit across networks. Existing encryption technologies, which form the foundation of contemporary cybersecurity infrastructure, face potential vulnerability as quantum computing capabilities mature. The prospect of quantum-enabled cryptanalysis has created urgent demand for encoding and encryption approaches that can maintain data confidentiality in a post-quantum environment. Simultaneously, the need to monitor and detect security threats such as data exfiltration, unauthorized encryption, and covert communication channels has grown more acute, yet traditional monitoring techniques often require direct inspection of data content, creating tensions between security requirements and privacy protection.

As data collection has become ubiquitous, the imperative to protect personal and sensitive information has intensified correspondingly. Privacy regulations such as the California Consumer Privacy Act and the European Union General Data Protection Regulation impose strict requirements on data handling practices and emphasize individual data privacy rights. To comply with these regulations and facilitate responsible data sharing, organizations frequently anonymize datasets prior to use in analytics, machine learning applications, or third-party transfers. However, conventional anonymization techniques often eliminate the very signals and patterns that would enable meaningful operational monitoring, performance optimization, and security analysis. The challenge of extracting actionable insights from data processing operations without compromising anonymization guarantees or reconstructing underlying sensitive information remains largely unresolved in existing systems.

What is needed is a system and method that addresses these converging challenges by enabling efficient data compaction and secure encoding of anonymized datasets while simultaneously generating operational telemetry that can be analyzed for security monitoring, performance optimization, and adaptive system control without requiring access to or reconstruction of the underlying data content. The present disclosure provides a solution in the form of compaction-derived telemetry that transforms anonymized encoding operations from passive data processing mechanisms into active sources of privacy-preserving analytical signals, enabling detection of encryption attempts, data exfiltration, dataset evolution, and other operationally significant conditions while maintaining full compliance with data protection requirements and preserving the integrity of anonymization guarantees.

### SUMMARY OF THE INVENTION

The inventor has conceived, and reduced to practice, systems and methods for compaction-derived telemetry generation and analysis that transform anonymized encoding operations from passive data processing mechanisms into active sources of privacy-preserving analytical signals, enabling detection of encryption attempts, data exfiltration, dataset evolution, and other operationally significant conditions while maintaining full compliance with data protection requirements and preserving the integrity of anonymization guarantees. The compaction-derived telemetry generation and analysis systems and methods disclosed herein enable interpretation of telemetry signals to infer dataset evolution, security-relevant conditions, and anomalous behaviors, and the use of such interpretations to drive closed-loop control actions, all without reconstructing, inspecting, or accessing underlying plaintext data, thereby preserving privacy and regulatory compliance while enabling novel analytic and security capabilities.

According to a preferred embodiment, a computer system is disclosed configured to execute software instructions stored on nontransitory machine-readable storage media, wherein the software instructions comprise instructions that cause the computer system to: receive one or more sourcepackets for encoding; encode the one or more sourcepackets using a codebook; for each sourcepacket encoded: generate compaction telemetry during the encoding, the compaction telemetry comprising one or more metrics selected from a group consisting of: compaction ratio, sourceblock length used, encoding time, codebook identifier, and compaction failure count; and construct a compaction telemetry vector comprising the generated compaction telemetry associated with a timestamp, wherein the compaction telemetry vector does not include reconstructive information about underlying data content; and store or transmit the compaction telemetry vector or vectors for analysis.

According to another preferred embodiment, a computer-implemented method is disclosed comprising the steps of: receiving one or more sourcepackets for encoding; encoding the one or more sourcepackets using a codebook; for each sourcepacket encoded: generating compaction telemetry during the encoding, the compaction telemetry comprising one or more metrics selected from a group consisting of: compaction ratio, sourceblock length used, encoding time, codebook identifier, and compaction failure count; and constructing a compaction telemetry vector comprising the generated compaction telemetry associated with a timestamp, wherein the compaction telemetry vector does not include reconstructive information about underlying data content; and storing or transmitting the compaction telemetry vector or vectors for analysis.

According to an aspect of an embodiment, the computer system further comprises software instructions that cause the computer system to perform telemetry analysis by analyzing the compaction telemetry vector or vectors to detect anomalies in compaction behavior.

According to an aspect of an embodiment, the computer system further comprises software instructions that cause the computer system to: identify conditions from the telemetry analysis requiring an automated response; compare the identified conditions against trigger conditions defined by a policy engine; initiate control actions when trigger conditions are met, the control actions including one or more of: adjusting sourceblock lengths, modifying codebook selection, changing encoding parameters, and generating security alerts; modify encoding parameters based on executed control actions; and observe subsequent compaction telemetry using a feedback monitor to assess effectiveness of the control actions, wherein the feedback monitor confirms resolution of detected conditions or escalates responses if anomalies persist.

According to an aspect of an embodiment, the control actions include automated security responses selected from a group consisting of: rate limiting data flows associated with an endpoint exhibiting anomalous compaction behavior, isolating affected endpoints, enforcing stricter encoding policies, and dynamic key rotation.

According to an aspect of an embodiment, the parameter adjustment subsystem adaptively modifies encoding behavior by dynamically adjusting one or more of: selected sourceblock lengths, choice of codebooks, frequency of codebook updates, and sampling rates for telemetry generation.

According to an aspect of an embodiment, the computer system further comprises software instructions that cause the computer system to: establish a baseline compaction profile representing expected compaction behavior from the telemetry analysis; and detect deviations from the baseline compaction profile by comparing observed compaction telemetry vectors against the baseline compaction profile.

According to an aspect of an embodiment, the computer system further comprises software instructions that cause the computer system to perform threat classification by: classifying detected deviations from the baseline compaction profile as security-relevant conditions using a threat classifier; and generating an alert using an alert generator when a security-relevant condition is classified, wherein the security-relevant condition is detected without reconstructing or inspecting underlying data content.

According to an aspect of an embodiment, the security-relevant conditions include detection of encrypted data based on sustained increases in compaction failure count, wherein encrypted data exhibits high entropy and fails to compact at normal rates.

According to an aspect of an embodiment, the security-relevant conditions include detection of steganography or covert channels based on identification of repeated anomalous compaction patterns aligned with message boundaries.

According to an aspect of an embodiment, the security-relevant conditions include detection of data exfiltration based on sudden increases in compaction failure localized to specific endpoints or sustained telemetry anomalies consistent with outbound-only data flow.

According to an aspect of an embodiment, the method further comprises the step of performing telemetry analysis by analyzing the compaction telemetry vector or vectors to detect anomalies in compaction behavior.

According to an aspect of an embodiment, the method further comprises the steps of: identifying conditions from the telemetry analysis requiring an automated response; comparing the identified conditions against trigger conditions defined by a policy engine; initiating control actions when trigger conditions are met, the control actions including one or more of: adjusting sourceblock lengths, modifying codebook selection, changing encoding parameters, and generating security alerts; modifying encoding parameters based on executed control actions; and observing subsequent compaction telemetry using a feedback monitor to assess effectiveness of the control actions, wherein the feedback monitor confirms resolution of detected conditions or escalates responses if anomalies persist.

According to an aspect of an embodiment, the control actions include automated security responses selected from a group consisting of: rate limiting data flows associated with an endpoint exhibiting anomalous compaction behavior, isolating affected endpoints, enforcing stricter encoding policies, and dynamic key rotation.

According to an aspect of an embodiment, the parameter adjustment subsystem adaptively modifies encoding behavior by dynamically adjusting one or more of: selected sourceblock lengths, choice of codebooks, frequency of codebook updates, and sampling rates for telemetry generation.

According to an aspect of an embodiment, the method further comprises the steps of: establishing a baseline compaction profile representing expected compaction behavior from the telemetry analysis; and detecting deviations from the baseline compaction profile by comparing observed compaction telemetry vectors against the baseline compaction profile.

According to an aspect of an embodiment, the method further comprises the step of performing threat classification by: classifying detected deviations from the baseline compaction profile as security-relevant conditions using a threat classifier; and generating an alert using an alert generator when a security-relevant condition is classified, wherein the security-relevant condition is detected without reconstructing or inspecting underlying data content.

According to an aspect of an embodiment, the security-relevant conditions include detection of encrypted data based on sustained increases in compaction failure count, wherein encrypted data exhibits high entropy and fails to compact at normal rates.

According to an aspect of an embodiment, the security-relevant conditions include detection of steganography or covert channels based on identification of repeated anomalous compaction patterns aligned with message boundaries.

According to an aspect of an embodiment, the security-relevant conditions include detection of data exfiltration based on sudden increases in compaction failure localized to specific endpoints or sustained telemetry anomalies consistent with outbound-only data flow.

### BRIEF DESCRIPTION OF THE DRAWING FIGURES

The accompanying drawings illustrate several aspects and, together with the description, serve to explain the principles of the invention according to the aspects. It will be appreciated by one skilled in the art that the particular arrangements illustrated in the drawings are merely exemplary and are not to be considered as limiting of the scope of the invention or the claims herein in any way.

FIG. 1 is a diagram showing an embodiment of the system in which all components of the system are operated locally.

FIG. 2 is a diagram showing an embodiment of one aspect of the system, the data deconstruction engine.

FIG. 3 is a diagram showing an embodiment of one aspect of the system, the data reconstruction engine.

FIG. 4 is a diagram showing an embodiment of one aspect of the system, the library management module.

FIG. 5 is a diagram showing another embodiment of the system in which data is transferred between remote locations.

FIG. 6 is a diagram showing an embodiment in which a standardized version of the sourceblock library and associated algorithms would be encoded as firmware on a dedicated processing chip included as part of the hardware of a plurality of devices.

FIG. 7 is a diagram showing an example of how data might be converted into reference codes using an aspect of an embodiment.

FIG. 8 is a method diagram showing the steps involved in using an embodiment to store data.

FIG. 9 is a method diagram showing the steps involved in using an embodiment to retrieve data.

FIG. 10 is a method diagram showing the steps involved in using an embodiment to encode data.

FIG. 11 is a method diagram showing the steps involved in using an embodiment to decode data.

FIG. 12 is a diagram showing an exemplary system architecture, according to a preferred embodiment.

FIG. 13 is a diagram showing a more detailed architecture for a customized library generator.

FIG. 14 is a diagram showing a more detailed architecture for a library optimizer.

FIG. 15 is a diagram showing a more detailed architecture for a transmission and storage engine.

FIG. 16 is a method diagram illustrating key system functionality utilizing an encoder and decoder pair.

FIG. 17 is a method diagram illustrating possible use of a hybrid encoder/decoder to improve the compression ratio.

FIG. 18 is a flow diagram illustrating the use of a data encoding system used to recursively encode data to further reduce data size.

FIG. 19 is an exemplary system architecture of a data encoding system used for cyber security purposes.

FIG. 20 is a flow diagram of an exemplary method used to detect anomalies in received encoded data and producing a warning.

FIG. 21 is a flow diagram of a data encoding system used for Distributed Denial of Service (DDoS) attack denial.

FIG. 22 is an exemplary system architecture of a data encoding system used for data mining and analysis purposes.

FIG. 23 is a flow diagram of an exemplary method used to enable high-speed data mining of repetitive data.

FIG. 24 is an exemplary system architecture of a data encoding system used for remote software and firmware updates.

FIG. 25 is a flow diagram of an exemplary method used to encode and transfer software and firmware updates to a device for installation, for the purposes of reduced bandwidth consumption.

FIG. 26 is an exemplary system architecture of a data encoding system used for large-scale software installation such as operating systems.

FIG. 27 is a flow diagram of an exemplary method used to encode new software and operating system installations for reduced bandwidth required for transference.

FIG. 28 is a block diagram of an exemplary system architecture of a codebook training system for a data encoding system, according to an embodiment.

FIG. 29 is a block diagram of an exemplary architecture for a codebook training module, according to an embodiment.

FIG. 30 is a block diagram of another embodiment of the codebook training system using a distributed architecture and a modified training module.

FIG. 31 is a method diagram illustrating the steps involved in using an embodiment of the codebook training system to update a codebook.

FIG. 32 is an exemplary system architecture for an encoding system with multiple codebooks.

FIG. 33 is a flow diagram describing an exemplary algorithm for encoding of data using multiple codebooks.

FIG. 34 is a flow diagram describing an exemplary codebook sorting algorithm for determining a plurality of codebooks to be shuffled between during the encoding process.

FIG. 35 is a diagram showing an exemplary codebook shuffling method.

FIG. 36 is a block diagram illustrating an exemplary system architecture for compacting and encrypting anonymized data, according to an embodiment.

FIG. 37 is a diagram illustrating an exemplary data source tally record and its anonymized counterpart, according to some embodiments.

FIG. 38 is a block diagram illustrating an exemplary anonymized tally record that may be received by system and an exemplary half-backed codebook constructed using the information contained in the anonymized tally record.

FIG. 39 is a diagram illustrating two exemplary data sources, each of which is shown in non-anonymized tally record and anonymized tally record form.

FIG. 40A is diagram illustrating an exemplary process of constructing a half-backed codebook using two data sources and data source stencils, according to some embodiments.

FIG. 40B is a diagram illustrating an exemplary process of transforming a combined half-backed codebook comprising data from two different data sources using data source stencils according to some embodiments.

FIG. 41 is a diagram illustrating an exemplary hybrid stencil constructed using three different data sources, according to some embodiments.

FIG. 42 is an exemplary flow diagram for a method of preparing an anonymized tally record, according to some embodiments.

FIG. 43 is an exemplary flow diagram for a method for constructing a half-backed codebook using a received anonymized tally record, according to some embodiments.

FIG. 44 is a method diagram illustrating the steps involved in using an embodiment of the codebook system to perform indexing and data analysis.

FIG. 45 is a method diagram illustrating the steps involved in using a hierarchical library manager to process sourceblocks.

FIG. 46 is a block diagram illustrating an exemplary compaction telemetry system for generating, analyzing, and acting upon compaction-derived telemetry in anonymized data processing systems.

FIG. 47 is a block diagram illustrating an exemplary telemetry vector aspect of a compaction telemetry system.

FIG. 48 is a block diagram illustrating an exemplary anomaly detection system aspect of a compaction telemetry system.

FIG. 49 is a block diagram illustrating an exemplary closed-loop control system aspect of a compaction telemetry system.

FIG. 50 is a block diagram illustrating an exemplary distributed and federated telemetry aspect of a compaction telemetry system.

FIG. 51 is a block diagram illustrating an exemplary analytics service system aspect of a compaction telemetry system.

FIG. 52 illustrates an exemplary computer system on which an embodiment described herein may be implemented

### DETAILED DESCRIPTION OF THE INVENTION

The inventor has conceived, and reduced to practice, systems and methods for compaction-derived telemetry generation and analysis that transform anonymized encoding operations from passive data processing mechanisms into active sources of privacy-preserving analytical signals, enabling detection of encryption attempts, data exfiltration, dataset evolution, and other operationally significant conditions while maintaining full compliance with data protection requirements and preserving the integrity of anonymization guarantees. The compaction-derived telemetry generation and analysis systems and methods disclosed herein enable interpretation of telemetry signals to infer dataset evolution, security-relevant conditions, and anomalous behaviors, and the use of such interpretations to drive closed-loop control actions, all without reconstructing, inspecting, or accessing underlying plaintext data, thereby preserving privacy and regulatory compliance while enabling novel analytic and security capabilities.

The disclosures herein introduce innovative capabilities for generating, analyzing, and acting upon compaction-derived telemetry that extends the utility of anonymized data compaction systems far beyond simple data storage and transmission. During the operation of an anonymized compaction system, including tally parsing, codebook construction, codeword assignment, encoding, and decoding processes, the methodology describes generates quantitative and qualitative measurements referred to as compaction telemetry. This telemetry includes metrics such as compaction efficiency ratios, codebook size and growth rates, match and mismatch frequencies, encoding and decoding performance statistics, and temporal patterns in compaction behavior. The telemetry is structured into machine-processable representations called compaction telemetry vectors, which can be associated with specific endpoints, datasets, time intervals, or operational contexts. These vectors capture the dynamic behavior of the compaction process without containing or enabling reconstruction of the underlying data content, thereby preserving all privacy guarantees of the anonymized encoding system.

The analysis of compaction telemetry enables detection of numerous security-relevant conditions and operational anomalies through purely non-invasive means. Persistent or systematic compaction failure can be interpreted as indicative of encrypted or pre-compressed data, as encrypted data typically exhibits high entropy and resists dictionary-based compaction. Detection criteria include sustained high mismatch rates relative to baseline performance, abnormal codebook growth without corresponding compaction gains, persistent residual entropy measurements exceeding configured thresholds, and repeated invocation of fallback encoding mechanisms. The methodologies describes can detect steganographic techniques or covert communication channels through analysis of localized or message-specific variations in compaction telemetry, identifying statistically improbable fluctuations in compaction efficiency or repeated anomalous patterns aligned with message boundaries. Data exfiltration attempts can be detected by identifying sudden increases in compaction failure localized to specific endpoints, divergence between expected and observed compaction behavior for known workloads, or sustained telemetry anomalies consistent with outbound-only data flow. All these security detection techniques rely solely on compaction telemetry and derived representations without requiring reconstruction, decryption, or inspection of underlying data content.

The disclosed methodologies implement closed-loop control mechanisms wherein observations of anonymized compaction behavior directly influence subsequent system operation through automated or semi-automated control actions. When compaction telemetry analysis detects security-relevant conditions such as encryption attempts, data exfiltration, or anomalous behavior patterns, the methodologies can initiate automated responses including quarantining suspicious data streams, alerting security personnel, adjusting encoding parameters, or implementing policy-based access controls. The methodologies can adapt encoding strategies based on telemetry feedback, selecting different codebooks, adjusting sourceblock lengths, or modifying optimization parameters to maintain target performance levels. These control actions may form feedback loops that enable stabilization of performance, responses to changing data characteristics, and maintenance of security posture without requiring manual intervention or direct data inspection.

The methodologies support distributed, federated, and multi-tenant deployment models that enable scalable analytics while maintaining data isolation and privacy. Compaction telemetry can be collected from multiple distributed endpoints and aggregated to identify correlated behavior across the network, detect coordinated anomalies, or establish population-level baselines for normal operation. In federated analysis configurations, individual endpoints perform local telemetry analysis and transmit only aggregated results or anomaly indicators to central systems, reducing bandwidth consumption while preserving data locality. Multi-tenant deployments maintain logical isolation of telemetry vectors associated with different tenants, enabling analytics-as-a-service offerings where customers obtain operational and security insights derived from compaction behavior without granting the service provider access to underlying data, thereby preserving customer data sovereignty and enabling monetization of analytics capabilities.

The disclosed techniques facilitate compliance with data protection regulations such as the California Consumer Privacy Act and the European Union General Data Protection Regulation, as compaction telemetry does not include personal data or reconstructive representations of source content. Organizations can perform sophisticated analytics, security monitoring, and performance optimization on data processing operations while maintaining full regulatory compliance and preserving individual privacy rights. The methodologies enable telemetry export through application programming interfaces (APIs) that provide controlled access to telemetry streams, anomaly indicators, trend summaries, and control recommendations, with appropriate security, rate limiting, and permission controls based on deployment requirements.

Beyond traditional data storage and transmission applications, the methodologies described herein enable numerous specialized use cases including cyber security through anomaly detection in encoded data streams, distributed denial of service attack mitigation by detecting large amounts of invalid or unencoded data, high-speed data mining of repetitive data through efficient encoding of common patterns, remote software and firmware updates with reduced bandwidth consumption, and large-scale software installations such as operating systems. The codebook training system can learn optimal encoding patterns from representative training data using machine learning techniques, with library optimization through pruning of low-occurrence entries, delta encoding for approximate codewords, and parametric optimization using techniques such as stochastic gradient descent and evolutionary search to optimize all interdependent system parameters.

In summary, the disclosures herein describe methodologies that transform anonymized data compaction from a passive encoding mechanism into an active sensing and control platform, providing efficient lossless data compaction with inherent encryption properties through the use of anonymized tally records and optimized codebook construction, while enabling privacy-preserving analytics, security detection, and adaptive system control that are not achievable through traditional data inspection techniques. The disclosures address fundamental challenges in data storage capacity, transmission bandwidth, encryption security, and privacy protection while enabling new capabilities in operational monitoring, threat detection, and autonomous system optimization across distributed computing environments.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

“Bit” as used herein refers to the smallest unit of information that can be stored or transmitted. It is in the form of a binary digit (either 0 or 1). In terms of hardware, the bit is represented as an electrical signal that is either off (representing 0) or on (representing 1).

“Byte” as used herein refers to a series of bits exactly eight bits in length.

“Codebook” as used herein refers to a database containing sourceblocks each with a pattern of bits and reference code unique within that library. The terms “library” and “encoding/decoding library” are synonymous with the term codebook.

“Compression” and “Deflation” as used herein mean the representation of data in a more compact form than the original dataset. Compression and/or deflation may be either “lossless”, in which the data can be reconstructed in its original form without any loss of the original data, or “lossy” in which the data can be reconstructed in its original form, but with some loss of the original data.

“Compression factor” and “Deflation factor” as used herein mean the net reduction in size of the compressed data relative to the original data (e.g., if the new data is 70% of the size of the original, then the deflation/compression factor is 30% or 0.3.)

“Compression ratio” and “Deflation ratio” as used herein all mean the size of the original data relative to the size of the compressed data (e.g., if the new data is 70% of the size of the original, then the deflation/compression ratio is 70% or 0.7.)

“Data” as used herein means information in any computer-readable form.

“Data set” as used herein refers to a grouping of data for a particular purpose. One example of a data set might be a word processing file containing text and formatting information.

“Effective compression” and “Effective compression ratio” as used herein refer to the additional amount data that can be stored using the method herein described versus conventional data storage methods. Although the method herein described is not data compression, per se, expressing the additional capacity in terms of compression is a useful comparison.

“Sourcepacket” as used herein means a packet of data received for encoding or decoding. A sourcepacket may be a portion of a data set.

“Sourceblock” as used herein means a defined number of bits or bytes used as the block size for encoding or decoding. A sourcepacket may be divisible into a number of sourceblocks. As one non-limiting example, a 1 megabyte sourcepacket of data may be encoded using 512 byte sourceblocks. The number of bits in a sourceblock may be dynamically optimized by the system during operation. In one aspect, a sourceblock may be of the same length as the block size used by a particular file system, typically 512 bytes or 4,096 bytes.

“Codeword” refers to the reference code form in which data is stored or transmitted in an aspect of the system. A codeword consists of a reference code to a sourceblock in the library plus an indication of that sourceblock’s location in a particular data set.

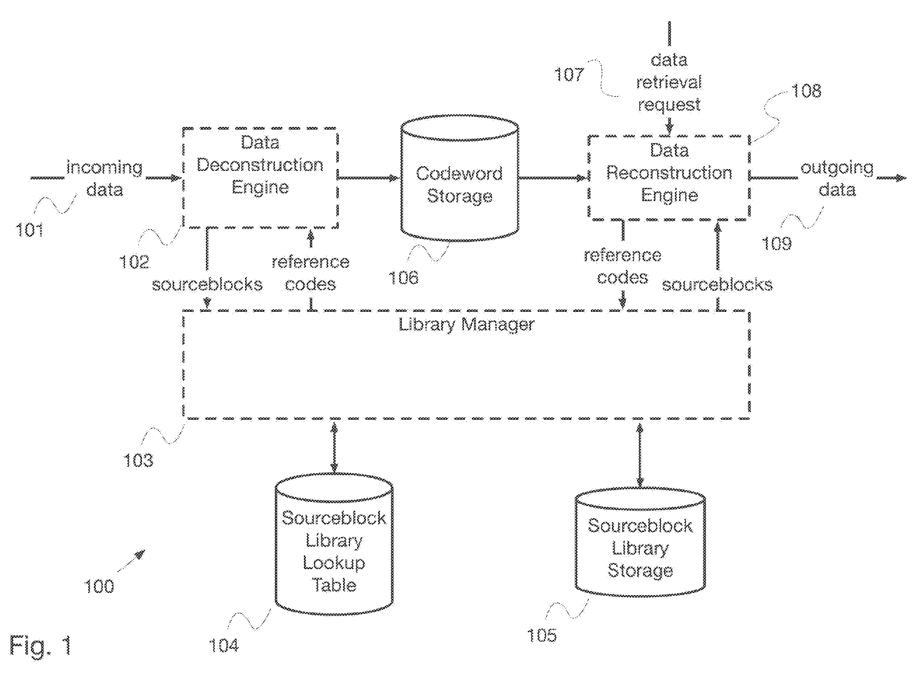

FIG. 1 is a diagram showing an embodiment 100 of the system in which all components of the system are operated locally. As incoming data 101 is received by data deconstruction engine 102. Data deconstruction engine 102 breaks the incoming data into sourceblocks, which are then sent to library manager 103. Using the information contained in sourceblock library lookup table 104 and sourceblock library storage 105, library manager 103 returns reference codes to data deconstruction engine 102 for processing into codewords, which are stored in codeword storage 106. When a data retrieval request 107 is received, data reconstruction engine 108 obtains the codewords associated with the data from codeword storage 106, and sends them to library manager 103. Library manager 103 returns the appropriate sourceblocks to data reconstruction engine 108, which assembles them into the proper order and sends out the data in its original form 109.

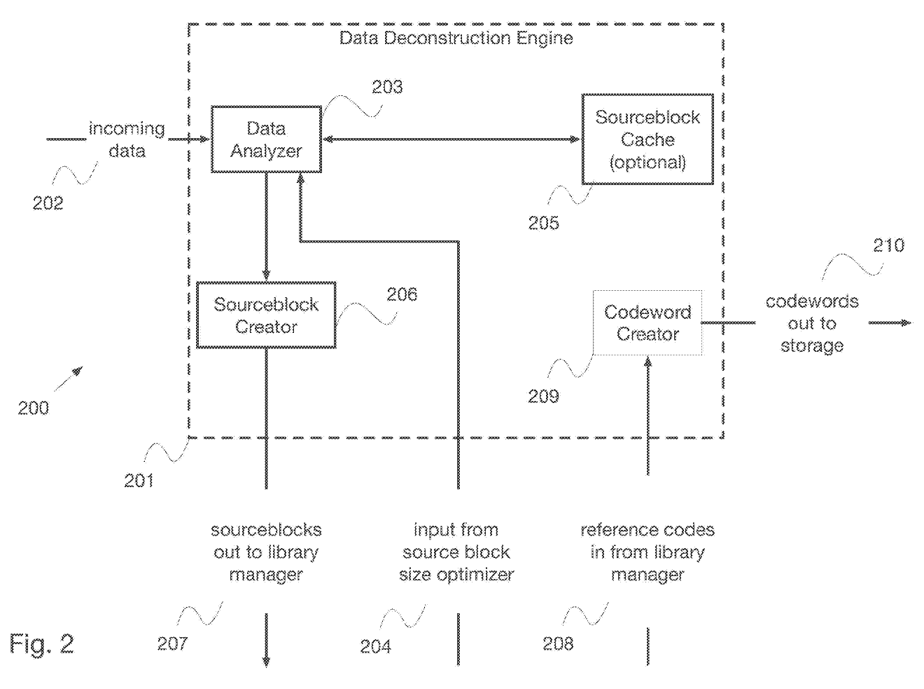

FIG. 2 is a diagram showing an embodiment of one aspect 200 of the system, specifically data deconstruction engine 201. Incoming data 202 is received by data analyzer 203, which optimally analyzes the data based on machine learning algorithms and input 204 from a sourceblock size optimizer, which is disclosed below. Data analyzer may optionally have access to a sourceblock cache 205 of recently-processed sourceblocks, which can increase the speed of the system by avoiding processing in library manager 103. Based on information from data analyzer 203, the data is broken into sourceblocks by sourceblock creator 206, which sends sourceblocks 207 to library manager 203 for additional processing. Data deconstruction engine 201 receives reference codes 208 from library manager 103, corresponding to the sourceblocks in the library that match the sourceblocks sent by sourceblock creator 206, and codeword creator 209 processes the reference codes into codewords comprising a reference code to a sourceblock and a location of that sourceblock within the data set. The original data may be discarded, and the codewords representing the data are sent out to storage 210.

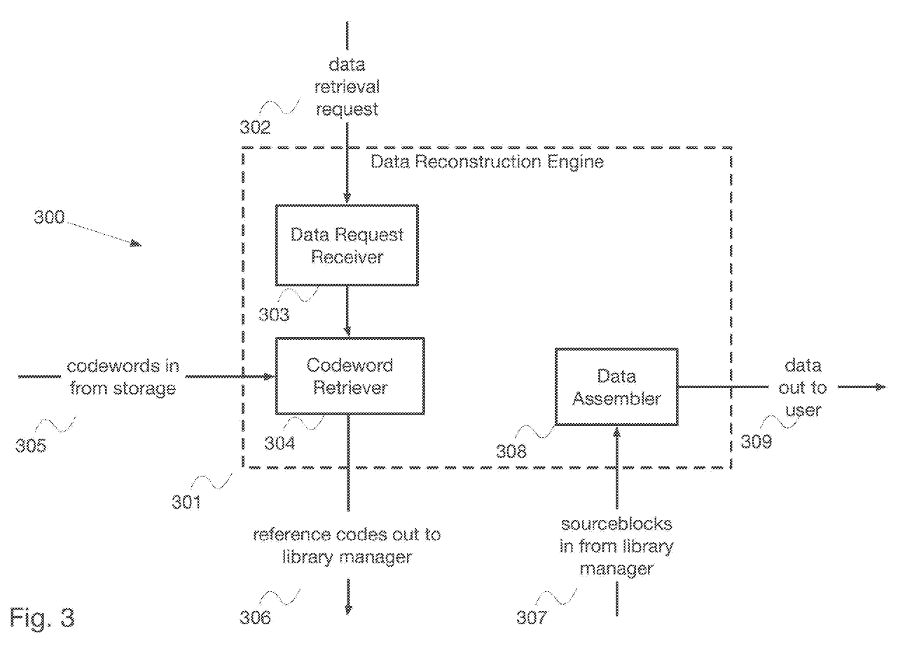

FIG. 3 is a diagram showing an embodiment of another aspect of system 300, specifically data reconstruction engine 301. When a data retrieval request 302 is received by data request receiver 303 (in the form of a plurality of codewords corresponding to a desired final data set), it passes the information to data retriever 304, which obtains the requested data 305 from storage. Data retriever 304 sends, for each codeword received, a reference codes from the codeword 306 to library manager 103 for retrieval of the specific sourceblock associated with the reference code. Data assembler 308 receives the sourceblock 307 from library manager 103 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 309 in its original form.

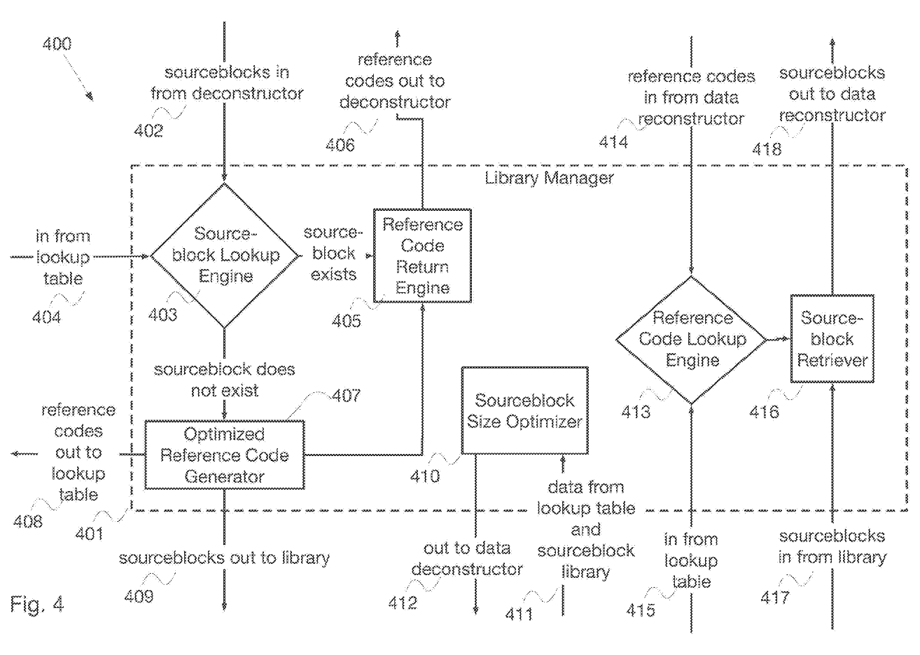

FIG. 4 is a diagram showing an embodiment of another aspect of the system 400, specifically library manager 401. One function of library manager 401 is to generate reference codes from sourceblocks received from data deconstruction engine 301. As sourceblocks are received 402 from data deconstruction engine 301, sourceblock lookup engine 403 checks sourceblock library lookup table 404 to determine whether those sourceblocks already exist in sourceblock library storage 105. If a particular sourceblock exists in sourceblock library storage 105, reference code return engine 405 sends the appropriate reference code 406 to data deconstruction engine 301. If the sourceblock does not exist in sourceblock library storage 105, optimized reference code generator 407 generates a new, optimized reference code based on machine learning algorithms. Optimized reference code generator 407 then saves the reference code 408 to sourceblock library lookup table 104; saves the associated sourceblock 409 to sourceblock library storage 105; and passes the reference code to reference code return engine 405 for sending 406 to data deconstruction engine 301. Another function of library manager 401 is to optimize the size of sourceblocks in the system. Based on information 411 contained in sourceblock library lookup table 104, sourceblock size optimizer 410 dynamically adjusts the size of sourceblocks in the system based on machine learning algorithms and outputs that information 412 to data analyzer 203. Another function of library manager 401 is to return sourceblocks associated with reference codes received from data reconstruction engine 301. As reference codes are received 414 from data reconstruction engine 301, reference code lookup engine 413 checks sourceblock library lookup table 415 to identify the associated sourceblocks; passes that information to sourceblock retriever 416, which obtains the sourceblocks 417 from sourceblock library storage 105; and passes them 418 to data reconstruction engine 301.

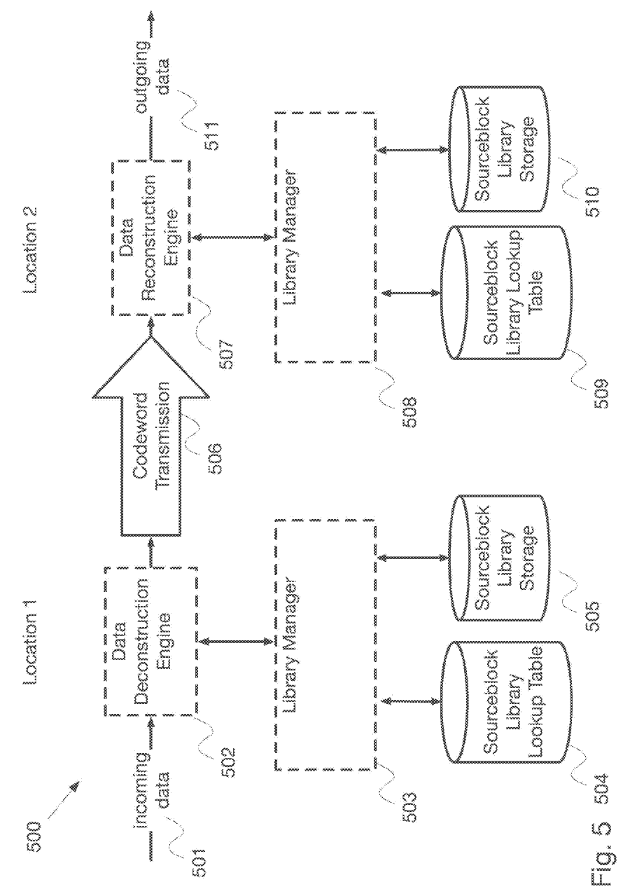

FIG. 5 is a diagram showing another embodiment of system 500, in which data is transferred between remote locations. As incoming data 501 is received by data deconstruction engine 502 at Location 1, data deconstruction engine 301 breaks the incoming data into sourceblocks, which are then sent to library manager 503 at Location 1. Using the information contained in sourceblock library lookup table 504 at Location 1 and sourceblock library storage 505 at Location 1, library manager 503 returns reference codes to data deconstruction engine 301 for processing into codewords, which are transmitted 506 to data reconstruction engine 507 at Location 2. In the case where the reference codes contained in a particular codeword have been newly generated by library manager 503 at Location 1, the codeword is transmitted along with a copy of the associated sourceblock. As data reconstruction engine 507 at Location 2 receives the codewords, it passes them to library manager module 508 at Location 2, which looks up the sourceblock in sourceblock library lookup table 509 at Location 2, and retrieves the associated from sourceblock library storage 510. Where a sourceblock has been transmitted along with a codeword, the sourceblock is stored in sourceblock library storage 510 and sourceblock library lookup table 504 is updated. Library manager 503 returns the appropriate sourceblocks to data reconstruction engine 507, which assembles them into the proper order and sends the data in its original form 511.

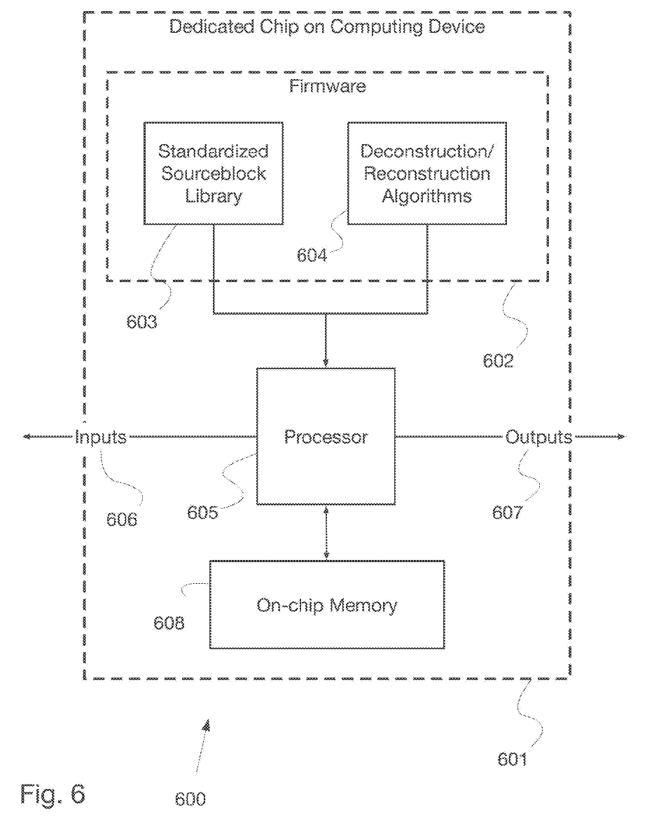

FIG. 6 is a diagram showing an embodiment 600 in which a standardized version of a sourceblock library 603 and associated algorithms 604 would be encoded as firmware 602 on a dedicated processing chip 601 included as part of the hardware of a plurality of devices 600. Contained on dedicated chip 601 would be a firmware area 602, on which would be stored a copy of a standardized sourceblock library 603 and deconstruction/reconstruction algorithms 604 for processing the data. Processor 605 would have both inputs 606 and outputs 607 to other hardware on the device 600. Processor 605 would store incoming data for processing on on-chip memory 608, process the data using standardized sourceblock library 603 and deconstruction/reconstruction algorithms 604, and send the processed data to other hardware on device 600. Using this embodiment, the encoding and decoding of data would be handled by dedicated chip 601, keeping the burden of data processing off device’s 600 primary processors. Any device equipped with this embodiment would be able to store and transmit data in a highly optimized, bandwidth-efficient format with any other device equipped with this embodiment.

Sourceblock is read from the library, and the data is reconstructed into its original form.

Since the library consists of re-usable building sourceblocks, and the actual data is represented by reference codes to the library, the total storage space of a single set of data would be much smaller than conventional methods, wherein the data is stored in its entirety. The more data sets that are stored, the larger the library becomes, and the more data can be stored in reference code form.

As an analogy, imagine each data set as a collection of printed books that are only occasionally accessed. The amount of physical shelf space required to store many collections would be quite large, and is analogous to conventional methods of storing every single bit of data in every data set. Consider, however, storing all common elements within and across books in a single library, and storing the books as references codes to those common elements in that library. As a single book is added to the library, it will contain many repetitions of words and phrases. Instead of storing the whole words and phrases, they are added to a library, and given a reference code, and stored as reference codes. At this scale, some space savings may be achieved, but the reference codes will be on the order of the same size as the words themselves. As more books are added to the library, larger phrases, quotations, and other words patterns will become common among the books. The larger the word patterns, the smaller the reference codes will be in relation to them as not all possible word patterns will be used. As entire collections of books are added to the library, sentences, paragraphs, pages, or even whole books will become repetitive. There may be many duplicates of books within a collection and across multiple collections, many references and quotations from one book to another, and much common phraseology within books on particular subjects. If each unique page of a book is stored only once in a common library and given a reference code, then a book of 1,000 pages or more could be stored on a few printed pages as a string of codes referencing the proper full-sized pages in the common library. The physical space taken up by the books would be dramatically reduced. The more collections that are added, the greater the likelihood that phrases, paragraphs, pages, or entire books will already be in the library, and the more information in each collection of books can be stored in reference form. Accessing entire collections of books is then limited not by physical shelf space, but by the ability to reprint and recycle the books as needed for use.

The projected increase in storage capacity using the method herein described is primarily dependent on two factors: 1) the ratio of the number of bits in a block to the number of bits in the reference code, and 2) the amount of repetition in data being stored by the system.

With respect to the first factor, the number of bits used in the reference codes to the sourceblocks must be smaller than the number of bits in the sourceblocks themselves in order for any additional data storage capacity to be obtained. As a simple example, 16-bit sourceblocks would require 216, or 65536, unique reference codes to represent all possible patterns of bits. If all possible 65536 blocks patterns are utilized, then the reference code itself would also need to contain sixteen bits in order to refer to all possible 65,536 blocks patterns. In such case, there would be no storage savings. However, if only 16 of those block patterns are utilized, the reference code can be reduced to 4 bits in size, representing an effective compression of 4 times (16 bits / 4 bits = 4) versus conventional storage. Using a typical block size of 512 bytes, or 4,096 bits, the number of possible block patterns is 24,096, which for all practical purposes is unlimited. A typical hard drive contains one terabyte (TB) of physical storage capacity, which represents 1,953,125,000, or roughly 231, 512 byte blocks. Assuming that 1 TB of unique 512-byte sourceblocks were contained in the library, and that the reference code would thus need to be 31 bits long, the effective compression ratio for stored data would be on the order of 132 times (4,096 / 31 ≈ 132) that of conventional storage.

With respect to the second factor, in most cases it could be assumed that there would be sufficient repetition within a data set such that, when the data set is broken down into sourceblocks, its size within the library would be smaller than the original data. However, it is conceivable that the initial copy of a data set could require somewhat more storage space than the data stored in a conventional manner, if all or nearly all sourceblocks in that set were unique. For example, assuming that the reference codes are 1/10th the size of a full-sized copy, the first copy stored as sourceblocks in the library would need to be 1.1 megabytes (MB), (1 MB for the complete set of full-sized sourceblocks in the library and 0.1 MB for the reference codes). However, since the sourceblocks stored in the library are universal, the more duplicate copies of something you save, the greater efficiency versus conventional storage methods. Conventionally, storing 10 copies of the same data requires 10 times the storage space of a single copy. For example, ten copies of a 1 MB file would take up 10 MB of storage space. However, using the method described herein, only a single full-sized copy is stored, and subsequent copies are stored as reference codes. Each additional copy takes up only a fraction of the space of the full-sized copy. For example, again assuming that the reference codes are 1/10th the size of the full-size copy, ten copies of a 1 MB file would take up only 2 MB of space (1 MB for the full-sized copy, and 0.1 MB each for ten sets of reference codes). The larger the library, the more likely that part or all of incoming data will duplicate sourceblocks already existing in the library.

The size of the library could be reduced in a manner similar to storage of data. Where sourceblocks differ from each other only by a certain number of bits, instead of storing a new sourceblock that is very similar to one already existing in the library, the new sourceblock could be represented as a reference code to the existing sourceblock, plus information about which bits in the new block differ from the existing block. For example, in the case where 512 byte sourceblocks are being used, if the system receives a new sourceblock that differs by only one bit from a sourceblock already existing in the library, instead of storing a new 512 byte sourceblock, the new sourceblock could be stored as a reference code to the existing sourceblock, plus a reference to the bit that differs. Storing the new sourceblock as a reference code plus changes would require only a few bytes of physical storage space versus the 512 bytes that a full sourceblock would require. The algorithm could be optimized to store new sourceblocks in this reference code plus changes form unless the changes portion is large enough that it is more efficient to store a new, full sourceblock.

It will be understood by one skilled in the art that transfer and synchronization of data would be increased to the same extent as for storage. By transferring or synchronizing reference codes instead of full-sized data, the bandwidth requirements for both types of operations are dramatically reduced.

In addition, the method described herein is inherently a form of encryption. When the data is converted from its full form to reference codes, none of the original data is contained in the reference codes. Without access to the library of sourceblocks, it would be impossible to re-construct any portion of the data from the reference codes. This inherent property of the method described herein could obviate the need for traditional encryption algorithms, thereby offsetting most or all of the computational cost of conversion of data back and forth to reference codes. In theory, the method described herein should not utilize any additional computing power beyond traditional storage using encryption algorithms. Alternatively, the method described herein could be in addition to other encryption algorithms to increase data security even further.

In other embodiments, additional security features could be added, such as: creating a proprietary library of sourceblocks for proprietary networks, physical separation of the reference codes from the library of sourceblocks, storage of the library of sourceblocks on a removable device to enable easy physical separation of the library and reference codes from any network, and incorporation of proprietary sequences of how sourceblocks are read and the data reassembled.

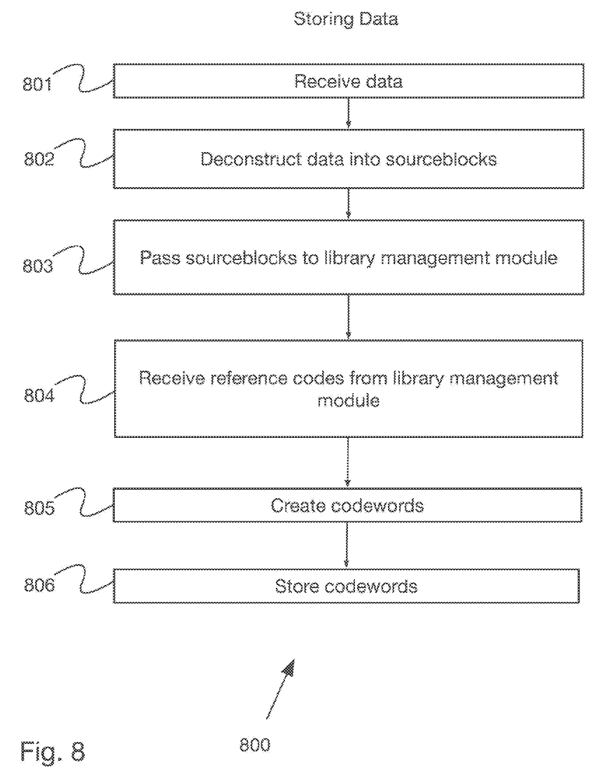

FIG. 8 is a method diagram showing the steps involved in using an embodiment 800 to store data. As data is received 801, it would be deconstructed into sourceblocks 802, and passed 803 to the library management module for processing. Reference codes would be received back 804 from the library management module, and could be combined with location information to create codewords 805, which would then be stored 806 as representations of the original data.

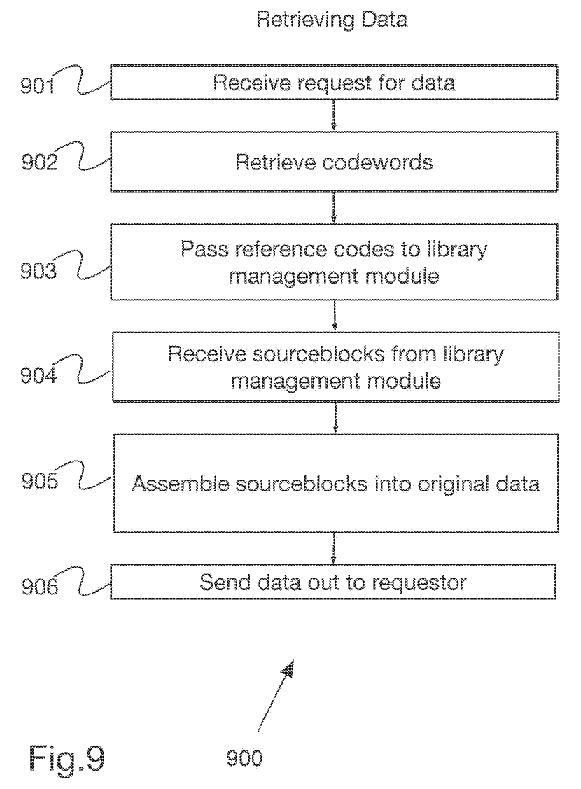

FIG. 9 is a method diagram showing the steps involved in using an embodiment 900 to retrieve data. When a request for data is received 901, the associated codewords would be retrieved 902 from the library. The codewords would be passed 903 to the library management module, and the associated sourceblocks would be received back 904. Upon receipt, the sourceblocks would be assembled 905 into the original data using the location data contained in the codewords, and the reconstructed data would be sent out 906 to the requestor.

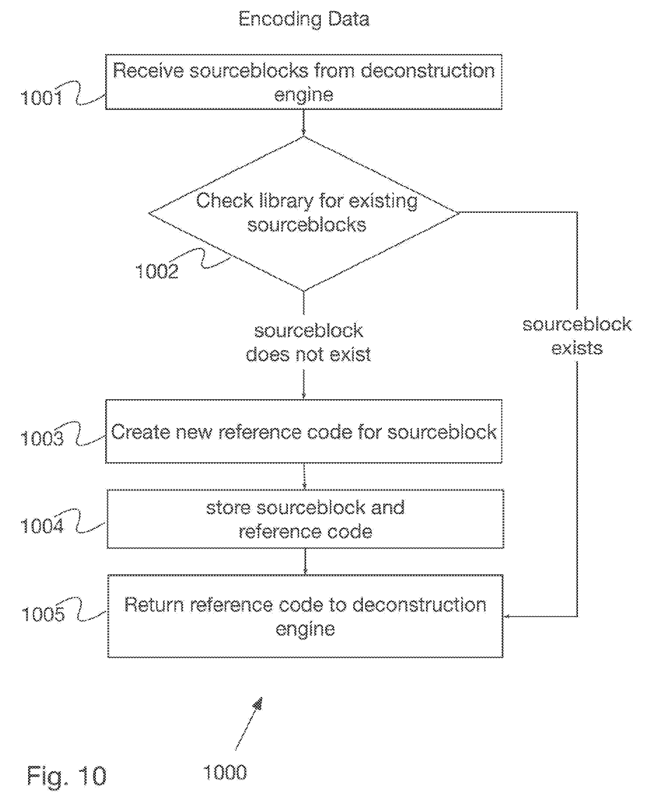

FIG. 10 is a method diagram showing the steps involved in using an embodiment 1000 to encode data. As sourceblocks are received 1001 from the deconstruction engine, they would be compared 1002 with the sourceblocks already contained in the library. If that sourceblock already exists in the library, the associated reference code would be returned 1005 to the deconstruction engine. If the sourceblock does not already exist in the library, a new reference code would be created 1003 for the sourceblock. The new reference code and its associated sourceblock would be stored 1004 in the library, and the reference code would be returned to the deconstruction engine.

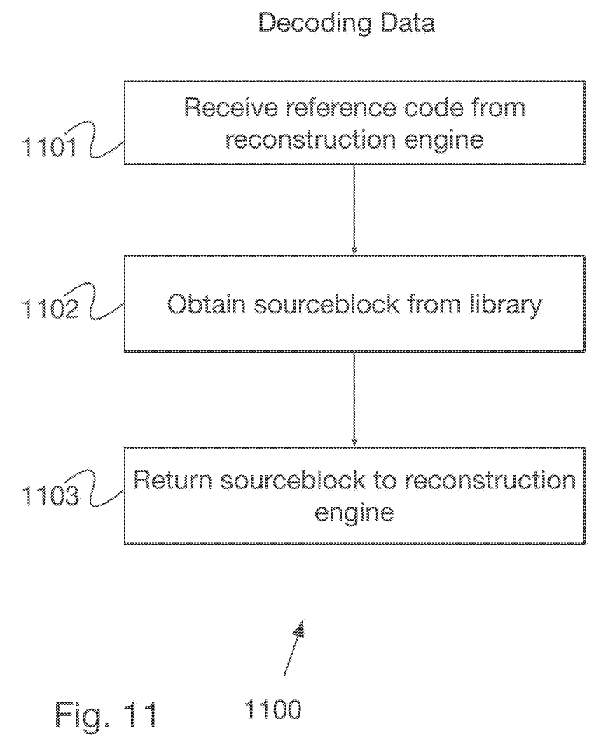

FIG. 11 is a method diagram showing the steps involved in using an embodiment 1100 to decode data. As reference codes are received 1101 from the reconstruction engine, the associated sourceblocks are retrieved 1102 from the library, and returned 1103 to the reconstruction engine.

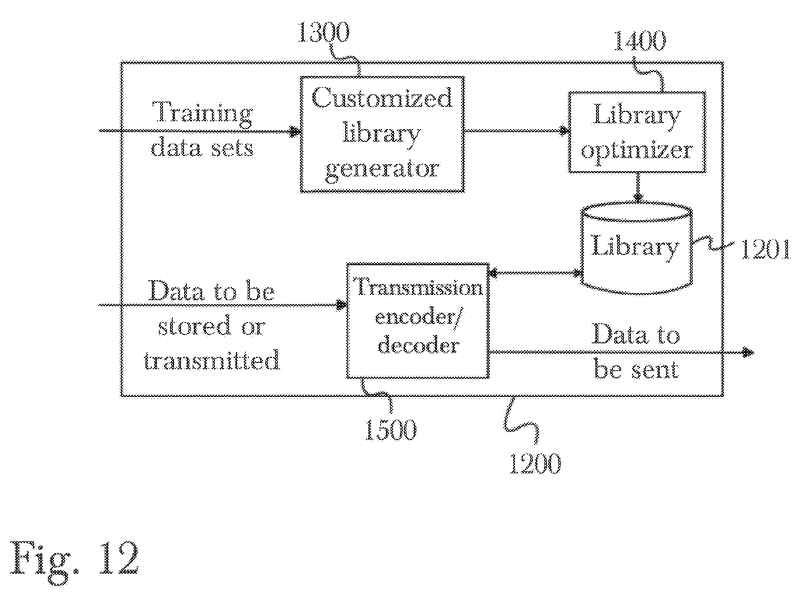

FIG. 12 is a diagram showing an exemplary system architecture 1200, according to a preferred embodiment. Incoming training data sets may be received at a customized library generator 1300 that processes training data to produce a customized word library 1201 comprising key-value pairs of data words (each comprising a string of bits) and their corresponding calculated binary Huffman codewords. The resultant word library 1201 may then be processed by a library optimizer 1400 to reduce size and improve efficiency, for example by pruning low-occurrence data entries or calculating approximate codewords that may be used to match more than one data word. A transmission encoder/decoder 1500 may be used to receive incoming data intended for storage or transmission, process the data using a word library 1201 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1200 provides near-instantaneous source coding that is dictionary-based and learned in advance from sample training data, so that encoding and decoding may happen concurrently with data transmission. This results in computational latency that is near zero but the data size reduction is comparable to classical compression. For example, if N bits are to be transmitted from sender to receiver, the compression ratio of classical compression is C, the ratio between the deflation factor of system 1200 and that of multi-pass source coding is p, the classical compression encoding rate is RC bit/s and the decoding rate is RD bit/s, and the transmission speed is S bit/s, the compress-send-decompress time will be T_old = N/R_C +N/CS+N/ [(CR)] _D while the transmit-while-coding time for system 1200 will be (assuming that encoding and decoding happen at least as quickly as network latency): T_new = N_p/CSso that the total data transit time improvement factor isT_old/T_new = (CS/R_C +1+S/R_D)/p which presents a savings whenever CS/R_C +S/R_D > p-1. This is a reasonable scenario given that typical values in real-world practice are C = 0.32, RC = 1.1 • 1012, RD = 4.2 • 1012, S = 1011, giving CS/R_C +S/R_D =0.053..., such that system 1200 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e. [(delay)] _invention=tp/CS since encoding and decoding occur concurrently with data transmission. On the other hand, the latency associated with classical compression is [(delay)] _prior art = N/R_C +N/CS+N/ [(CR)] _D where N is the packet/file size. Even with the generous values chosen above as well as N = 512K, t = 10, and p = 1.05, this results in delay invention ≈ 3.3 • 10-10 while delay prior art ≈ 1.3 • 10-7, a more than 400-fold reduction in latency.

A key factor in the efficiency of Huffman coding used by system 1200 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1200 addresses this by restriction of data types and density estimation; training data is provided that is representative of the type of data anticipated in “real-world” use of system 1200, which is then used to model the distribution of binary strings in the data in order to build a Huffman code word library 1200.

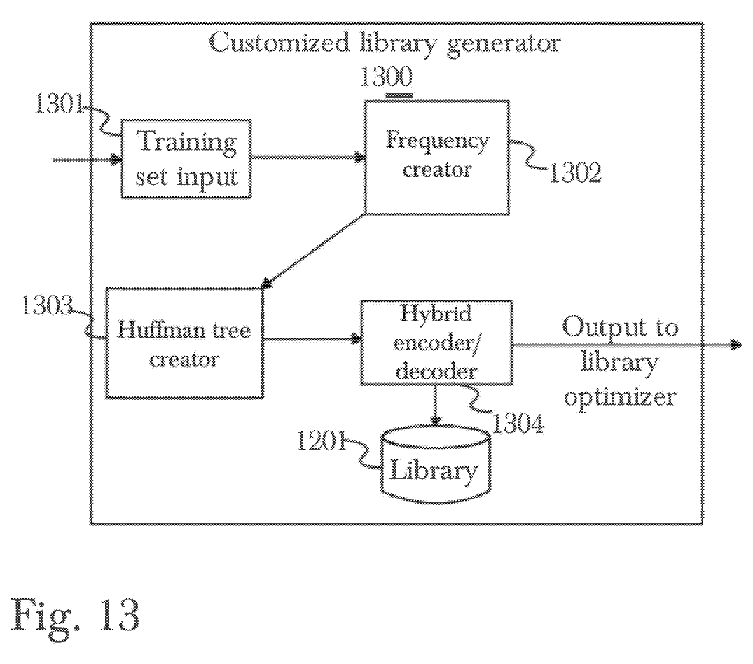

FIG. 13 is a diagram showing a more detailed architecture for a customized library generator 1300. When an incoming training data set 1301 is received, it may be analyzed using a frequency creator 1302 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yield better results when used with real-world data (rather than, for example, being only based on a single training data set that may not be very similar to a received non-training data set). A second Huffman tree creator 1303 may be utilized to identify words that do not match any existing entries in a word library 1201 and pass them to a hybrid encoder/decoder 1304, that then calculates a binary Huffman codeword for the mismatched word and adds the codeword and original data to the word library 1201 as a new key-value pair. In this manner, customized library generator 1300 may be used both to establish an initial word library 1201 from a first training set, as well as expand the word library 1201 using additional training data to improve operation.

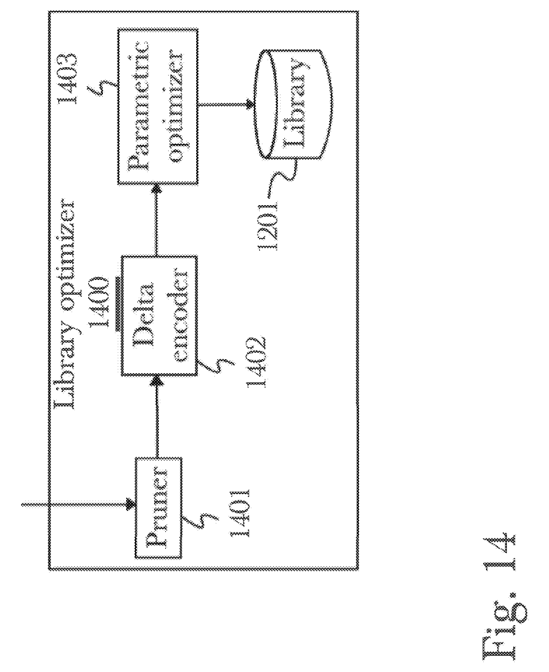

FIG. 14 is a diagram showing a more detailed architecture for a library optimizer 1400. A pruner 1401 may be used to load a word library 1201 and reduce its size for efficient operation, for example by sorting the word library 1201 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1201 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1402 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1403 may load configuration parameters for operation to optimize the use of the word library 1201 during operation. Best-practice parameter/hyperparameter optimization strategies such as stochastic gradient descent, quasi-random grid search, and evolutionary search may be used to make optimal choices for all interdependent settings playing a role in the functionality of system 1200. In cases where lossless compression is not required, the delta value may be discarded at the expense of introducing some limited errors into any decoded (reconstructed) data.

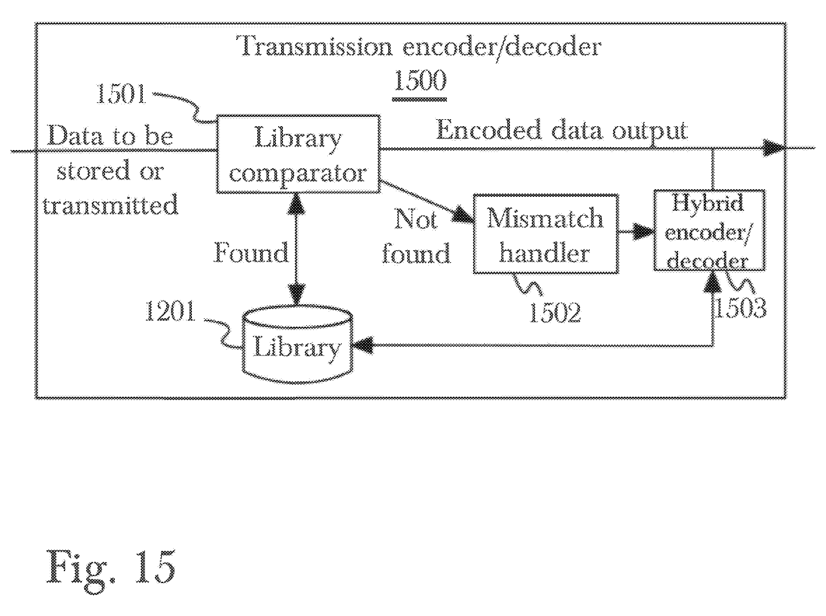

FIG. 15 is a diagram showing a more detailed architecture for a transmission encoder/decoder 1500. According to various arrangements, transmission encoder/decoder 1500 may be used to deconstruct data for storage or transmission, or to reconstruct data that has been received, using a word library 1201. A library comparator 1501 may be used to receive data comprising words or codewords, and compare against a word library 1201 by dividing the incoming stream into substrings of length t and using a fast hash to check word library 1201 for each substring. If a substring is found in word library 1201, the corresponding key/value (that is, the corresponding source word or codeword, according to whether the substring used in comparison was itself a word or codeword) is returned and appended to an output stream. If a given substring is not found in word library 1201, a mismatch handler 1502 and hybrid encoder/decoder 1503 may be used to handle the mismatch similarly to operation during the construction or expansion of word library 1201. A mismatch handler 1502 may be utilized to identify words that do not match any existing entries in a word library 1201 and pass them to a hybrid encoder/decoder 1503, that then calculates a binary Huffman codeword for the mismatched word and adds the codeword and original data to the word library 1201 as a new key-value pair. The newly-produced codeword may then be appended to the output stream. In arrangements where a mismatch indicator is included in a received data stream, this may be used to preemptively identify a substring that is not in word library 1201 (for example, if it was identified as a mismatch on the transmission end), and handled accordingly without the need for a library lookup.

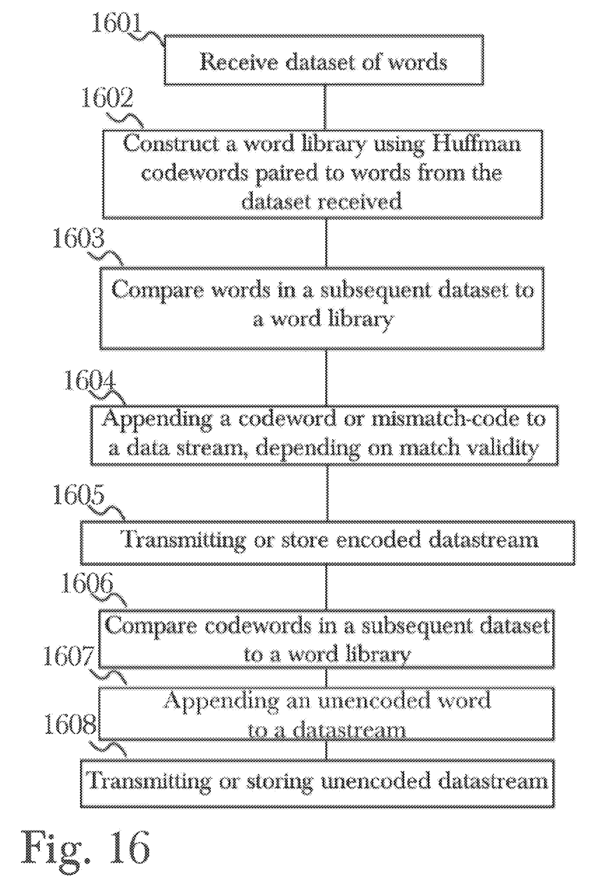

FIG. 16 is a method diagram illustrating key system functionality utilizing an encoder and decoder pair, according to a preferred embodiment. In a first step 1601, at least one incoming data set may be received at a customized library generator 1300 that then 1602 processes data to produce a customized word library 1201 comprising key-value pairs of data words (each comprising a string of bits) and their corresponding calculated binary Huffman codewords. A subsequent dataset may be received, and compared to the word library 1603 to determine the proper codewords to use in order to encode the dataset. Words in the dataset are checked against the word library and appropriate encodings are appended to a data stream 1604. If a word is mismatched within the word library and the dataset, meaning that it is present in the dataset but not the word library, then a mismatched code is appended, followed by the unencoded original word. If a word has a match within the word library, then the appropriate codeword in the word library is appended to the data stream. Such a data stream may then be stored or transmitted 1605 to a destination as desired. For the purposes of decoding, an already-encoded data stream may be received and compared 1606, and un-encoded words may be appended to a new data stream 1607 depending on word matches found between the encoded data stream and the word library that is present. A matching codeword that is found in a word library is replaced with the matching word and appended to a data stream, and a mismatch code found in a data stream is deleted and the following unencoded word is re-appended to a new data stream, the inverse of the process of encoding described earlier. Such a data stream may then be stored or transmitted 1608 as desired.

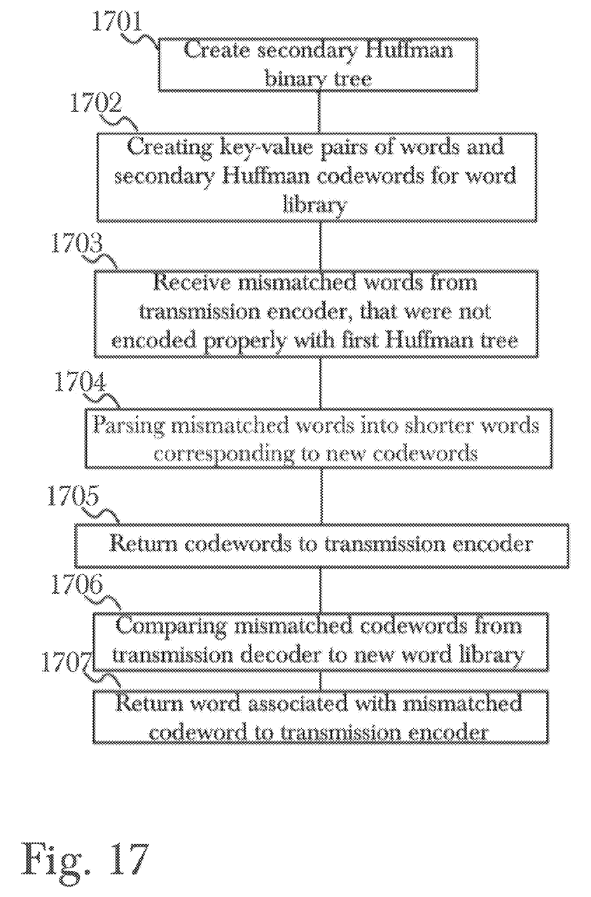

FIG. 17 is a method diagram illustrating possible use of a hybrid encoder/decoder to improve the compression ratio, according to a preferred aspect. A second Huffman binary tree may be created 1701, having a shorter maximum length of codewords than a first Huffman binary tree 1602, allowing a word library to be filled with every combination of codeword possible in this shorter Huffman binary tree 1702. A word library may be filled with these Huffman codewords and words from a dataset 1702, such that a hybrid encoder/decoder 1304, 1503 may receive any mismatched words from a dataset for which encoding has been attempted with a first Huffman binary tree 1703, 1604 and parse previously mismatched words into new partial codewords (that is, codewords that are each a substring of an original mismatched codeword) using the second Huffman binary tree 1704. In this way, an incomplete word library may be supplemented by a second word library. New codewords attained in this way may then be returned to a transmission encoder 1705, 1500. In the event that an encoded dataset is received for decoding, and there is a mismatch code indicating that additional coding is needed, a mismatch code may be removed and the unencoded word used to generate a new codeword as before 1706, so that a transmission encoder 1500 may have the word and newly generated codeword added to its word library 1707, to prevent further mismatching and errors in encoding and decoding.

It will be recognized by a person skilled in the art that the methods described herein can be applied to data in any form. For example, the method described herein could be used to store genetic data, which has four data units: C, G, A, and T. Those four data units can be represented as 2 bit sequences: 00, 01, 10, and 11, which can be processed and stored using the method described herein.

It will be recognized by a person skilled in the art that certain embodiments of the methods described herein may have uses other than data storage. For example, because the data is stored in reference code form, it cannot be reconstructed without the availability of the library of sourceblocks. This is effectively a form of encryption, which could be used for cyber security purposes. As another example, an embodiment of the method described herein could be used to store backup copies of data, provide for redundancy in the event of server failure, or provide additional security against cyberattacks by distributing multiple partial copies of the library among computers are various locations, ensuring that at least two copies of each sourceblock exist in different locations within the network.

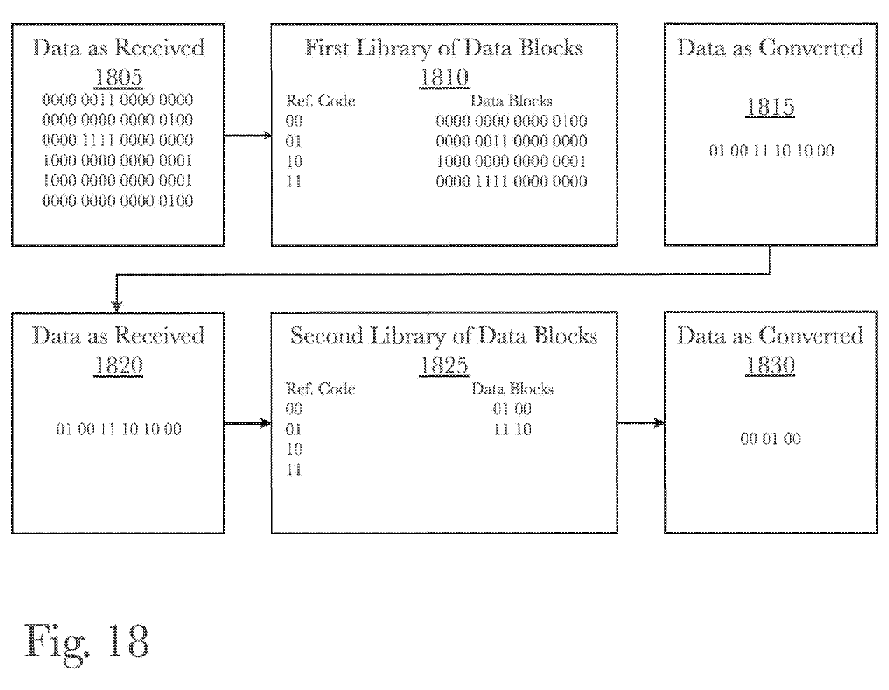

FIG. 18 is a flow diagram illustrating the use of a data encoding system used to recursively encode data to further reduce data size. Data may be input 1805 into a data deconstruction engine 102 to be deconstructed into code references, using a library of code references based on the input 1810. Such example data is shown in a converted, encoded format 1815, highly compressed, reducing the example data from 96 bits of data, to 12 bits of data, before sending this newly encoded data through the process again 1820, to be encoded by a second library 1825, reducing it even further. The newly converted data 1830 is shown as only 6 bits in this example, thus a size of 6.25% of the original data packet. With recursive encoding, then, it is possible and implemented in the system to achieve increasing compression ratios, using multi-layered encoding, through recursively encoding data. Both initial encoding libraries 1810 and subsequent libraries 1825 may be achieved through machine learning techniques to find optimal encoding patterns to reduce size, with the libraries being distributed to recipients prior to transfer of the actual encoded data, such that only the compressed data 1830 must be transferred or stored, allowing for smaller data footprints and bandwidth requirements. This process can be reversed to reconstruct the data. While this example shows only two levels of encoding, recursive encoding may be repeated any number of times. The number of levels of recursive encoding will depend on many factors, a non-exhaustive list of which includes the type of data being encoded, the size of the original data, the intended usage of the data, the number of instances of data being stored, and available storage space for codebooks and libraries. Additionally, recursive encoding can be applied not only to data to be stored or transmitted, but also to the codebooks and/or libraries, themselves. For example, many installations of different libraries could take up a substantial amount of storage space. Recursively encoding those different libraries to a single, universal library would dramatically reduce the amount of storage space required, and each different library could be reconstructed as necessary to reconstruct incoming streams of data.

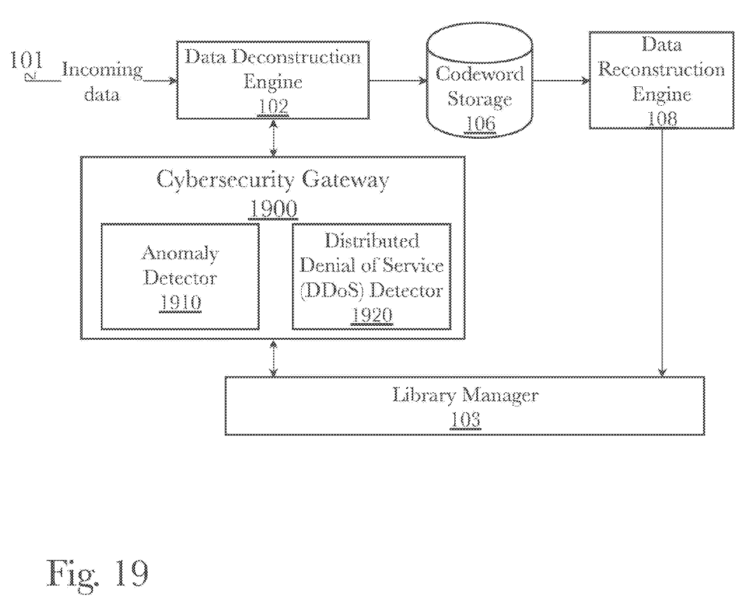

FIG. 19 is an exemplary system architecture of a data encoding system used for cyber security purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. However, a cybersecurity gateway 1900 is present, communicating in-between a library manager 103 and a deconstruction engine 102, and containing an anomaly detector 1910 and distributed denial of service (DDoS) detector 1920. The anomaly detector examines incoming data to determine whether there is a disproportionate number of incoming reference codes that do not match reference codes in the existing library. A disproportionate number of non-matching reference codes may indicate that data is being received from an unknown source, of an unknown type, or contains unexpected (possibly malicious) data. If the disproportionate number of non-matching reference codes exceeds an established threshold or persists for a certain length of time, the anomaly detector 1910 raises a warning to a system administrator. Likewise, the DDoS detector 1920 examines incoming data to determine whether there is a disproportionate amount of repetitive data. A disproportionate amount of repetitive data may indicate that a DDoS attack is in progress. If the disproportionate amount of repetitive data exceeds an established threshold or persists for a certain length of time, the DDoS detector 1910 raises a warning to a system administrator. In this way, a data encoding system may detect and warn users of, or help mitigate, common cyber-attacks that result from a flow of unexpected and potentially harmful data, or attacks that result from a flow of too much irrelevant data meant to slow down a network or system, as in the case of a DDoS attack.

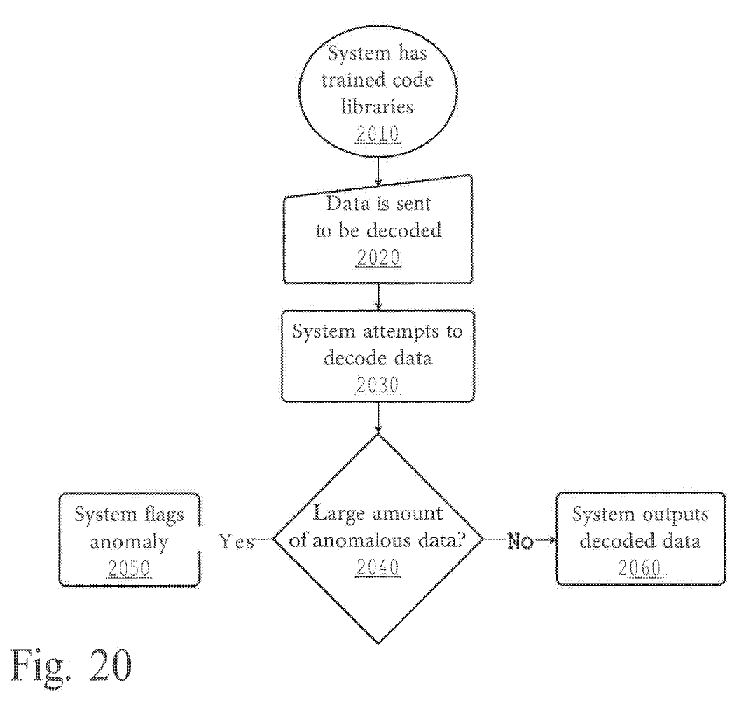

FIG. 20 is a flow diagram of an exemplary method used to detect anomalies in received encoded data and producing a warning. A system may have trained encoding libraries 2010, before data is received from some source such as a network connected device or a locally connected device including USB connected devices, to be decoded 2020. Decoding in this context refers to the process of using the encoding libraries to take the received data and attempt to use encoded references to decode the data into its original source 2030, potentially more than once if recursive encoding was used, but not necessarily more than once. An anomaly detector 1910 may be configured to detect a large amount of un-encoded data 2040 in the midst of encoded data, by locating data or references that do not appear in the encoding libraries, indicating at least an anomaly, and potentially data tampering or faulty encoding libraries. A flag or warning is set by the system 2050, allowing a user to be warned at least of the presence of the anomaly and the characteristics of the anomaly. However, if a large amount of invalid references or unencoded data are not present in the encoded data that is attempting to be decoded, the data may be decoded and output as normal 2060, indicating no anomaly has been detected.

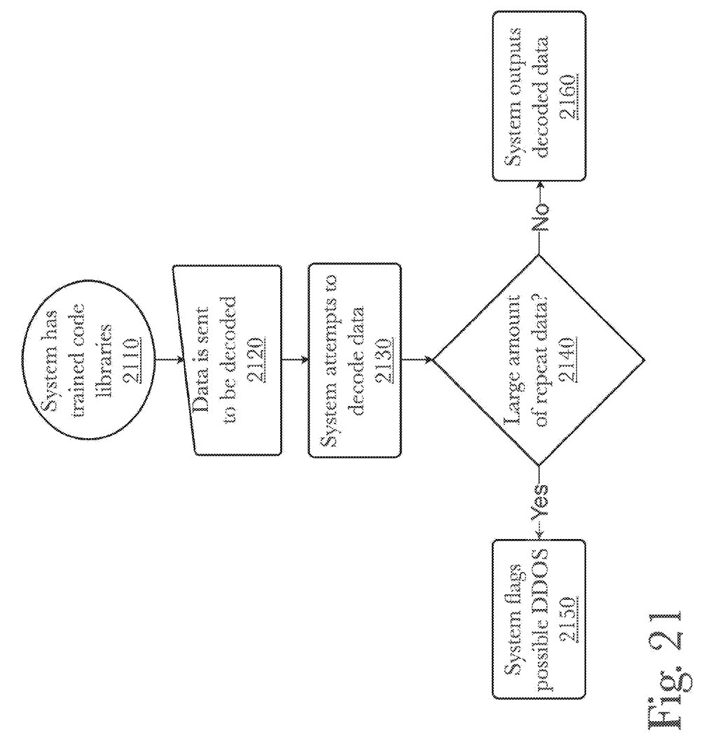

FIG. 21 is a flow diagram of a method used for Distributed Denial of Service (DDoS) attack denial. A system may have trained encoding libraries 2110, before data is received from some source such as a network connected device or a locally connected device including USB connected devices, to be decoded 2120. Decoding in this context refers to the process of using the encoding libraries to take the received data and attempt to use encoded references to decode the data into its original source 2130, potentially more than once if recursive encoding was used, but not necessarily more than once. A DDoS detector 1920 may be configured to detect a large amount of repeating data 2140 in the encoded data, by locating data or references that repeat many times over (the number of which can be configured by a user or administrator as need be), indicating a possible DDoS attack. A flag or warning is set by the system 2150, allowing a user to be warned at least of the presence of a possible DDoS attack, including characteristics about the data and source that initiated the flag, allowing a user to then block incoming data from that source. However, if a large amount of repeat data in a short span of time is not detected, the data may be decoded and output as normal 2160, indicating no DDoS attack has been detected.

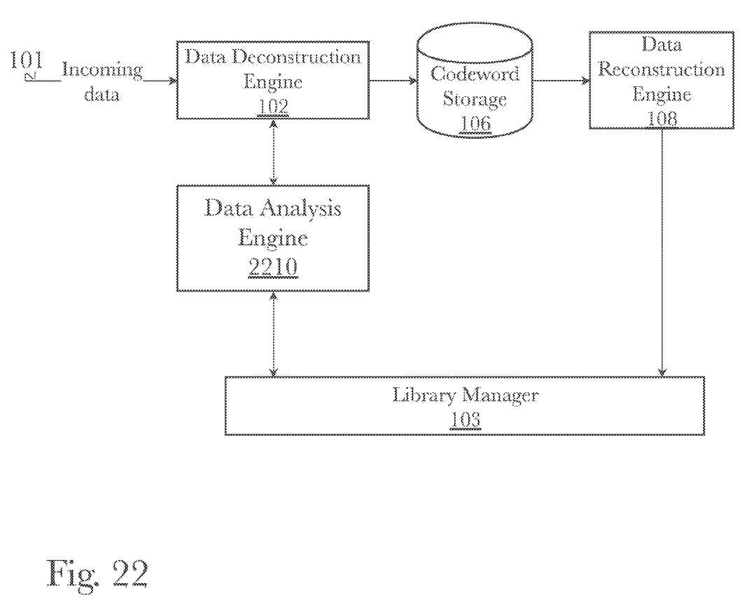

FIG. 22 is an exemplary system architecture of a data encoding system used for data mining and analysis purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. A data analysis engine 2210, typically operating while the system is otherwise idle, sends requests for data to the data reconstruction engine 108, which retrieves the codewords representing the requested data from codeword storage 106, reconstructs them into the data represented by the codewords, and send the reconstructed data to the data analysis engine 2210 for analysis and extraction of useful data (i.e., data mining). Because the speed of reconstruction is significantly faster than decompression using traditional compression technologies (i.e., significantly less decompression latency), this approach makes data mining feasible. Very often, data stored using traditional compression is not mined precisely because decompression lag makes it unfeasible, especially during shorter periods of system idleness. Increasing the speed of data reconstruction broadens the circumstances under which data mining of stored data is feasible.

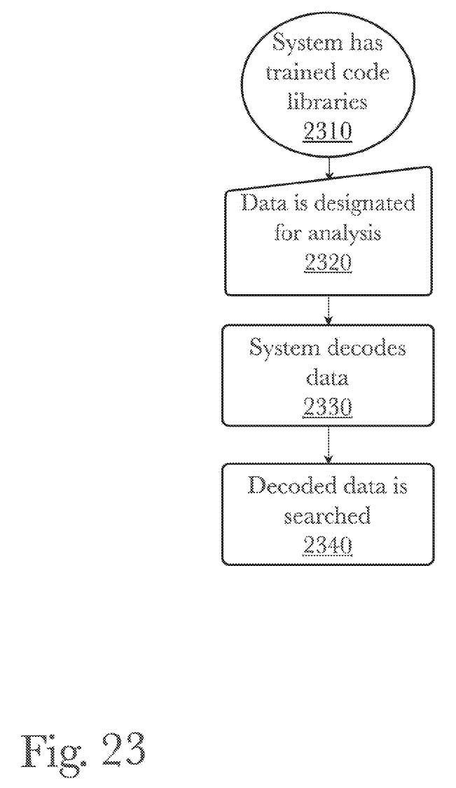

FIG. 23 is a flow diagram of an exemplary method used to enable high-speed data mining of repetitive data. A system may have trained encoding libraries 2310, before data is received from some source such as a network connected device or a locally connected device including USB connected devices, to be analyzed 2320 and decoded 2330. When determining data for analysis, users may select specific data to designate for decoding 2330, before running any data mining or analytics functions or software on the decoded data 2340. Rather than having traditional decryption and decompression operate over distributed drives, data can be regenerated immediately using the encoding libraries disclosed herein, as it is being searched. Using methods described in FIG. 9 and FIG. 11, data can be stored, retrieved, and decoded swiftly for searching, even across multiple devices, because the encoding library may be on each device. For example, if a group of servers host codewords relevant for data mining purposes, a single computer can request these codewords, and the codewords can be sent to the recipient swiftly over the bandwidth of their connection, allowing the recipient to locally decode the data for immediate evaluation and searching, rather than running slow, traditional decompression algorithms on data stored across multiple devices or transfer larger sums of data across limited bandwidth.

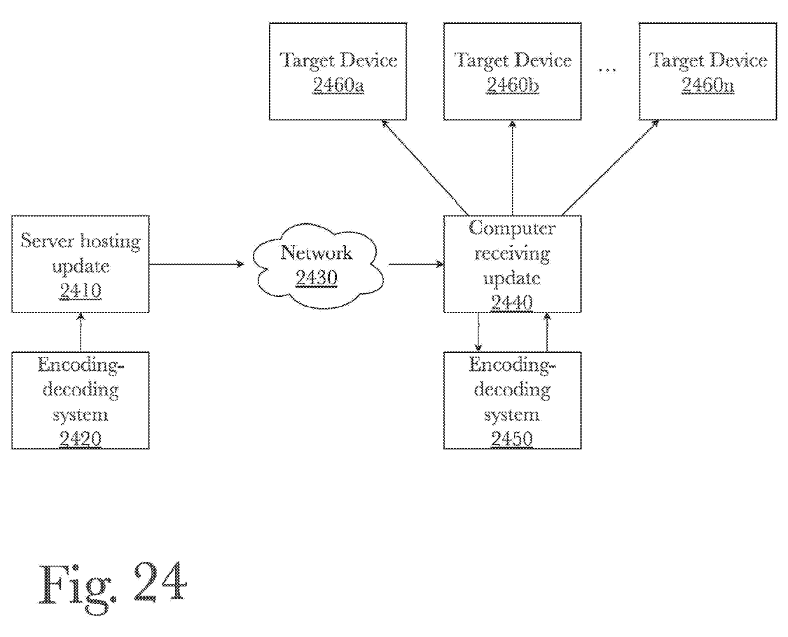

FIG. 24 is an exemplary system architecture of a data encoding system used for remote software and firmware updates. Software and firmware updates typically require smaller, but more frequent, file transfers. A server which hosts a software or firmware update 2410 may host an encoding-decoding system 2420, allowing for data to be encoded into, and decoded from, sourceblocks or codewords, as disclosed in previous figures. Such a server may possess a software update, operating system update, firmware update, device driver update, or any other form of software update, which in some cases may be minor changes to a file, but nevertheless necessitate sending the new, completed file to the recipient. Such a server is connected over a network 2430, which is further connected to a recipient computer 2440, which may be connected to a server 2410 for receiving such an update to its system. In this instance, the recipient device 2440 also hosts the encoding and decoding system 2450, along with a codebook or library of reference codes that the hosting server 2410 also shares. The updates are retrieved from storage at the hosting server 2410 in the form of codewords, transferred over the network 2430 in the form of codewords, and reconstructed on the receiving computer 2440. In this way, a far smaller file size, and smaller total update size, may be sent over a network. The receiving computer 2440 may then install the updates on any number of target computing devices 2460a-n, using a local network or other high-bandwidth connection.

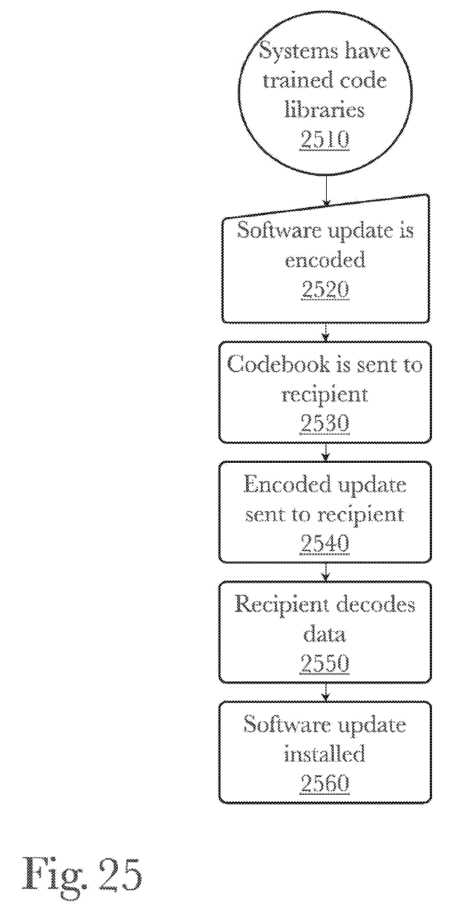

FIG. 25 is a flow diagram of an exemplary method used to encode and transfer software and firmware updates to a device for installation, for the purposes of reduced bandwidth consumption. A first system may have trained code libraries or “codebooks” present 2510, allowing for a software update of some manner to be encoded 2520. Such a software update may be a firmware update, operating system update, security patch, application patch or upgrade, or any other type of software update, patch, modification, or upgrade, affecting any computer system. A codebook for the patch must be distributed to a recipient 2530, which may be done beforehand and either over a network or through a local or physical connection, but must be accomplished at some point in the process before the update may be installed on the recipient device 2560. An update may then be distributed to a recipient device 2540, allowing a recipient with a codebook distributed to them 2530 to decode the update 2550 before installation 2560. In this way, an encoded and thus heavily compressed update may be sent to a recipient far quicker and with less bandwidth usage than traditional lossless compression methods for data, or when sending data in uncompressed formats. This especially may benefit large distributions of software and software updates, as with enterprises updating large numbers of devices at once.

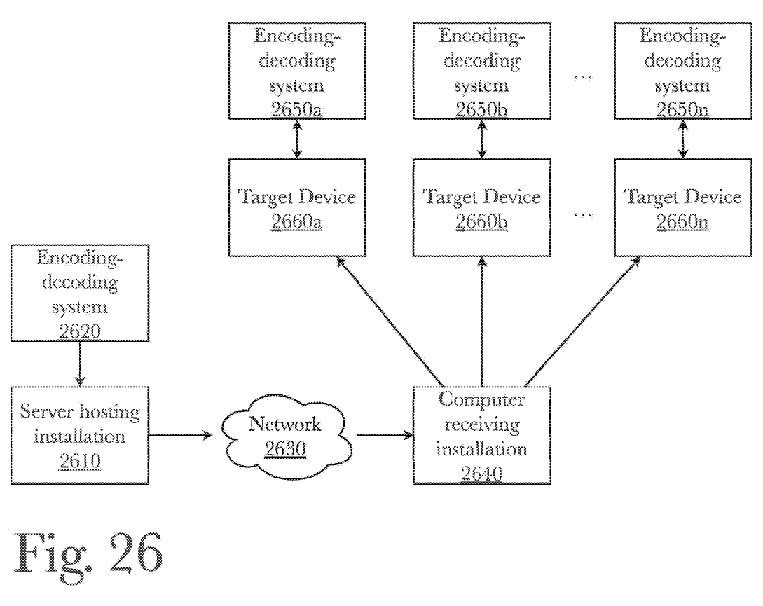

FIG. 26 is an exemplary system architecture of a data encoding system used for large-scale software installation such as operating systems. Large-scale software installations typically require very large, but infrequent, file transfers. A server which hosts an installable software 2610 may host an encoding-decoding system 2620, allowing for data to be encoded into, and decoded from, sourceblocks or codewords, as disclosed in previous figures. The files for the large scale software installation are hosted on the server 2610, which is connected over a network 2630 to a recipient computer 2640. In this instance, the encoding and decoding system 2650a-n is stored on or connected to one or more target devices 2660a-n, along with a codebook or library of reference codes that the hosting server 2610 shares. The software is retrieved from storage at the hosting server 2610 in the form of codewords, and transferred over the network 2630 in the form of codewords to the receiving computer 2640. However, instead of being reconstructed at the receiving computer 2640, the codewords are transmitted to one or more target computing devices, and reconstructed and installed directly on the target devices 2660a-n. In this way, a far smaller file size, and smaller total update size, may be sent over a network or transferred between computing devices, even where the network 2630 between the receiving computer 2640 and target devices 2660a-n is low bandwidth, or where there are many target devices 2660a-n.

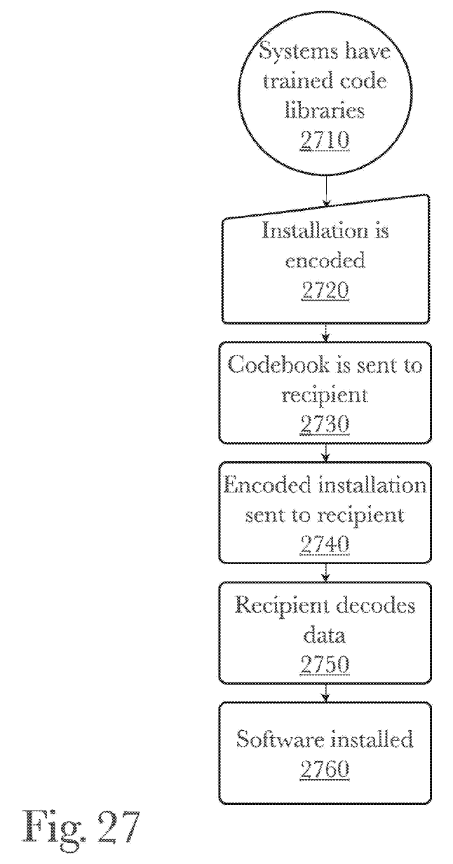

FIG. 27 is a flow diagram of an exemplary method used to encode new software and operating system installations for reduced bandwidth required for transference. A first system may have trained code libraries or “codebooks” present 2710, allowing for a software installation of some manner to be encoded 2720. Such a software installation may be a software update, operating system, security system, application, or any other type of software installation, execution, or acquisition, affecting a computer system. An encoding library or “codebook” for the installation must be distributed to a recipient 2730, which may be done beforehand and either over a network or through a local or physical connection, but must be accomplished at some point in the process before the installation can begin on the recipient device 2760. An installation may then be distributed to a recipient device 2740, allowing a recipient with a codebook distributed to them 2730 to decode the installation 2750 before executing the installation 2760. In this way, an encoded and thus heavily compressed software installation may be sent to a recipient far quicker and with less bandwidth usage than traditional lossless compression methods for data, or when sending data in uncompressed formats. This especially may benefit large distributions of software and software updates, as with enterprises updating large numbers of devices at once.

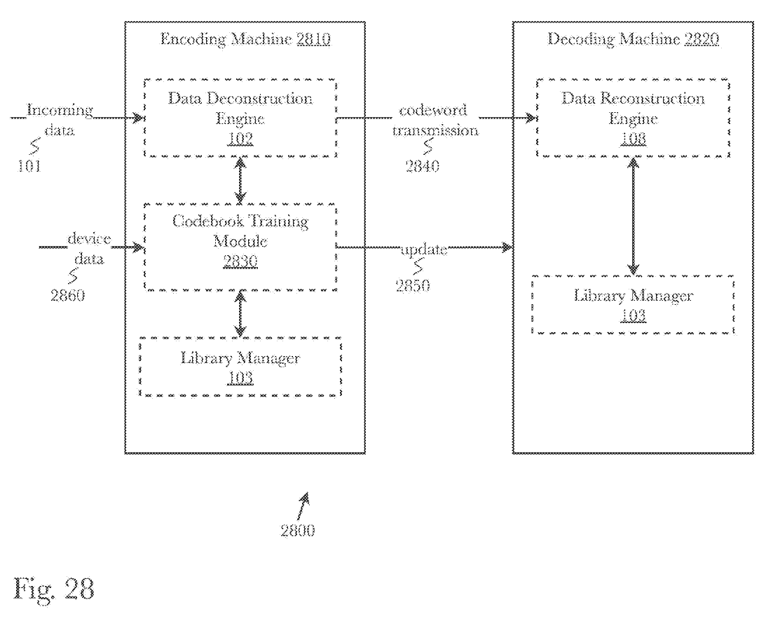

FIG. 28 is a block diagram of an exemplary system architecture 2800 of a codebook training system for a data encoding system, according to an embodiment. According to this embodiment, two separate machines may be used for encoding 2810 and decoding 2820. Much like in FIG. 1, incoming data 101 to be deconstructed is sent to a data deconstruction engine 102 residing on encoding machine 2810, which may attempt to deconstruct the data and turn it into a collection of codewords using a library manager 103. Codewords may be transmitted 2840 to a data reconstruction engine 108 residing on decoding machine 2820, which may reconstruct the original data from the codewords, using a library manager 103. However, according to this embodiment, a codebook training module 2830 is present on the decoding machine 2810, communicating in-between a library manager 103 and a deconstruction engine 102. According to other embodiments, codebook training module 2830 may reside instead on decoding machine 2820 if the machine has enough computing resources available; which machine the module 2830 is located on may depend on the system user’s architecture and network structure. Codebook training module 2830 may send requests for data to the data reconstruction engine 2810, which routes incoming data 101 to codebook training module 2830. Codebook training module 2830 may perform analyses on the requested data in order to gather information about the distribution of incoming data 101 as well as monitor the encoding/decoding model performance. Additionally, codebook training module 2830 may also request and receive device data 2860 to supervise network connected devices and their processes and, according to some embodiments, to allocate training resources when requested by devices running the encoding system. Devices may include, but are not limited to, encoding and decoding machines, training machines, sensors, mobile computing devices, and Internet-of-things (“IoT”) devices. Based on the results of the analyses, the codebook training module 2830 may create a new training dataset from a subset of the requested data in order to counteract the effects of data drift on the encoding/decoding models, and then publish updated 2850 codebooks to both the encoding machine 2810 and decoding machine 2820.

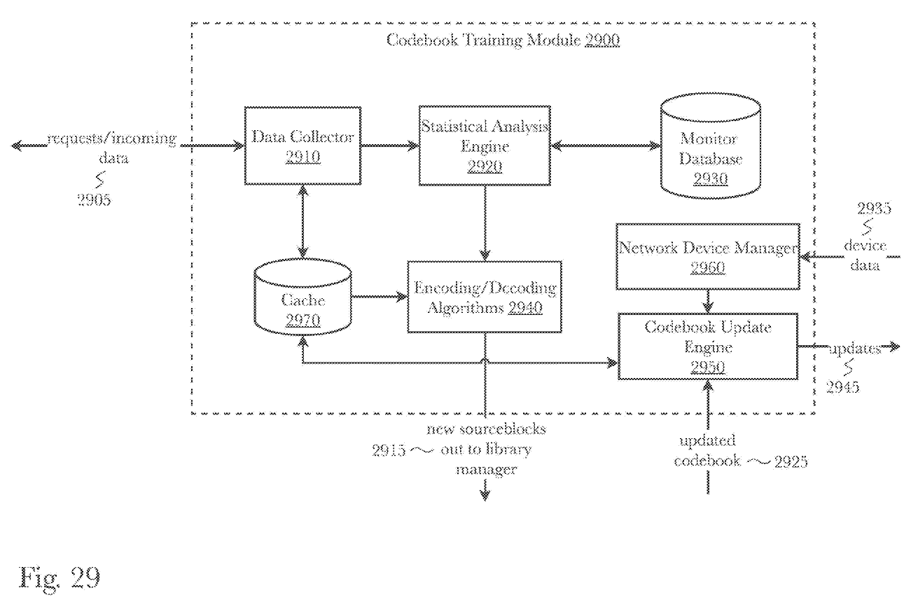

FIG. 29 is a block diagram of an exemplary architecture for a codebook training module 2900, according to an embodiment. According to the embodiment, a data collector 2910 is present which may send requests for incoming data 2905 to a data deconstruction engine 102 which may receive the request and route incoming data to codebook training module 2900 where it may be received by data collector 2910. Data collector 2910 may be configured to request data periodically such as at schedule time intervals, or for example, it may be configured to request data after a certain amount of data has been processed through the encoding machine 2810 or decoding machine 2820. The received data may be a plurality of sourceblocks, which are a series of binary digits, originating from a source packet otherwise referred to as a datagram. The received data may be compiled into a test dataset and temporarily stored in a cache 2970. Once stored, the test dataset may be forwarded to a statistical analysis engine 2920 which may utilize one or more algorithms to determine the probability distribution of the test dataset. Best-practice probability distribution algorithms such as Kullback-Leibler divergence, adaptive windowing, and Jensen-Shannon divergence may be used to compute the probability distribution of training and test datasets. A monitoring database 2930 may be used to store a variety of statistical data related to training datasets and model performance metrics in one place to facilitate quick and accurate system monitoring capabilities as well as assist in system debugging functions. For example, the original or current training dataset and the calculated probability distribution of this training dataset used to develop the current encoding and decoding algorithms may be stored in monitor database 2930.

Since data drifts involve statistical change in the data, the best approach to detect drift is by monitoring the incoming data’s statistical properties, the model’s predictions, and their correlation with other factors. After statistical analysis engine 2920 calculates the probability distribution of the test dataset it may retrieve from monitor database 2930 the calculated and stored probability distribution of the current training dataset. It may then compare the two probability distributions of the two different datasets in order to verify if the difference in calculated distributions exceeds a predetermined difference threshold. If the difference in distributions does not exceed the difference threshold, that indicates the test dataset, and therefore the incoming data, has not experienced enough data drift to cause the encoding/decoding system performance to degrade significantly, which indicates that no updates are necessary to the existing codebooks. However, if the difference threshold has been surpassed, then the data drift is significant enough to cause the encoding/decoding system performance to degrade to the point where the existing models and accompanying codebooks need to be updated. According to an embodiment, an alert may be generated by statistical analysis engine 2920 if the difference threshold is surpassed or if otherwise unexpected behavior arises.

In the event that an update is required, the test dataset stored in the cache 2970 and its associated calculated probability distribution may be sent to monitor database 2930 for long term storage. This test dataset may be used as a new training dataset to retrain the encoding and decoding algorithms 2940 used to create new sourceblocks based upon the changed probability distribution. The new sourceblocks may be sent out to a library manager 2915 where the sourceblocks can be assigned new codewords. Each new sourceblock and its associated codeword may then be added to a new codebook and stored in a storage device. The new and updated codebook may then be sent back 2925 to codebook training module 2900 and received by a codebook update engine 2950. Codebook update engine 2950 may temporarily store the received updated codebook in the cache 2970 until other network devices and machines are ready, at which point codebook update engine 2950 will publish the updated codebooks 2945 to the necessary network devices.

A network device manager 2960 may also be present which may request and receive network device data 2935 from a plurality of network connected devices and machines. When the disclosed encoding system and codebook training system 2800 are deployed in a production environment, upstream process changes may lead to data drift, or other unexpected behavior. For example, a sensor being replaced that changes the units of measurement from inches to centimeters, data quality issues such as a broken sensor always reading 0, and covariate shift which occurs when there is a change in the distribution of input variables from the training set. These sorts of behavior and issues may be determined from the received device data 2935 in order to identify potential causes of system error that is not related to data drift and therefore does not require an updated codebook. This can save network resources from being unnecessarily used on training new algorithms as well as alert system users to malfunctions and unexpected behavior devices connected to their networks. Network device manager 2960 may also utilize device data 2935 to determine available network resources and device downtime or periods of time when device usage is at its lowest. Codebook update engine 2950 may request network and device availability data from network device manager 2960 in order to determine the most optimal time to transmit updated codebooks (i.e., trained libraries) to encoder and decoder devices and machines.

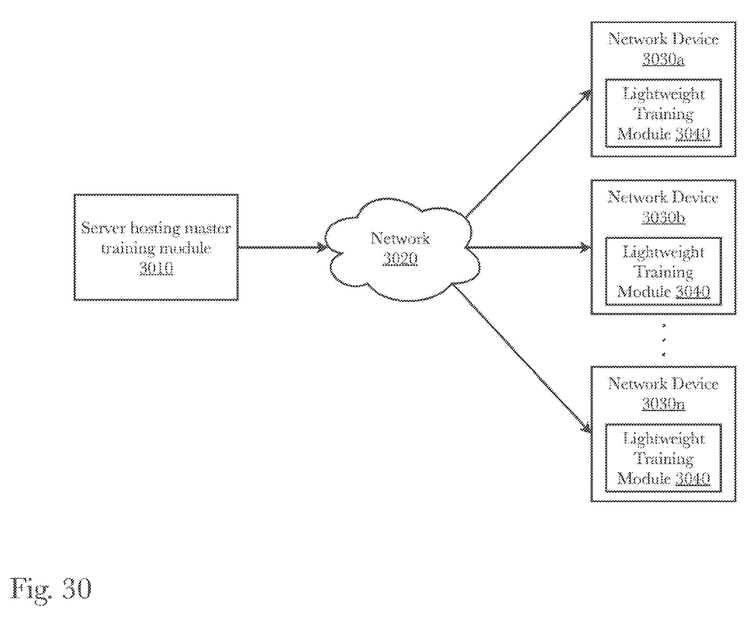

FIG. 30 is a block diagram of another embodiment of the codebook training system using a distributed architecture and a modified training module. According to an embodiment, there may be a server which maintains a master supervisory process over remote training devices hosting a master training module 3010 which communicates via a network 3020 to a plurality of connected network devices 3030a-n. The server may be located at the remote training end such as, but not limited to, cloud-based resources, a user-owned data center, etc. The master training module located on the server operates similarly to the codebook training module disclosed in FIG. 29 above, however, the server 3010 utilizes the master training module via the network device manager 2960 to farm out training resources to network devices 3030a-n. The server 3010 may allocate resources in a variety of ways, for example, round-robin, priority-based, or other manner, depending on the user needs, costs, and number of devices running the encoding/decoding system. Server 3010 may identify elastic resources which can be employed if available to scale up training when the load becomes too burdensome. On the network devices 3030a-n may be present a lightweight version of the training module 3040 that trades a little suboptimality in the codebook for training on limited machinery and/or makes training happen in low-priority threads to take advantage of idle time. In this way the training of new encoding/decoding algorithms may take place in a distributed manner which allows data gathering or generating devices to process and train on data gathered locally, which may improve system latency and optimize available network resources.

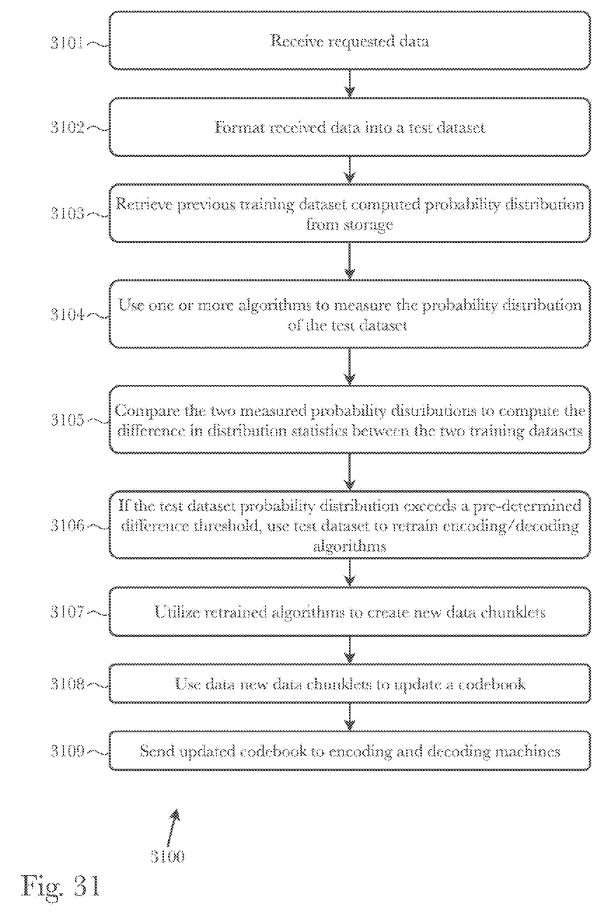

FIG. 31 is a method diagram illustrating the steps 3100 involved in using an embodiment of the codebook training system to update a codebook. The process begins when requested data is received 3101 by a codebook training module. The requested data may comprise a plurality of sourceblocks. Next, the received data may be stored in a cache and formatted into a test dataset 3102. The next step is to retrieve the previously computed probability distribution associated with the previous (most recent) training dataset from a storage device 3103. Using one or more algorithms, measure and record the probability distribution of the test dataset 3104. The step after that is to compare the measured probability distributions of the test dataset and the previous training dataset to compute the difference in distribution statistics between the two datasets 3105. If the test dataset probability distribution exceeds a pre-determined difference threshold, then the test dataset will be used to retrain the encoding/decoding algorithms 3106 to reflect the new distribution of the incoming data to the encoder/decoder system. The retrained algorithms may then be used to create new data sourceblocks 3107 that better capture the nature of the data being received. These newly created data sourceblocks may then be used to create new codewords and update a codebook 3108 with each new data sourceblock and its associated new codeword. Last, the updated codebooks may be sent to encoding and decoding machines 3109 in order to ensure the encoding/decoding system function properly.

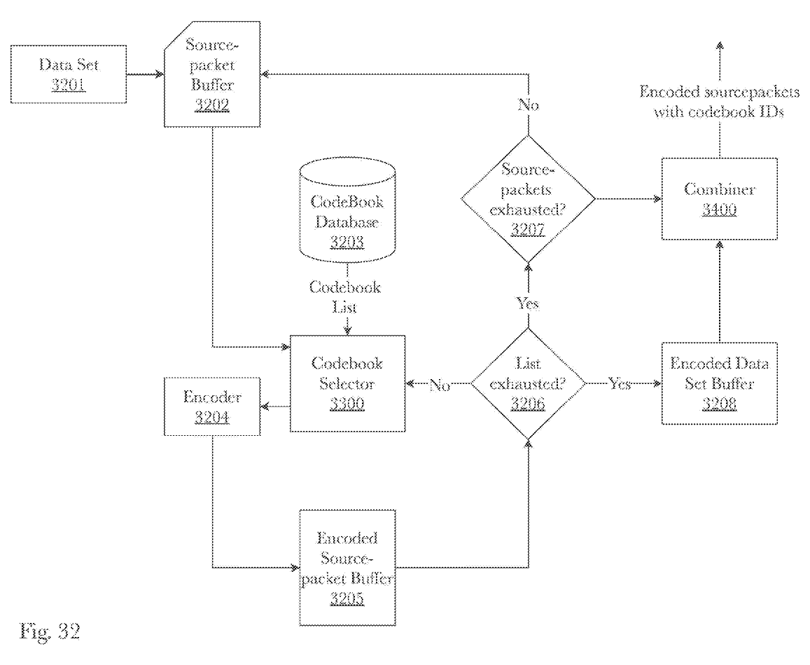

FIG. 32 is an exemplary system architecture for an encoding system with multiple codebooks. A data set to be encoded 3201 is sent to a sourcepacket buffer 3202. The sourcepacket buffer is an array which stores the data which is to be encoded and may contain a plurality of sourcepackets. Each sourcepacket is routed to a codebook selector 3300, which retrieves a list of codebooks from a codebook database 3203. The sourcepacket is encoded using the first codebook on the list via an encoder 3204, and the output is stored in an encoded sourcepacket buffer 3205. The process is repeated with the same sourcepacket using each subsequent codebook on the list until the list of codebooks is exhausted 3206, at which point the most compact encoded version of the sourcepacket is selected from the encoded sourcepacket buffer 3205 and sent to an encoded data set buffer 3208 along with the ID of the codebook used to produce it. The sourcepacket buffer 3202 is determined to be exhausted 3207, a notification is sent to a combiner 3400, which retrieves all of the encoded sourcepackets and codebook IDs from the encoded data set buffer 3208, and combines them into a single file for output.

According to an embodiment, the list of codebooks used in encoding the data set may be consolidated to a single codebook which is provided to the combiner 3400 for output along with the encoded sourcepackets and codebook IDs. In this case, the single codebook will contain the data from, and codebook IDs of, each of the codebooks used to encode the data set. This may provide a reduction in data transfer time, although it is not required since each sourcepacket (or sourceblock) will contain a reference to a specific codebook ID which references a codebook that can be pulled from a database or be sent alongside the encoded data to a receiving device for the decoding process.

In some embodiments, each sourcepacket of a data set 3201 arriving at the encoder 3204 is encoded using a different sourceblock length. Changing the sourceblock length changes the encoding output of a given codebook. Two sourcepackets encoded with the same codebook but using different sourceblock lengths would produce different encoded outputs. Therefore, changing the sourceblock length of some or all sourcepackets in a data set 3201 provides additional security. Even if the codebook was known, the sourceblock length would have to be known or derived for each sourceblock in order to decode the data set 3201. Changing the sourceblock length may be used in conjunction with the use of multiple codebooks.

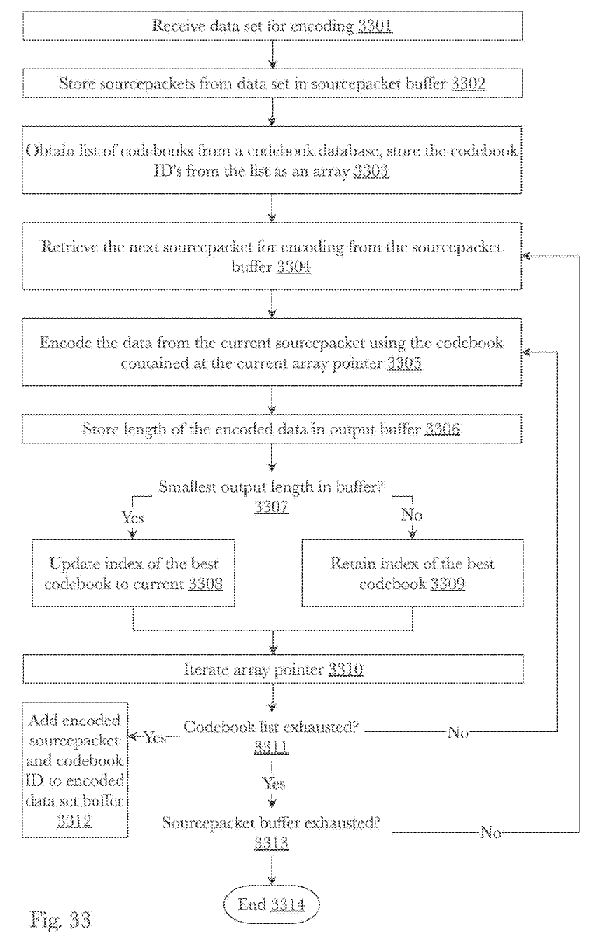

FIG. 33 is a flow diagram describing an exemplary algorithm for encoding of data using multiple codebooks. A data set is received for encoding 3301, the data set comprising a plurality of sourcepackets. The sourcepackets are stored in a sourcepacket buffer 3302. A list of codebooks to be used for multiple codebook encoding is retrieved from a codebook database (which may contain more codebooks than are contained in the list) and the codebook IDs for each codebook on the list are stored as an array 3303. The next sourcepacket in the sourcepacket buffer is retrieved from the sourcepacket buffer for encoding 3304. The sourcepacket is encoded using the codebook in the array indicated by a current array pointer 3305. The encoded sourcepacket and length of the encoded sourcepacket is stored in an encoded sourcepacket buffer 3306. If the length of the most recently stored sourcepacket is the shortest in the buffer 3607, an index in the buffer is updated to indicate that the codebook indicated by the current array pointer is the most efficient codebook in the buffer for that sourcepacket. If the length of the most recently stored sourcepacket is not the shortest in the buffer 3607, the index in the buffer is not updated because a previous codebook used to encode that sourcepacket was more efficient 3309. The current array pointer is iterated to select the next codebook in the list 3310. If the list of codebooks has not been exhausted 3311, the process is repeated for the next codebook in the list, starting at step 3305. If the list of codebooks has been exhausted 3311, the encoded sourcepacket in the encoded sourcepacket buffer (the most compact version) and the codebook ID for the codebook that encoded it are added to an encoded data set buffer 3312 for later combination with other encoded sourcepackets from the same data set. At that point, the sourcepacket buffer is checked to see if any sourcepackets remain to be encoded 3313. If the sourcepacket buffer is not exhausted, the next sourcepacket is retrieved 3304 and the process is repeated starting at step 3304. If the sourcepacket buffer is exhausted 3313, the encoding process ends 3314. In some embodiments, rather than storing the encoded sourcepacket itself in the encoded sourcepacket buffer, a universal unique identification (UUID) is assigned to each encoded sourcepacket, and the UUID is stored in the encoded sourcepacket buffer instead of the entire encoded sourcepacket.

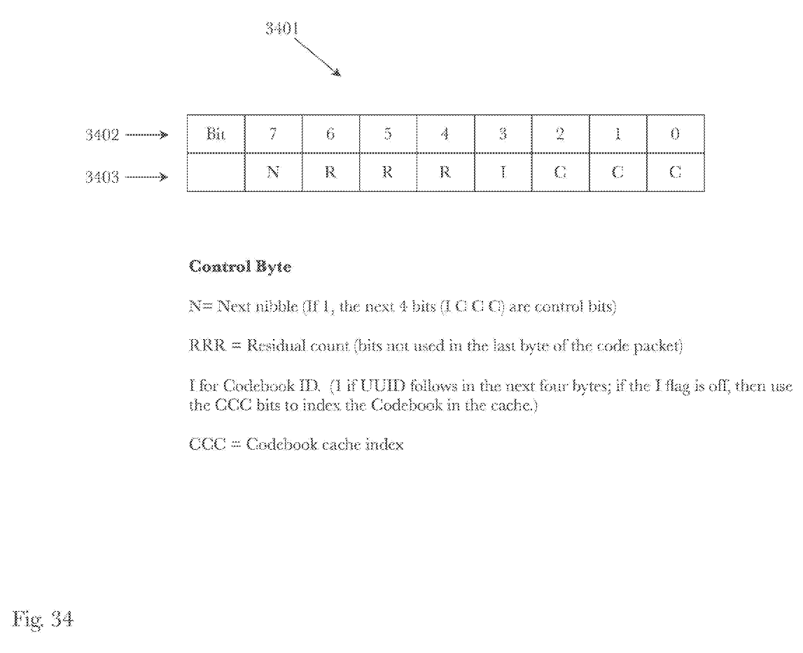

FIG. 34 is a diagram showing an exemplary control byte used to combine sourcepackets encoded with multiple codebooks. In this embodiment, a control byte 3401 (i.e., a series of 8 bits) is inserted at the before (or after, depending on the configuration) the encoded sourcepacket with which it is associated, and provides information about the codebook that was used to encode the sourcepacket. In this way, sourcepackets of a data set encoded using multiple codebooks can be combined into a data structure comprising the encoded sourcepackets, each with a control byte that tells the system how the sourcepacket can be decoded. The data structure may be of numerous forms, but in an embodiment, the data structure comprises a continuous series of control bytes followed by the sourcepacket associated with the control byte. In some embodiments, the data structure will comprise a continuous series of control bytes followed by the UUID of the sourcepacket associated with the control byte (and not the encoded sourcepacket, itself). In some embodiments, the data structure may further comprise a UUID inserted to identify the codebook used to encode the sourcepacket, rather than identifying the codebook in the control byte. Note that, while a very short control code (one byte) is used in this example, the control code may be of any length, and may be considerably longer than one byte in cases where the sourceblocks size is large or in cases where a large number of codebooks have been used to encode the sourcepacket or data set.

In this embodiment, for each bit location 3402 of the control byte 3401, a data bit or combinations of data bits 3403 provide information necessary for decoding of the sourcepacket associated with the control byte. Reading in reverse order of bit locations, the first bit N (location 7) indicates whether the entire control byte is used or not. If a single codebook is used to encode all sourcepackets in the data set, N is set to 0, and bits 3 to 0 of the control byte 3401 are ignored. However, where multiple codebooks are used, N is set to 1 and all 8 bits of the control byte 3401 are used. The next three bits RRR (locations 6 to 4) are a residual count of the number of bits that were not used in the last byte of the sourcepacket. Unused bits in the last byte of a sourcepacket can occur depending on the sourceblock size used to encode the sourcepacket. The next bit I (location 3) is used to identify the codebook used to encode the sourcepacket. If bit I is 0, the next three bits CCC (locations 2 to 0) provide the codebook ID used to encode the sourcepacket. The codebook ID may take the form of a codebook cache index, where the codebooks are stored in an enumerated cache. If bit I is 1, then the codebook is identified using a four-byte UUID that follows the control byte.

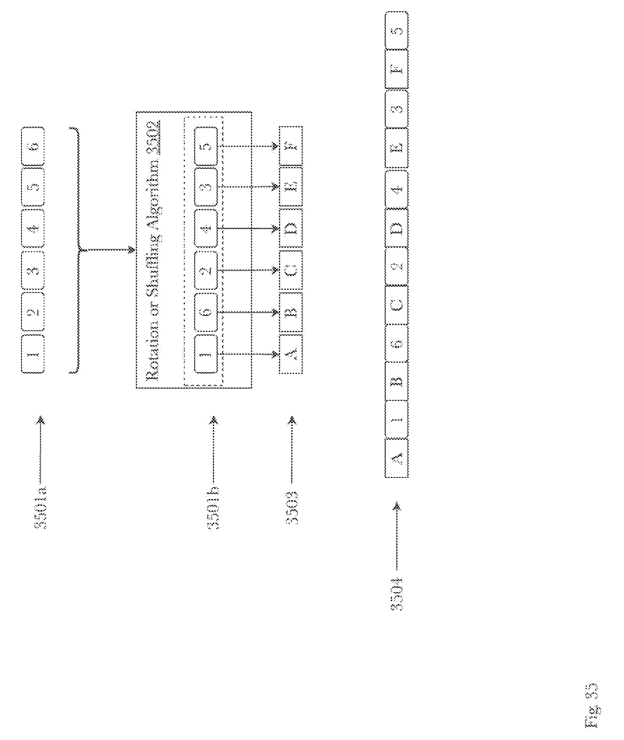

FIG. 35 is a diagram showing an exemplary codebook shuffling method. In this embodiment, rather than selecting codebooks for encoding based on their compaction efficiency, codebooks are selected either based on a rotating list or based on a shuffling algorithm. The methodology of this embodiment provides additional security to compacted data, as the data cannot be decoded without knowing the precise sequence of codebooks used to encode any given sourcepacket or data set.

Here, a list of six codebooks is selected for shuffling, each identified by a number from 1 to 6 3501a. The list of codebooks is sent to a rotation or shuffling algorithm 3502, and reorganized according to the algorithm 3501b. The first six of a series of sourcepackets, each identified by a letter from A to E, 3503 is each encoded by one of the algorithms, in this case A is encoded by codebook 1, B is encoded by codebook 6, C is encoded by codebook 2, D is encoded by codebook 4, E is encoded by codebook 13 A is encoded by codebook 5. The encoded sourcepackets 3503 and their associated codebook identifiers 3501b are combined into a data structure 3504 in which each encoded sourcepacket is followed by the identifier of the codebook used to encode that particular sourcepacket.

According to an embodiment, the codebook rotation or shuffling algorithm 3502 may produce a random or pseudo-random selection of codebooks based on a function. Some non-limiting functions that may be used for shuffling include: 1. given a function f(n) which returns a codebook according to an input parameter n in the range 1 to N are, and given t the number of the current sourcepacket or sourceblock: f(t*M modulo p), where M is an arbitrary multiplying factor (1 <= M <= p-1) which acts as a key, and p is a large prime number less than or equal to N; 2. f(A^t modulo p), where A is a base relatively prime to p-1 which acts as a key, and p is a large prime number less than or equal to N; 3. f(floor(t*x) modulo N), and x is an irrational number chosen randomly to act as a key; 4. f(t XOR K) where the XOR is performed bit-wise on the binary representations of t and a key K with same number of bits in its representation of N. The function f(n) may return the nth codebook simply by referencing the nth element in a list of codebooks, or it could return the nth codebook given by a formula chosen by a user.

In one embodiment, prior to transmission, the endpoints (users or devices) of a transmission agree in advance about the rotation list or shuffling function to be used, along with any necessary input parameters such as a list order, function code, cryptographic key, or other indicator, depending on the requirements of the type of list or function being used. Once the rotation list or shuffling function is agreed, the endpoints can encode and decode transmissions from one another using the encodings set forth in the current codebook in the rotation or shuffle plus any necessary input parameters.

In some embodiments, the shuffling function may be restricted to permutations within a set of codewords of a given length.

Note that the rotation or shuffling algorithm is not limited to cycling through codebooks in a defined order. In some embodiments, the order may change in each round of encoding. In some embodiments, there may be no restrictions on repetition of the use of codebooks.

In some embodiments, codebooks may be chosen based on some combination of compaction performance and rotation or shuffling. For example, codebook shuffling may be repeatedly applied to each sourcepacket until a codebook is found that meets a minimum level of compaction for that sourcepacket. Thus, codebooks are chosen randomly or pseudo-randomly for each sourcepacket, but only those that produce encodings of the sourcepacket better than a threshold will be used.

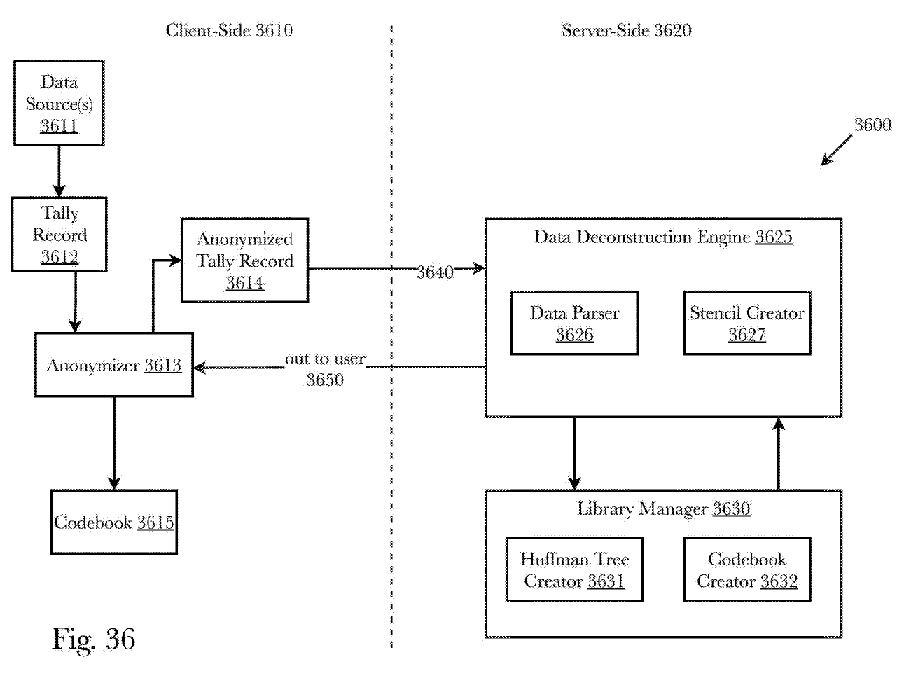

FIG. 36 is a block diagram illustrating an exemplary system architecture 3600 for compacting and encrypting anonymized data, according to an embodiment. According to some embodiments, the system 3600 may be configured in a client-server representation to facilitate and maintain data integrity and privacy by dividing the executable into two pieces: (1) tallies/counts, anonymization and deanonymization, all carried out on the client-side 3610 by the system 3600 user and/or data owner, and (2) codebook construction and optimization which is carried out on the server-side 3620 by system 3600.

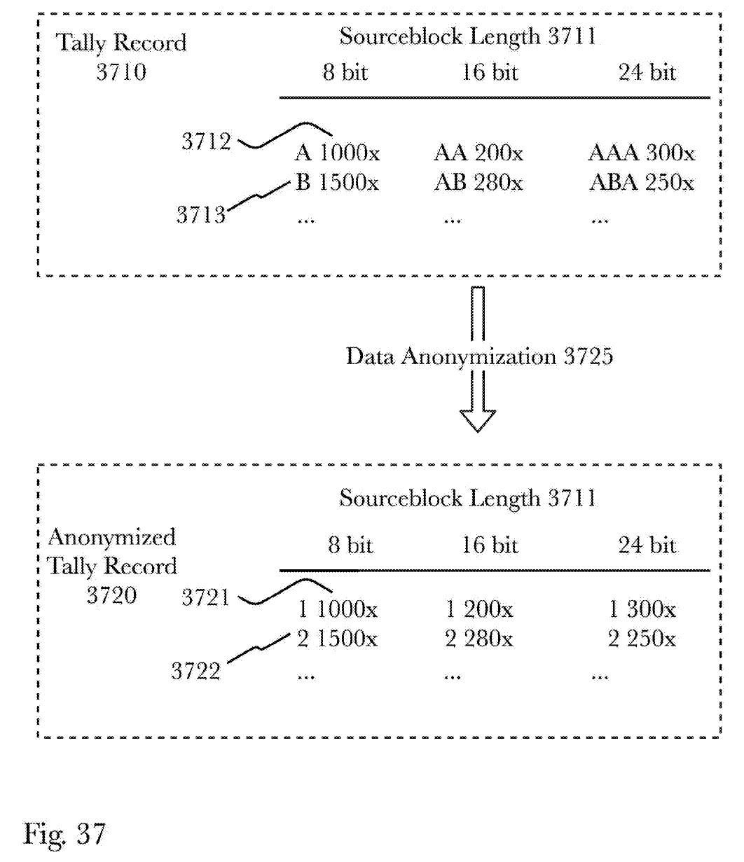

On the client-side 3610 a system 3600 user (or data owner or user, all terms can be understood to represent the same entity and are used interchangeably throughout this disclosure) may have one or more data sources 3611 which may or may not contain information that the user wants to keep private while also taking advantage of the compaction and encryption capabilities of system 3600. The user needs to prepare their data source(s) 3611 prior to sending the data to the server-side 3620. The first data preparation step that the user needs to complete is to collect the substring (i.e., sourceblock) counts of all reasonable lengths. For example, for a given data source the user may choose to divide the data source 3611 into a plurality of sourceblocks of length 8-bits and then count and log each occurrence of each sourceblock until all sourceblocks have been accounted for. Continuing this example, the user may choose to divide the data source 3611 again into a plurality of sourceblocks of length 16-bits and then count and log each occurrence of each sourceblock until all sourceblocks have been accounted for. The user may repeat this process for a given data source(s) 3611 any number of times, using different sourceblock lengths each time. The result of this process is a tally record 3612 which comprises the following information: the sourceblock lengths used to divide the data source; for each data sourceblock length the list of the plurality of sourceblocks, and for each sourceblock a tally of the number of times the sourceblock was counted in the data source 3611. The next step the user needs to perform in order to prepare their data from processing by system 3600 on the server-side 3620 is to anonymize the tally record using an anonymizer 3613. Anonymizer may be configured to both anonymize and deanonymize data according to a data anonymization mechanism selected by the data owner on the client-side 3610. Data anonymization of the tally record 3612 results in an anonymized tally record 3614. The anonymized tally record 3614 may comprise the same information as the tally record 3612 with the only difference being that the sourceblocks are replaced tokens that represent the actual sourceblock data. The anonymized tally record 3614 is fully prepared for data compaction and encryption and may be sent 3640 to a data deconstruction engine 3625 for processing. FIG. 37 shows an exemplary tally record and anonymized tally record, according to an embodiment.

According to some embodiments, on the server-side anonymized data compaction system 3600 may be configured to receive one or more anonymized data sets in the form of an anonymized tally record 3614, the anonymized tally record 3614 may comprise information including, but not limited to, the sourceblock lengths chosen to divide the data source 3611, for each sourceblock length a plurality of tokens (i.e., anonymized data sourceblocks), and for each token a tally (e.g., count or some other indication) of the number of times the data sourceblock represented by the token occurs in the data source 3611. System 3600 may comprise a data deconstruction engine 3625 comprising a record parser 3626 and a stencil creator 3627, and a library manager 3630 comprising a codebook creator 3632 and Huffman tree creator 3631. Data deconstruction engine 3625 may be configured to receive and parse an anonymized tally record 3614 using a data parser 3626 which scans through the received anonymized tally record 3614 in order to identify the token that occurs the most often (i.e., which token has the highest associated tally). According to some embodiments, data parser 3626 may begin parsing the anonymized tally record 3614 starting with the tokens representing the smallest sourceblock length, and once all the tokens for that sourceblock length have been parsed and sent to library manager 3630 the data parser 3626 moves onto the next sourceblock length set of tokens. The identified token may be sent to library manager 3630 for codeword assignment. Data parser 3626 can continue to iterate through the anonymized tally record 3614 to identify the token that has the next highest tally value and send that token to library manager 3630; this process may repeat until each token in the tally record has been parsed and sent to library manager 3630. If two or more tokens have the same tally value, then data parser 3626 may be configured to send the first of the two or more tokens that is identified to library manager 3630.

The token with the highest tally value and all subsequent tokens are sent to library manager 3630 where a Huffman tree creator 3631 may create a first Huffman binary tree based on the tally (occurrences) of each token in the tally record, wherein the topmost binary tree node represents the token with the highest tally value, and a Huffman reference codeword is assigned to each token in the tally record according to the first Huffman binary tree. This process of parsing tokens, Huffman tree creation, and codeword generation is performed for each set of tokens representing different sourceblock lengths. In this way, each sourceblock length set of tokens has its own Huffman tree and corresponding set of reference codes. Codebook creator 3632 may use the codewords created by the Huffman binary tree to create a half-backed codebook comprising a plurality of tokens and for each token a unique codeword. This codebook is referred to as half-backed because it only contains half of the relevant information (the codewords) necessary to encrypt, store, transmit, and decrypt the data source 3611 in compacted form. The missing half of information is the sourceblock associated with each of the codewords, which are represented as tokens in the half-backed codebook. Codebook creator 3632 may also leverage machine learning to optimize the construction of the half-backed codebook, ensuring that the data compaction is the most optimal. For example, codebook creator may use machine learning or some other computational mechanism (e.g., calculating compaction ratio) to identify which sourceblock length resulted in the most optimal compaction after Huffman binary tree creation and codeword assignment, and then select this sourceblock length and its associated tokens/codewords to create a half-backed codebook. According to some embodiments, codebook creator 3632 may be further configured to create a combined half-backed codebook comprising tokens from two or more data sources 3611. A combined half-backed codebook may be comprised of sourceblocks from one data source at one sourceblock length, and sourceblocks from another data source at a different sourceblock length. For example, a first data source may result in optimal compaction using sourceblock lengths of 8-bits, whereas a second data source may result in optimal compaction using sourceblock lengths of 16-bits, and these two data sources may be combined into a half-backed codebook despite not using uniform sourceblock lengths between the two data sources. Once a half-backed codebook has been created it may be sent 3650 back to data owner on the client-side 3610 who can perform deanonymization on the tokens contained in the half-backed codebook, replacing each token with its data sourceblock equivalent. This results in the data owner having in their possession a codebook 3615 comprising a plurality of data sourceblocks and for each sourceblock a unique codeword representing the sourceblock in compacted and encrypted form.

According to some embodiments, a stencil creator 3627 may also be a component of system 3600. Stencil creator 3627 may be configured to create a stencil data structure for a half-backed codebook that contains tokens from two or more data sources. The stencil may contain information or mechanisms for extracting tokens and codewords belonging to one of the two or more data sources that are represented by the tokens contained in the combined half-backed codebook. The created stencil and the half-backed codebook may be transmitted to the data owner on the client-side 3610, wherein the data owner may use the stencil to extract the correct tokens from the combined half-backed codebook in order to create the deanonymized codebook 3615. According to some embodiments, stencil creator 3627 may be configured to create a hybrid stencil that may be used to generate a hybrid synthesized codebook comprising sourceblocks from multiple data sources and for each sourceblock a codeword. The hybrid stencil may be created such that each codeword appears only once in the hybrid synthesized codebook. The use of hybrid stencil allows system 3600 to synthesize codebooks by combining partial results from multiple datasets/data sources. On the client-side 3610 when the user receives a combined half-backed codebook and its stencils or a hybrid synthesized codebook and its hybrid stencil, the user may first deanonymize the received codebook and then use the stencil to extract the correct values into their own codebooks. This results in the formation of the same number of codebooks as the number of data sources 3611 which were used to create the combined half-backed codebook or hybrid synthesized codebook.

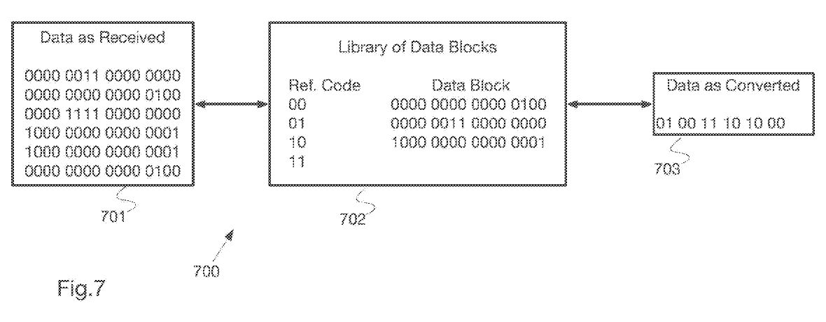

FIG. 7 is a diagram showing an example of how data might be converted into reference codes using an aspect of an embodiment 700. As data is received 701, it is read by the processor in sourceblocks of a size dynamically determined by the previously disclosed sourceblock size optimizer 410. In this example, each sourceblock is 16 bits in length, and the library 702 initially contains three sourceblocks with reference codes 00, 01, and 10. The entry for reference code 11 is initially empty. As each 16 bit sourceblock is received, it is compared with the library. If that sourceblock is already contained in the library, it is assigned the corresponding reference code. So, for example, as the first line of data (0000001100000000) is received, it is assigned the reference code (01) associated with that sourceblock in the library. If that sourceblock is not already contained in the library, as is the case with the third line of data (0000111100000000) received in the example, that sourceblock is added to the library and assigned a reference code, in this case 11. The data is thus converted 703 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding

FIG. 37 is a diagram illustrating an exemplary data source tally record 3710 and its anonymized counterpart 3720, according to some embodiments. The data source may belong to a system 3600 user who wishes to take advantage of the compaction and encryption capabilities of system 3600, but who also wishes to keep their data private. System 3600 can facilitate the compaction of anonymized data. Data source may be prepared for processing by first dividing up the data source into a plurality of sourceblocks at all reasonable lengths, for example at sourceblock lengths 3711 of 8-bits, 16-bits, 24-bits, etc. For instance, the data source may first be broken down into a plurality of sourceblocks 3713 each with a sourceblock length 3711 of 8-bits. Then, the owner of data source can create a log count 3712 (e.g., tally) of the number of times each sourceblock 3713 occurs in data source. After all the sourceblocks have been created and counted, the data source owner (e.g., system 3600 user) can anonymize 3725 the tally record 3710. According to some embodiments, data source may be anonymized using a variety of techniques including, but not limited to, directory replacement, masking out, scrambling/shuffling, generalization, blurring, data encryption, substitution, nulling out, number and date variance, or a custom anonymization technique chosen by data source owner. Because the data anonymization is carried out by the data source owner (e.g., system 3600 user) prior to sending the anonymized tally record 3720 to system 3600 for compaction and encryption, the exact method of data anonymization that is used is variable, dependent upon, and may be specific to a particular user or organization.

After the anonymization 3725 process, the original sourceblocks may be replaced with tokens 3722 acting as stand-ins for the original data. Each token 3722, its associated tally 3721, and the sourceblock length 3711 may be transmitted to system 3600 as an anonymized tally record 3720. System 3600 only requires the information included in the anonymized tally record 3720 in order to compact and encrypt the original source data without needing to be aware of what the original data was. This anonymized tally record 3720 information is enough for system 3600 to construct codebooks for the original source data and can even be used to select the optimal codebook.

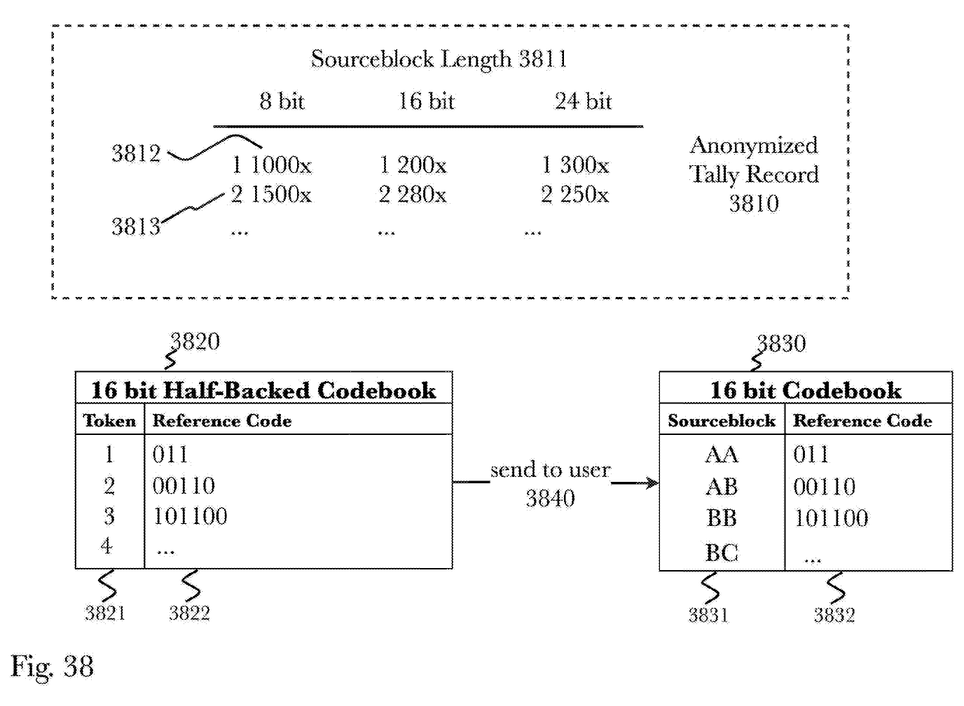

FIG. 38 is a block diagram illustrating an exemplary anonymized tally record 3810 that may be received by system 3600 and an exemplary half-backed codebook 3820 constructed using the information contained in the anonymized tally record 3810. According to some embodiments, an anonymized tally record 3810 may be received by system 3600 from a system user. Anonymized tally record 3810 may comprise an indication of the sourceblock length(s) 3811 used (e.g., 8-bit, 16-bit, 24-bit, etc.), and for each sourceblock length 3811 the anonymized data in the form of tokens 3813 which represent sourceblocks of non-anonymized data, and a tally 3812 or count of the number of times that a sourceblock, represented by token 3813 occurred in the original data source. For example, the anonymized tally record 3810 indicates that the original data source was divided into sourceblocks three different times, each time with a different sourceblock length 3811 (8-bit, 16-bit, and 24-bit). The 8-bit data is indicated as the column of data descending underneath the 8-bit column header, wherein the column has two rows indicating the token 3813 (represented as an integer value) and its associated tally 3813 (represented as an integer value followed by an ‘x’). It should be appreciated that the use of integer values used to represent the tokens 3813 was chosen to simplify this example, and that tokens 3813 may be represented in variety of ways, not limited to only integer representations. Likewise, it should also be appreciated that the tally 3812 or count need not be represented as an integer value followed by an ‘x’. Tally 3812 may be represented as a binary digit, hexadecimal digit, integer, or the like, and that different embodiments and aspects may implement different ways of representing the tally 3812.

According to some embodiments, system 3600 may process the received anonymized tally record 3810 in order to construct a half-backed codebook 3820. Half-backed codebook 3820 may be constructed similarly to regular codebooks, the only difference being that regular codebooks contain a plurality of sourceblocks and for each sourceblock a unique reference code 3822 (i.e., codeword), whereas a half-backed codebook 3820 comprises a plurality of tokens 3821 and for each token a unique reference code 3822. System 3600 performs codebook construction and reference code creation and assignment using the techniques disclosed above (referring to FIG. 36) and throughout this specification, the only difference is that tokens are used in place of sourceblocks.

The exemplary anonymized tally record 3810 of FIG. 38 is comprised of three sets of data; with each set of data corresponding to a sourceblock length 3811 (8-bit, 16-bit, and 24-bit). System 3600 can compact each set of data and then determine which compacted set of data yielded the optimal compaction results. For this example, the set of data associated with sourceblocks of length 16-bits was the most optimal set of data, so the half-backed codebook 3820 associated with that data set will be selected. Once the optimal half-backed codebook 3820 is selected, it may be sent 3840 back to the system user (e.g., customer and/or data source owner). System 3600 user can then deanonymize the tokens contained within the received half-backed codebook 3820 using the reverse of whatever data anonymization technique they used to tokenize the data. The result of this process is that the system 3600 user now has in their possession a codebook 3830 comprising sourceblocks 3831 of their original data and for each sourceblock a reference code 3832 (i.e., codeword) representing a compacted and encrypted form of the sourceblock 3831. In this way, a system 3600 user may be able to keep their data private, but also have the benefit of the data compaction and encryption provided by system 3600.

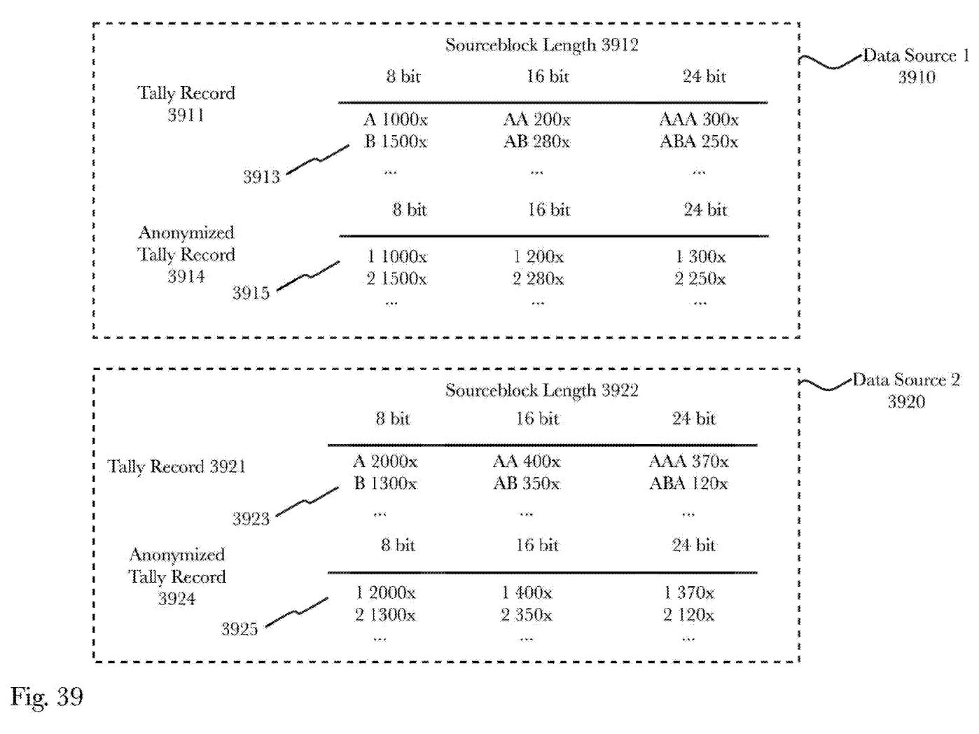

FIG. 39 is a diagram illustrating two exemplary data sources, each of which is shown in non-anonymized tally record and anonymized tally record form. According to some embodiments, system 3600 may receive two or more data sources 3910, 3920 in anonymized tally record form 3914, 3924. Data source 1 3910 may be prepared into a tally record 3911 containing a plurality of token/tally pairs 3913 for different sourceblock lengths 3912. The tally record may be anonymized resulting in an anonymized tally record 3914 comprising a plurality of token/tally pairs 3915 for different sourceblock lengths 3912. Similarly, data source 23920 may be prepared into a tally record 3921 comprising a plurality of sourceblock/tally pairs 3923 for different sourceblock lengths 3922. The tally record 3921 may be anonymized resulting in an anonymized tally record 3924 comprising a plurality of token/tally pairs 3925 for different sourceblock lengths. Both anonymized tally records 3914, 3924 may be sent to system 3600 for data compaction and encryption processing into a combined half-backed codebook.

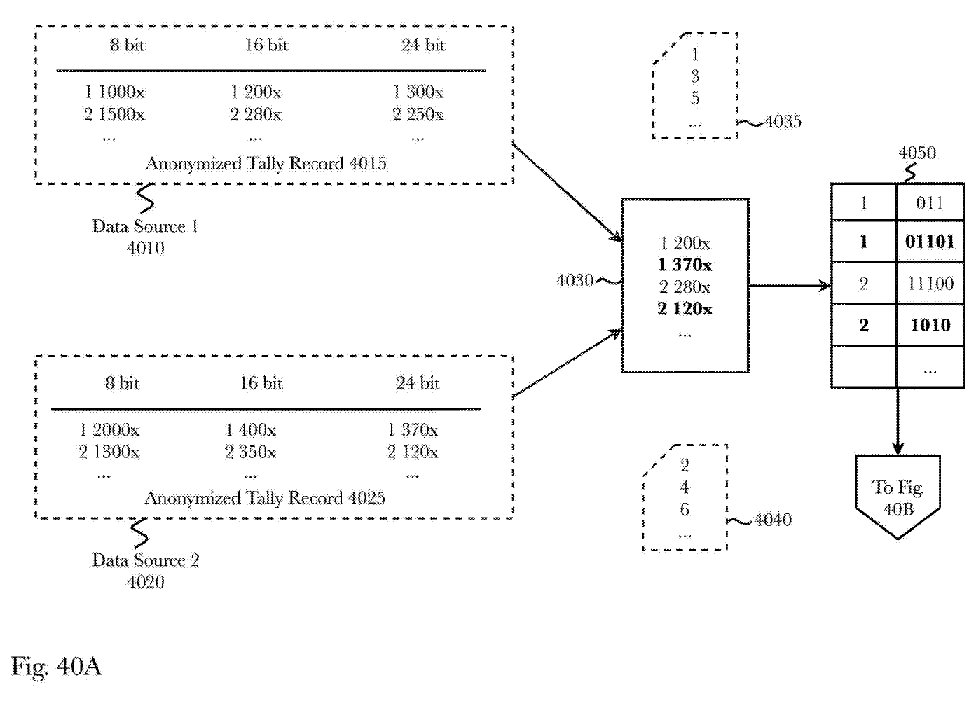

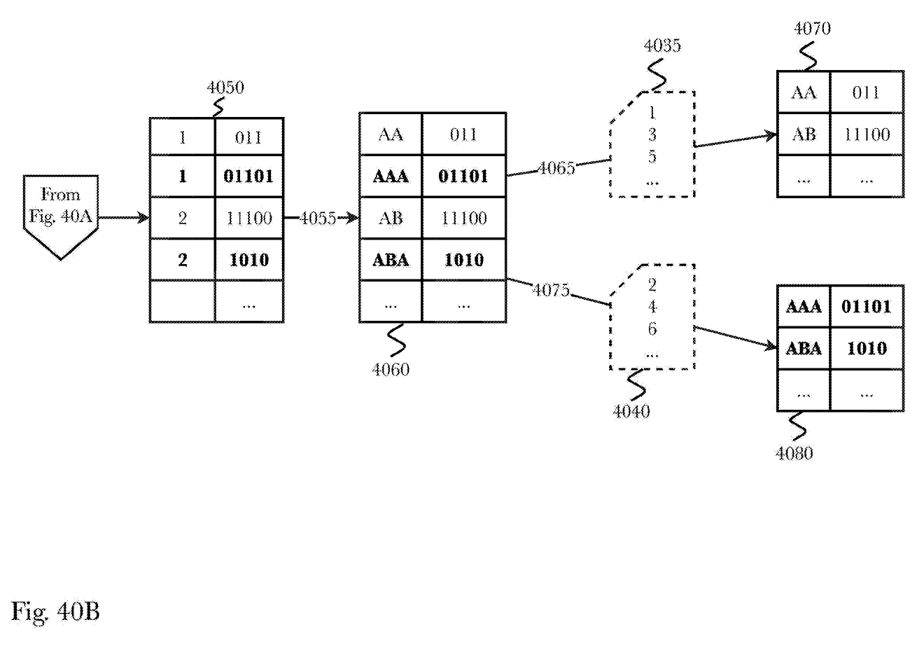

FIG. 40A is diagram illustrating an exemplary process of constructing a half-backed codebook 4050 using two data sources 4010, 4020 and data source stencils 4035, 4040, according to some embodiments. The anonymized tally records 4015, 4025 associated with data source 14010 and data source 24020 each contain three sets of data corresponding to three different sourceblock lengths (8-bit, 16-bit, 24-bit). Each set of data may be compacted and the optimally (e.g., best compaction) compacted data set from each data source may be selected for half-backed codebook creation. For example, consider the 16-bit data set from data source 14010 as the most optimal set from data source 1 4010, and the 24-bit data set from data source 24020 as the most optimal set from data source 24020. Each of these two sets of data with the best compaction may combined into a single data structure 4030 comprising tokens and for each token its tally. According to some embodiments, each of the two sets of data may have an accompanying stencil 4035, 4040 that is created which can be used to extract the appropriate data values from the combined data structure 4030. As illustrated, the combined data structure comprises tokens taken from the 16-bit data set of data source 14010 and stores these values in the odd-numbered positions of the combined data structure 4030 starting with the first position using one-based indexing. In some embodiments, the data structure may use zero-based indexing. The stencil 4035 associated with data source 14010 lists the positions (e.g., 1, 3, 5, 7,… etc.) in the combined data structure 4030 which correspond to token/count combinations that originated from data source 14010. The 24-bit data set from data source 24020 may be added to the combined data structure 4030 in even-numbered positions starting with position 2 (indicated by the bolded values in combined data structure 4030). The stencil 4040 associated with data source 24020 lists the positions (e.g., 2, 4, 6,… etc.) in the combined data structure 4030 which correspond to token/count combinations that originated from data source 24020. The combined data structure 4030 may be passed to library manager 3630 in order to compact and encrypt the data contained within combined data structure 4030 to construct a combined half-backed codebook 4050 comprising data from two different data sources. Once a combined half-backed codebook 4050 is constructed, the combined half-backed codebook 4050 and any stencils 4035, 4040 may be transmitted back to the owner of the data sources where the combined half-backed codebook 4050 may be transformed into a full-fledged codebook, as discussed in FIG. 40B.

FIG. 40B is a diagram illustrating an exemplary process of transforming a combined half-backed codebook 4050 comprising data from two different data sources using data source stencils 4035, 4040 according to some embodiments. According to some embodiments, a system user and/or data owner may receive from the system 3600 a combined half-backed codebook 4050 and any associated data source stencils 4035, 4040. The data owner can deanonymize 4055 the tokens stored within the combined half-backed codebook 4050 by replacing the tokenized data values with the original data values (sourceblocks) that existed prior to anonymization 4060. This results in transforming the combined half-backed codebook 4050 into a standard codebook 4070, 4080 comprising a plurality of sourceblocks of data and for each sourceblock a reference code (i.e., codeword). However, because this combined half-backed codebook 4050 contains data from two different data sources, it requires the use 4065, 4075 of the accompanying received stencils 4035, 4040 in order to deconstruct the combined half-backed codebook 4050 into two separate codebooks 4070, 4080, each of which is associated with its original data sources. As a result, the system user and/or data owner now has a means to store and/or transmit the original data sources 4010, 4020 in a compacted and encrypted format without disclosing the contents/values of the original data sources.

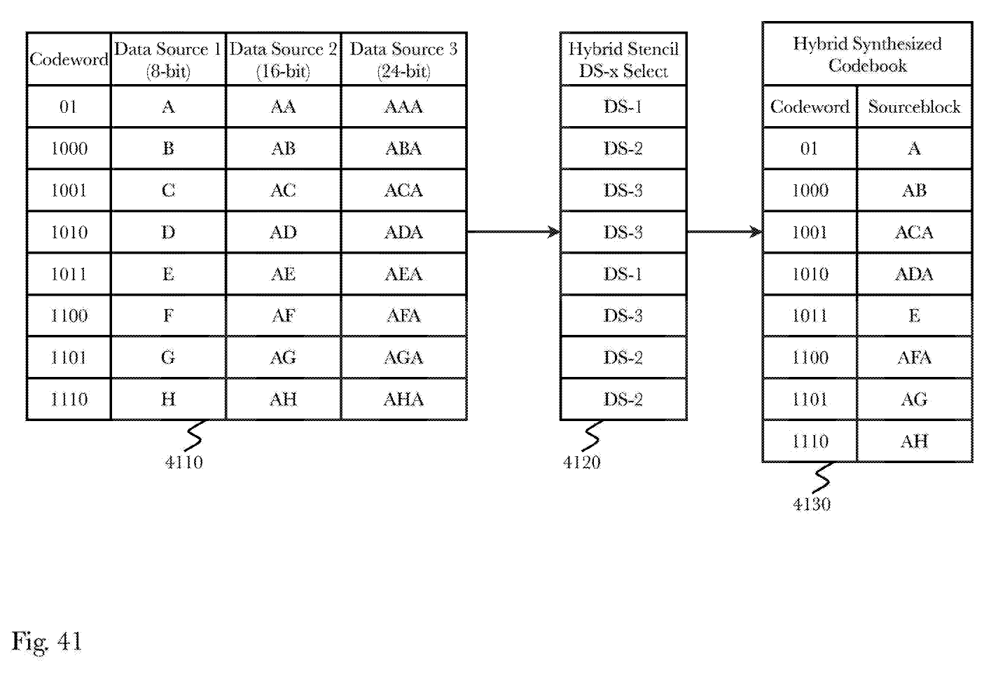

FIG. 41 is a diagram illustrating an exemplary hybrid stencil constructed using three different data sources, according to some embodiments. According to some embodiments, hybrid stencils 4120 may be used to synthesize codebooks by combining partial results from multiple datasets 4110. This may be done dynamically at runtime, requiring transmission or storage only of the hybrid stencil 4120, which is generally smaller in size than the codebook. Hybrid stencils 4120 can only use each codeword once. Using a hybrid stencil 4120 results in the construction of a hybrid synthesized codebook 4130.

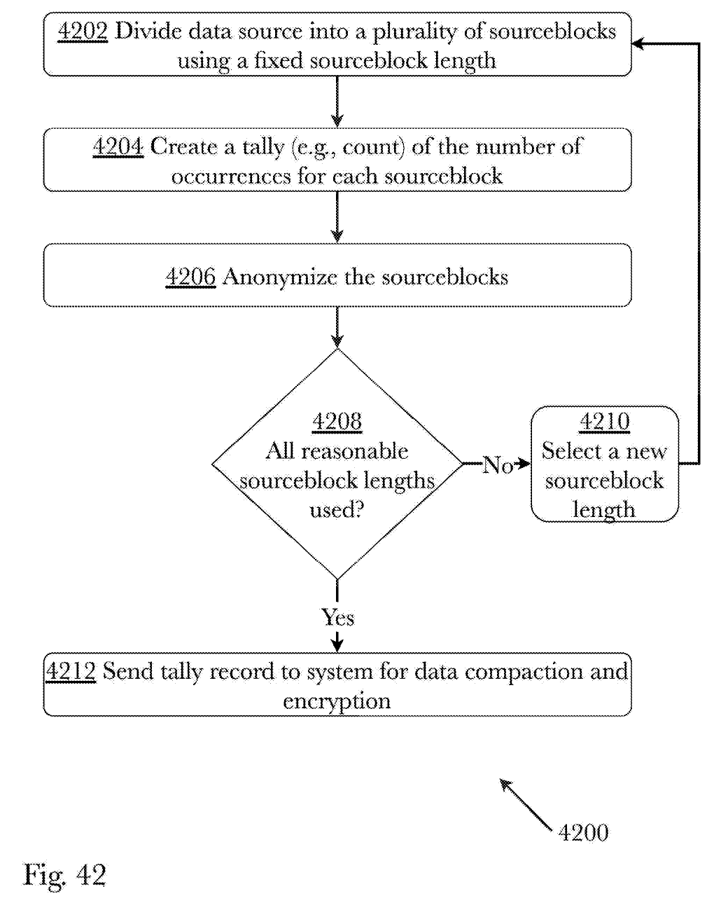

FIG. 42 is an exemplary flow diagram for a method 4200 of preparing an anonymized tally record, according to some embodiments. According to some embodiments, the process is carried out by a data owner and/or system 3600 user prior to sending an anonymized tally record to system 3600 for data compaction and encryption. The process begins at step 4202 by dividing the data source into a plurality of sourceblocks using a fixed sourceblock length (e.g., 8-bits, 16-bits, etc.). As a next step 4204, create a tally (e.g., count) of the number of occurrences for each sourceblock. After this step, the data owner should now have a tally record comprising a plurality of sourceblocks and for each sourceblock a tally value. The next step 4206 is to anonymize the sourceblocks within the tally record using a data anonymization technique or mechanism chosen by the data owner. The next step is to check 4208 whether all reasonable sourceblock lengths have been selected for dividing the data source into a plurality of sourceblocks. If not all reasonable sourceblock lengths have been used, a new sourceblock length is selected 4210 and the process returns to step 4202 until all reasonable sourceblock lengths have been iterated through. At that point, the last step 4212 is to send the anonymized tally record to system 3600 for data compaction and encryption via codebook construction and optimization.

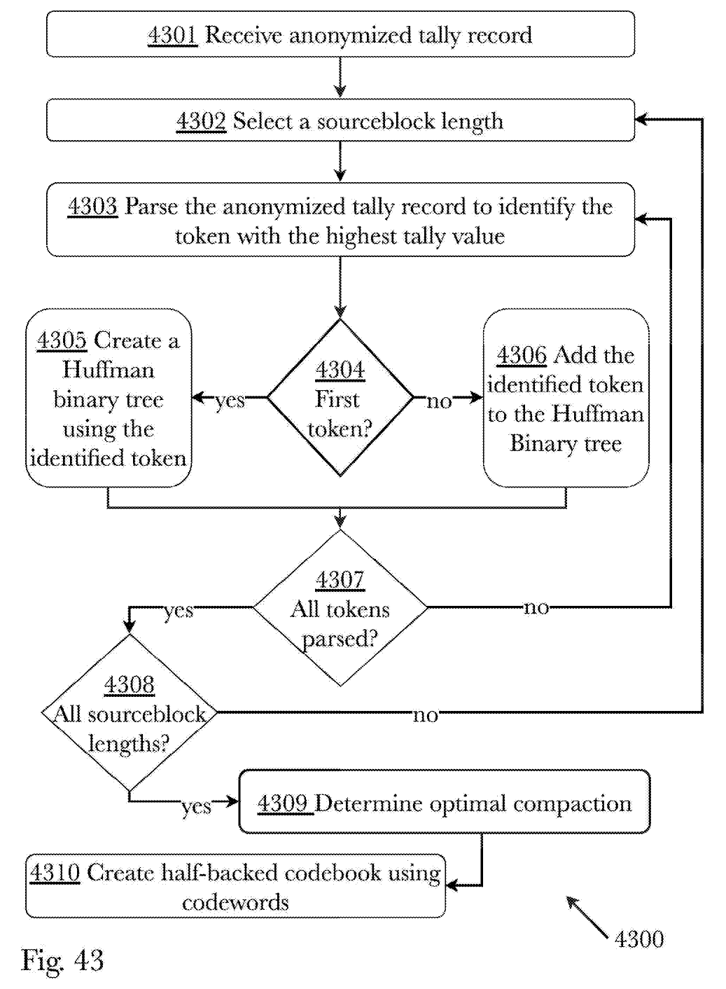

FIG. 43 is an exemplary flow diagram for a method 4300 for constructing a half-backed codebook using a received anonymized tally record, according to some embodiments. According to some embodiments, the process begins with step 4301 when system 3600 receives an anonymized tally record. At the next step 4302, a data parser 3626 may be configured to select a sourceblock length from the available options of sourceblock lengths provided by the anonymized tally record. Then, data parser 3626 may parse the anonymized tally record to identify the token with the highest tally value. Additionally, when a token is identified it may be temporarily removed (or flagged) from the anonymized tally record so that as data parser 3626 iterates through the anonymized tally record it does not identify the same token twice. The next step determines if the identified token was the first token (i.e., the token with the highest tally value) 4304. If the identified token is the first token, then it may be sent to library manager 3630 where Huffman tree creator 3631 can create a Huffman binary tree using the identified first token with the highest tally value as the starting point for the binary tree 4305 and assigned a codeword. If instead, the identified token is not the first token then it is simply added to the Huffman binary tree and assigned a codeword 4306. After a Huffman binary tree creation or after adding a token to the Huffman tree, the next step 4307 checks if all the tokens associated with a given sourceblock length have been parsed. If not all the tokens have been parsed then the process repeats itself starting with step 4303. Instead, if all tokens have been parsed, then another check occurs 4308 which determines if all sourceblock lengths contained in the received anonymized tally record have been processed. If not all sourceblock lengths have been processed then the process repeats itself starting with step 4302. However, if all sourceblock lengths have been processed then codebook creator 3632 may 4309 optimize and/or determine which sourceblock length resulted in the most optimal (e.g., best compaction ratio, etc.) compaction. Then as a last step 4310, the codebook creator 3632 may create a half-backed codebook using determined sourceblock length assigned codewords.

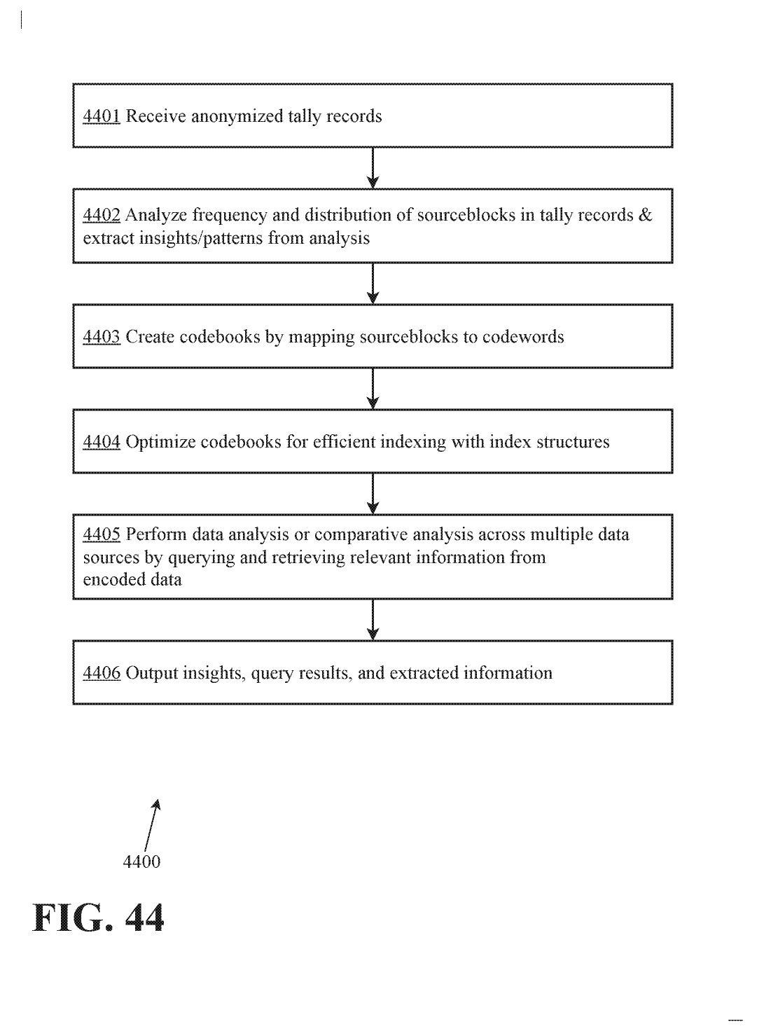

FIG. 44 is a flowchart illustrating the steps 4400 involved in the data analysis and indexing process using anonymized tally records and codebooks in an embodiment. The process begins with receiving the anonymized tally records as input 4401. These tally records are then analyzed to determine the frequency and distribution of sourceblocks within the dataset 4402. This analysis step allows for extracting valuable insights and patterns from the data. Next, the codebooks are created by mapping the sourceblocks to codewords 4403, which enables efficient data compression and encryption. The codebooks are further optimized to facilitate effective indexing 4404. This optimization step involves creating suitable indexing structures, such as inverted indexes or hash tables, which enable fast search and retrieval operations on the encoded data. With the optimized codebooks and indexes in place, various data analysis tasks can be performed 4405. These tasks include querying and retrieving relevant information from the encoded data, as well as conducting comparative analysis across multiple data sources. The results of the data analysis, including insights, query results, and extracted information, are produced as output 4406.

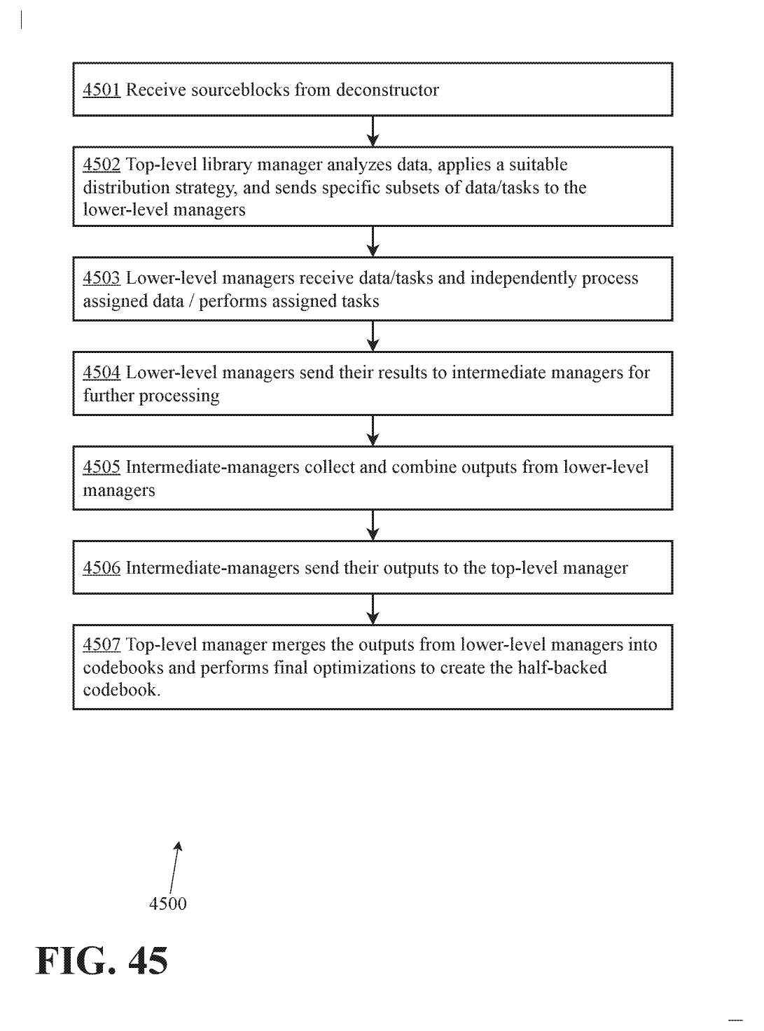

FIG. 45 is a flowchart illustrating the steps 4500 involved of the hierarchical library manager. The top-level library manager receives anonymized codeblocks 4501, analyzes the sourceblocks, and applied a suitable distribution strategy before sending the data to the lower-level managers 4502. These lower-level managers independently process their assigned sourceblocks, applying specific optimization techniques such as assigning codewords, creating partial codebooks, or performing local optimizations 4503. Once the lower-level managers have completed their processing, they send their intermediate results, which may include partially optimized codebooks or relevant metadata, to the intermediate-level library managers 4504. The intermediate-level managers collect and consolidate these results from multiple lower-level managers, combining them into more comprehensive codebooks or datasets. They may further refine and optimize the consolidated codebooks by applying additional techniques to improve efficiency or remove redundancies 4505. The intermediate-level managers then pass the refined codebooks to the top-level library manager 4506. The top-level manager, sitting at the root of the hierarchy, receives the consolidated codebooks from the intermediate-level managers and performs final optimizations 4507. This may involve merging codebooks, eliminating duplicates, or applying global optimization techniques to create the final, optimized codebook, such as the half-backed codebook, representing the entire dataset. The top-level manager may also make high-level decisions, such as determining the optimal sourceblock length or selecting the most efficient codebook structure. Finally, the top-level manager prepares the optimized codebook for further use, such as storage or transmission, completing the hierarchical processing of sourceblocks within the library manager system.

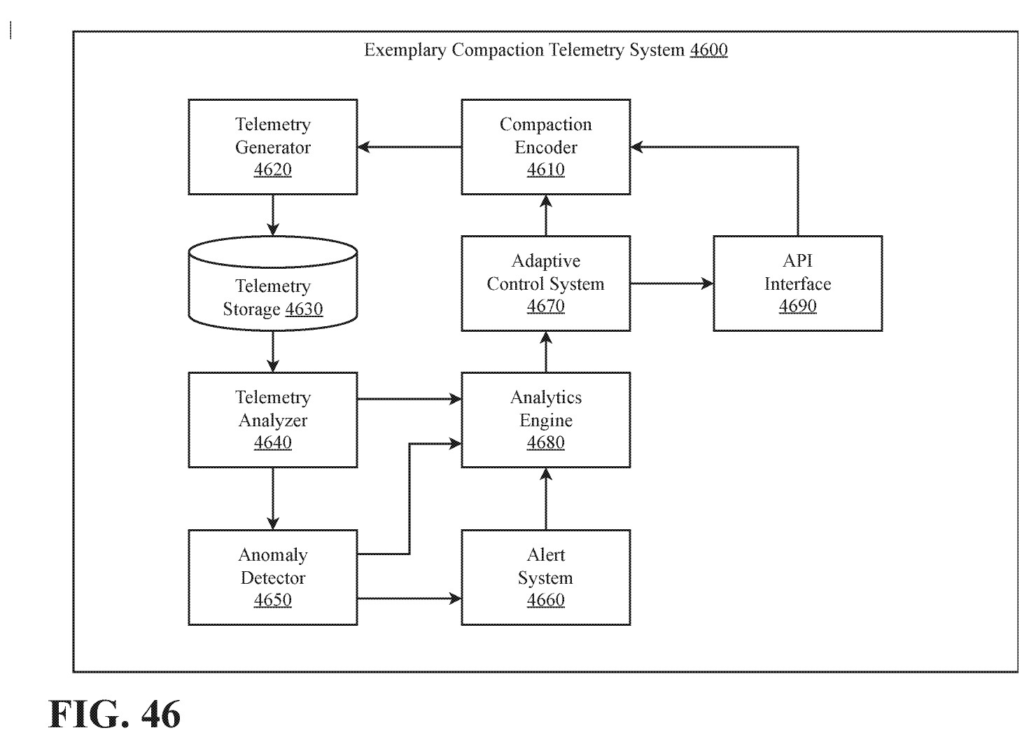

FIG. 46 is a block diagram illustrating an exemplary compaction telemetry system 4600 for generating, analyzing, and acting upon compaction-derived telemetry in anonymized data processing systems. Compaction telemetry system 4600 comprises a plurality of interconnected components that generate, analyze, and operate on quantitative and qualitative measurements derived during the operation of an anonymized data compaction system, including during tally parsing, codebook construction, codeword assignment, encoding, decoding, and optimization processes. All telemetry generated by compaction telemetry system 4600 is derived solely from anonymized compaction operations and system behavior, wherein at no point is underlying plaintext data reconstructed, inspected, or accessed, thereby preserving privacy guarantees of anonymized encoding systems and maintaining compatibility with regulatory and contractual data protection requirements.

Compaction encoder 4610 represents a component configured to process incoming data units using existing codebooks to perform live encoding and decoding operations on anonymized data. During encoding operations, compaction encoder 4610 records operational metrics associated with encoding and decoding behavior, including frequency of successful codeword matches, frequency and distribution of mismatches, rate of invocation of hybrid or fallback encoding mechanisms, encoding latency or throughput measurements, residual data sizes following encoding, and effectiveness of selected sourceblock lengths during live operation. Compaction encoder 4610 may also generate telemetry during codebook construction and optimization, recording operational characteristics such as ordering statistics of anonymized tokens by frequency or weight, depth and structure of generated Huffman or equivalent trees, number of tokens processed per sourceblock length, convergence characteristics of codebook optimization, time required to generate or update a codebook, and relative compaction efficiency achieved for different sourceblock lengths. Telemetry generated by compaction encoder 4610 may be associated with individual data packets, sessions, endpoints, or time intervals, depending on system configuration.

Telemetry generator 4620 represents a component configured to generate and collect compaction telemetry according to one or more sampling strategies. In some embodiments, telemetry generator 4620 samples telemetry at fixed time intervals, while in other embodiments, telemetry is generated in response to events such as detection of compaction failure, threshold crossings, or codebook updates. Telemetry generator 4620 may also employ adaptive sampling strategies in which telemetry generation frequency is increased or decreased based on observed system stability, anomaly likelihood, or available computational resources. Each instance of generated compaction telemetry may be associated with contextual metadata such as an endpoint identifier, dataset identifier, session identifier, timestamp, or operational state indicator, wherein such associations enable subsequent aggregation, comparison, and analysis of telemetry across time and across multiple endpoints. Association and tagging of telemetry data performed by telemetry generator 4620 does not require disclosure of underlying data content and may be performed using identifiers already present within anonymized compaction systems.

Telemetry storage 4630 represents a component configured to store compaction telemetry vectors locally at an endpoint, transmit such vectors to a remote analytics system, or both. Telemetry storage 4630 aggregates compaction telemetry generated during codebook construction, encoding, and decoding to form one or more compaction telemetry vectors associated with a specific endpoint, wherein each compaction telemetry vector may represent telemetry collected over a defined time interval, session, workload, or operational phase. Telemetry values contributing to a compaction telemetry vector may be normalized, weighted, or transformed prior to aggregation through transformations including scaling, smoothing, binning, or dimensionality reduction. As these transformations do not have access to the unencoded data, the transformations do not introduce any dependency on underlying unencoded data. In some embodiments, telemetry storage 4630 constructs compaction telemetry vectors as time-series data structures, wherein successive vectors corresponding to adjacent or overlapping time intervals are stored and analyzed to capture temporal trends in compaction behavior, thereby enabling detection of gradual or abrupt changes in system behavior including changes in data characteristics, encoding effectiveness, or security posture. Transmission of telemetry vectors by telemetry storage 4630 may occur over secure channels and may be subject to additional anonymization or aggregation prior to transmission, wherein because telemetry vectors do not contain underlying data content or reconstructive information, their storage and transmission pose reduced privacy and security risks relative to traditional data analytics.

Telemetry analyzer 4640 represents a component configured to interpret compaction telemetry vectors in order to infer operational, behavioral, and security-relevant conditions associated with anonymized data processing without reconstructing or accessing underlying data content. Telemetry analyzer 4640 establishes one or more baseline compaction profiles for an endpoint, dataset, or operational context, wherein a baseline compaction profile represents an expected range or distribution of compaction telemetry vectors under normal or previously observed conditions. Baseline compaction profiles may be established using historical telemetry data, training datasets, configuration parameters, or adaptive learning techniques, and baselines may be static, periodically refreshed, or continuously updated to reflect evolving system behavior. Telemetry analyzer 4640 compares observed compaction telemetry vectors against corresponding baseline compaction profiles to detect deviations including absolute differences, proportional differences, or statistically significant departures from expected values. In some embodiments, interpretation of compaction telemetry by telemetry analyzer 4640 includes analysis of changes over time through computation of first-order derivatives representing rates of change in telemetry values, second-order derivatives representing acceleration or deceleration of change, or higher-order temporal features, thereby enabling detection of gradual drift, sudden transitions, oscillatory behavior, or other dynamic patterns in compaction behavior that may not be apparent from instantaneous telemetry vectors alone.

Anomaly detector 4650 represents a component configured to perform deviation detection using threshold-based methods, statistical hypothesis testing, machine learning models, or combinations thereof, wherein detected deviations may be classified according to severity, persistence, or confidence level. Anomaly detector 4650 interprets changes in compaction telemetry as indicative of changes in characteristics of underlying datasets such as schema evolution, content distribution shifts, or changes in data generation processes, wherein such inferences are made without access to underlying data values and rely solely on observed compaction behavior. In some embodiments, anomaly detector 4650 uses compaction telemetry to detect security-relevant conditions including encryption anomalies, steganographic patterns, or data exfiltration attempts. For example, anomaly detector 4650 may detect encrypted or high-entropy payloads through observation of sudden onset of compaction failure localized to specific endpoints, sustained deviation from baseline compaction ratios characteristic of encrypted or high-entropy content, or repeated anomalous patterns aligned with message boundaries. Anomaly detector 4650 may also detect data exfiltration attempts through identification of sudden increases in compaction failure localized to specific endpoints, divergence between expected and observed compaction behavior for known workloads, or sustained telemetry anomalies consistent with outbound-only data flow.

Alert system 4660 represents a component configured to generate notifications or alerts in response to detected anomalies, deviations, or security-relevant conditions identified by anomaly detector 4650. Alert system 4660 may transmit alerts to security systems, operators, or other system components when compaction telemetry vectors deviate from baseline compaction profiles beyond configured thresholds, wherein trigger conditions may be defined based on absolute telemetry values, rates of change, persistence of anomalies, confidence scores, or combinations thereof. Trigger conditions implemented by alert system 4660 may be endpoint-specific, workload-specific, or globally defined and may be adjusted dynamically based on system learning or operator input. In some embodiments, alert system 4660 may escalate alerts based on severity of detected conditions or may provide alerts with varying levels of urgency depending on confidence levels and potential impact of detected anomalies.

Adaptive control system 4670 represents a component configured to initiate automated or semi-automated control actions in response to interpretations of compaction telemetry, thereby forming closed-loop control mechanisms in which observations of anonymized compaction behavior directly influence subsequent system operation. Upon detection of security-relevant conditions such as encryption anomalies, steganographic patterns, or suspected data exfiltration, adaptive control system 4670 may initiate automated security responses including rate limiting or throttling of data flows associated with an endpoint, isolation or sandboxing of affected endpoints or sessions, dynamic key rotation or rekeying of encoding mechanisms, enforcement of stricter encoding or monitoring policies, or generation of alerts or notifications to security systems or operators. These actions may be executed without accessing underlying data content and may be reversible or adaptive based on subsequent telemetry observations. In some embodiments, adaptive control system 4670 drives adaptive modification of encoding behavior through dynamic adjustment of selected sourceblock lengths, choice of codebooks or encoding strategies, frequency of codebook updates, or sampling rates for telemetry generation. Closed-loop control actions implemented by adaptive control system 4670 may be governed by policy rules that map interpreted telemetry conditions to specific responses, wherein policies may be locally enforced, centrally managed, or distributed across multiple system components. Following execution of control actions, adaptive control system 4670 monitors subsequent compaction telemetry to assess effectiveness of responses, wherein telemetry-driven feedback enables confirmation of resolution of detected conditions, escalation of responses if anomalies persist, or restoration of normal operation when conditions stabilize.

Analytics engine 4680 represents a component configured to perform advanced analysis and interpretation of compaction telemetry vectors across multiple endpoints, administrative domains, or tenants. Analytics engine 4680 may aggregate compaction telemetry vectors from multiple endpoints to form composite telemetry representations, wherein such aggregation may occur centrally, hierarchically, or in a distributed or federated manner. Aggregated telemetry may be used to identify correlated behavior across endpoints, detect coordinated anomalies, or establish population-level baselines, wherein aggregation may be performed without exposing individual endpoint data beyond anonymized telemetry vectors. In some embodiments, analytics engine 4680 performs federated analysis in which each endpoint or administrative domain performs local analysis and shares only derived telemetry summaries, anomaly indicators, or aggregated statistics, thereby reducing bandwidth consumption, preserving data locality, and enabling collaborative detection of coordinated behaviors across endpoints without exposing individual telemetry streams. Analytics engine 4680 may implement a compaction telemetry vector as a fixed-length vector, a sparse vector, a matrix, a tensor, or another structured data object, wherein dimensionality and structure of vectors may be selected based on analytic requirements, system constraints, or deployment considerations. In some embodiments, different subsets of telemetry metrics are used for different analytic purposes, resulting in multiple telemetry vector formats derived from the same underlying telemetry stream.

API interface 4690 represents a component configured to expose compaction telemetry vectors or derived analytic results through application programming interfaces. API interface 4690 may provide access to telemetry streams, anomaly indicators, trend summaries, or control recommendations, wherein APIs may be secured, rate-limited, and permissioned according to deployment requirements. In some embodiments, API interface 4690 facilitates analytics-as-a-service offerings in which compaction-derived telemetry is offered as a managed analytics service, wherein customers obtain operational and security insights derived from compaction behavior without granting service providers access to underlying data. This model enables monetization of analytics while preserving customer data sovereignty. Because compaction telemetry does not include personal data or reconstructive representations, API interface 4690 facilitates compliance with data protection regulations such as GDPR and CCPA, wherein telemetry-based analytics may be performed on regulated data without triggering obligations associated with data inspection or processing. In multi-tenant deployments, API interface 4690 maintains logical isolation of compaction telemetry vectors associated with different tenants, wherein aggregation or comparative analysis across tenants may be performed only on anonymized or normalized telemetry representations that prevent inference of tenant-specific data characteristics.

Collectively, components of compaction telemetry system 4600 enable privacy-preserving analytics, security detection, and adaptive control that are not achievable through traditional data inspection techniques. By generating, analyzing, and acting upon compaction telemetry, compaction telemetry system 4600 transforms anonymized data compaction systems from passive encoding mechanisms into active sensing and control platforms while preserving core privacy and efficiency benefits. All interpretation and analysis performed by compaction telemetry system 4600 operate exclusively on compaction telemetry vectors and derived representations, wherein no step requires reconstruction, inspection, or access to underlying plaintext data or sourceblocks, thereby maintaining non-reconstructive analytics that preserve privacy, confidentiality, and regulatory compliance while enabling security and behavioral inference.

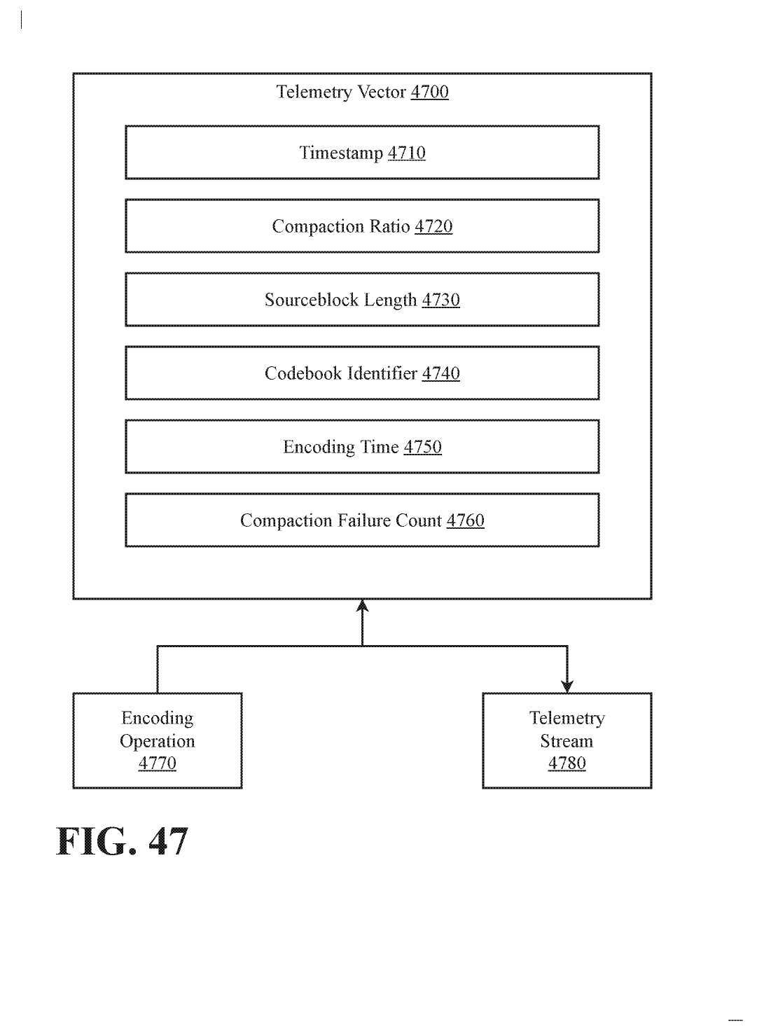

FIG. 47 is a block diagram illustrating an exemplary telemetry vector 4700 aspect of a compaction telemetry system, representing a structured, machine-readable representation comprising one or more compaction telemetry measurements associated with a particular endpoint, dataset, session, time interval, or operational context. Telemetry vector 4700 may be represented as a fixed-length or variable-length vector, a record, a time-series sample, or another structured data object suitable for automated analysis. Telemetry vector 4700 comprises a plurality of elements that collectively represent quantitative and qualitative measurements generated during operation of an anonymized data compaction system, including during tally parsing, codebook construction, codeword assignment, encoding, decoding, and optimization processes. All telemetry represented within telemetry vector 4700 is derived solely from anonymized compaction operations and system behavior, wherein at no point is underlying plaintext data reconstructed, inspected, or accessed, thereby preserving privacy guarantees of anonymized encoding systems and maintaining compatibility with regulatory and contractual data protection requirements. Exemplary telemetry vector 4700 of this embodiment comprises the telemetry factors of a timestamp 4710, a compaction ratio 4720, a sourceblock length 4730, a codebook identifier 4740, an encoding time 4750, and a compaction failure count 4760. These telemetry factors are non-limiting, and other embodiments may have other telemetry factors.

Timestamp 4710 represents a temporal reference element associated with telemetry vector 4700 that identifies a specific point in time or time interval during which compaction telemetry measurements were collected. Each instance of generated compaction telemetry may be associated with contextual metadata such as an endpoint identifier, dataset identifier, session identifier, timestamp, or operational state indicator, wherein such associations enable subsequent aggregation, comparison, and analysis of telemetry across time and across multiple endpoints. Timestamp 4710 enables construction of compaction telemetry vectors as time-series data structures, wherein successive vectors corresponding to adjacent or overlapping time intervals may be stored and analyzed to capture temporal trends in compaction behavior. Temporal compaction telemetry vectors enable detection of gradual or abrupt changes in system behavior including changes in data characteristics, encoding effectiveness, or security posture. In some embodiments, interpretation of compaction telemetry includes analysis of changes over time through computation of first-order derivatives representing rates of change in telemetry values, second-order derivatives representing acceleration or deceleration of change, or higher-order temporal features, wherein temporal analysis enables detection of gradual drift, sudden transitions, oscillatory behavior, or other dynamic patterns in compaction behavior that may not be apparent from instantaneous telemetry vectors alone. Association and tagging of telemetry data using timestamp 4710 does not require disclosure of underlying data content and may be performed using identifiers already present within anonymized compaction systems.

Compaction ratio 4720 represents a measurement element within telemetry vector 4700 that quantifies effective compaction factor achieved during encoding operations. Compaction ratio 4720 reflects relative compaction efficiency achieved for different sourceblock lengths and provides a metric for evaluating compaction performance. Observed compaction telemetry vectors including compaction ratio 4720 may be compared against corresponding baseline compaction profiles to detect deviations, wherein such deviations may include absolute differences, proportional differences, or statistically significant departures from expected values. Deviation detection may be performed using threshold-based methods, statistical hypothesis testing, machine learning models, or combinations thereof, wherein detected deviations may be classified according to severity, persistence, or confidence level. Changes in compaction ratio 4720 may be interpreted as indicative of changes in characteristics of underlying datasets such as schema evolution, content distribution shifts, or changes in data generation processes, wherein such inferences are made without access to underlying data values and rely solely on observed compaction behavior. In some embodiments, persistent or systematic reduction in compaction ratio 4720 may be interpreted as indicative of encrypted or pre-compressed data, wherein because encrypted data typically exhibits high entropy and resists dictionary-based compaction, sustained deviation from baseline compaction efficiency may signal presence of encryption.

Sourceblock length 4730 represents a parameter element within telemetry vector 4700 that indicates a length or size of sourceblocks processed during encoding operations. Sourceblock length 4730 is associated with telemetry measurements reflecting effectiveness metrics associated with different sourceblock lengths during live operation. During codebook construction and optimization, telemetry may include number of tokens processed per sourceblock length and relative compaction efficiency achieved for different sourceblock lengths, wherein recorded telemetry reflects behavior of compaction systems as they operate on anonymized representations and does not include underlying data values represented by tokens. In some embodiments, compaction telemetry interpretation drives adaptive modification of encoding behavior through dynamic adjustment of selected sourceblock lengths, choice of codebooks or encoding strategies, frequency of codebook updates, or sampling rates for telemetry generation, thereby enabling systems to maintain optimal compaction performance, enhance security sensitivity, or reduce computational overhead in response to changing conditions. Sourceblock length 4730 information within telemetry vector 4700 enables analysis of effectiveness of different sourceblock configurations without requiring access to underlying data content.

Codebook identifier 4740 represents a reference element within telemetry vector 4700 that identifies a specific codebook or dictionary used during encoding and decoding operations. Codebook identifier 4740 enables association of telemetry measurements with particular codebooks, facilitating analysis of codebook performance and effectiveness. Telemetry associated with codebook identifier 4740 may include codebook or dictionary growth rate, codebook churn or turnover rate, and frequency or distribution of codebook updates. During codebook construction and optimization, telemetry may include ordering statistics of anonymized tokens by frequency or weight, depth and structure of generated Huffman or equivalent trees, convergence characteristics of codebook optimization, and time required to generate or update a codebook. In some embodiments, abnormal growth of codebooks without corresponding compaction gains may be indicative of compaction failure, wherein compaction failure refers to a condition in which data processed by an anonymized compaction system fails to achieve an expected or baseline level of compaction efficiency. Codebook identifier 4740 enables systems to track and analyze performance of different codebooks across multiple encoding operations and datasets without requiring access to underlying plaintext data or deanonymized representations thereof.

Encoding time 4750 represents a temporal measurement element within telemetry vector 4700 that quantifies time-to-codeword assignment or encoding latency associated with encoding operations. Encoding time 4750 reflects operational metrics associated with encoding and decoding behavior including encoding latency or throughput measurements. During live encoding and decoding operations, as incoming data units are processed using existing codebooks, systems observe and record operational metrics associated with encoding and decoding behavior, wherein telemetry generated during encoding and decoding may be associated with individual data packets, sessions, endpoints, or time intervals depending on system configuration. Telemetry values contributing to compaction telemetry vectors including encoding time 4750 may be normalized, weighted, or transformed prior to aggregation through transformations including scaling, smoothing, binning, or dimensionality reduction, provided that transformations do not introduce any dependency on underlying plaintext data. Analysis of encoding time 4750 enables detection of performance anomalies, identification of encoding inefficiencies, and optimization of system resource allocation without requiring inspection of underlying data content. In some embodiments, sustained increases in encoding time 4750 may indicate degradation of codebook effectiveness or changes in data characteristics requiring codebook updates or adaptive encoding parameter adjustments.

Compaction failure count 4760 represents a measurement element within telemetry vector 4700 that quantifies compaction failure rate or non-compaction incidence during encoding operations. Compaction failure count 4760 reflects frequency of successful codeword matches and frequency and distribution of mismatches between incoming data units and existing codebooks. Compaction failure refers to a condition in which data processed by an anonymized compaction system fails to achieve an expected or baseline level of compaction efficiency, wherein compaction failure may be transient or persistent and may be characterized by repeated inability to match incoming data units to existing codewords, sustained high-entropy residuals, abnormal growth of codebooks without corresponding compaction gains, or divergence from established compaction baselines. Compaction failure count 4760 is defined with respect to behavior of compaction systems and does not imply inspection, interpretation, or reconstruction of underlying data content. In some embodiments, persistent or systematic compaction failure reflected in compaction failure count 4760 may be interpreted as indicative of encrypted or pre-compressed data, steganographic techniques, or data exfiltration attempts. Detection based on compaction failure count 4760 may include sustained high mismatch rates relative to baseline, persistent residual entropy measurements exceeding configured thresholds, or repeated invocation of fallback or hybrid encoding mechanisms. Such detection is performed without decrypting or inspecting payload data and does not require access to cryptographic keys.

Encoding operation 4770 represents a functional process that generates compaction telemetry during live encoding and decoding operations as incoming data units are processed using existing codebooks. Encoding operation 4770 observes and records operational metrics associated with encoding and decoding behavior, wherein telemetry generated includes frequency of successful codeword matches, frequency and distribution of mismatches, rate of invocation of hybrid or fallback encoding mechanisms, encoding latency or throughput measurements, residual data sizes following encoding, and effectiveness of selected sourceblock lengths during live operation. Compaction telemetry may be generated and collected according to one or more sampling strategies, wherein in some embodiments telemetry is sampled at fixed time intervals while in other embodiments telemetry is generated in response to events such as detection of compaction failure, threshold crossings, or codebook updates. Adaptive sampling strategies may also be employed in which telemetry generation frequency is increased or decreased based on observed system stability, anomaly likelihood, or available computational resources. Encoding operation 4770 leverages existing compaction workflows to produce telemetry signals without modifying fundamental anonymization, encoding, or decoding logic, thereby enabling generation of structured, non-reconstructive signals that can be analyzed and acted upon independently of underlying data content.

Telemetry stream 4780 represents a continuous flow of compaction telemetry measurements generated by encoding operation 4770 that are aggregated to form telemetry vector 4700. Telemetry stream 4780 comprises compaction telemetry generated during codebook construction, encoding, and decoding that is aggregated to form one or more compaction telemetry vectors associated with a specific endpoint, wherein each compaction telemetry vector may represent telemetry collected over a defined time interval, session, workload, or operational phase. In some embodiments, different subsets of telemetry metrics within telemetry stream 4780 are used for different analytic purposes, resulting in multiple telemetry vector formats derived from the same underlying telemetry stream. Compaction telemetry vectors formed from telemetry stream 4780 may be stored locally at an endpoint, transmitted to a remote analytics system, or both, wherein transmission of telemetry vectors may occur over secure channels and may be subject to additional anonymization or aggregation prior to transmission. Because telemetry vectors formed from telemetry stream 4780 do not contain underlying data content or reconstructive information, their storage and transmission pose reduced privacy and security risks relative to traditional data analytics. Telemetry stream 4780 enables continuous monitoring and analysis of compaction behavior across time, facilitating detection of temporal trends, anomalies, and evolving patterns in data characteristics without requiring access to underlying plaintext data or sourceblocks.

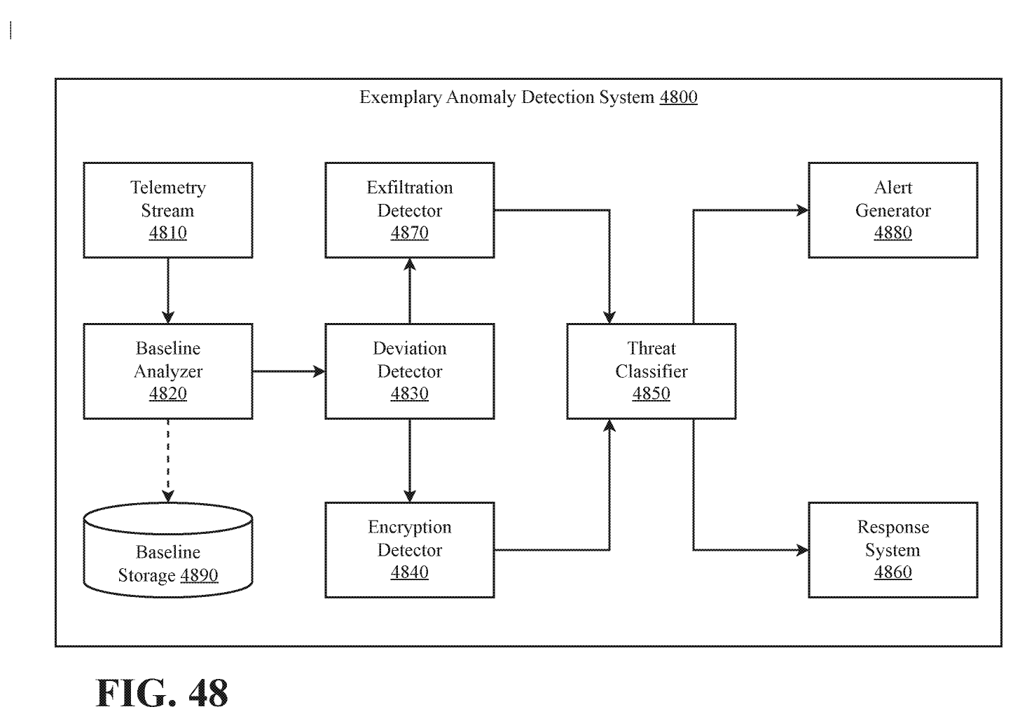

FIG. 48 is a block diagram illustrating an exemplary anomaly detection system 4800 aspect of a compaction telemetry system for detecting security-relevant conditions including encryption, steganography, data exfiltration, and control signaling by analyzing compaction telemetry generated by anonymized data compaction systems. Anomaly detection system 4800 comprises a plurality of interconnected components configured to interpret compaction telemetry vectors in order to infer operational, behavioral, and security-relevant conditions associated with anonymized data processing without reconstructing or accessing underlying data content. All security and side-channel detection techniques implemented by anomaly detection system 4800 rely on compaction telemetry and derived representations, wherein no underlying data content is reconstructed, decrypted, or inspected, thereby achieving security monitoring in a non-invasive manner that preserves privacy, confidentiality, and regulatory compliance.

Telemetry stream 4810 represents a continuous or periodic flow of compaction telemetry measurements that provides input to anomaly detection system 4800. Telemetry stream 4810 comprises quantitative and qualitative measurements generated during operation of anonymized data compaction systems, including during tally parsing, codebook construction, codeword assignment, encoding, decoding, and optimization processes. Compaction telemetry conveyed by telemetry stream 4810 is derived from behavior and performance of compaction mechanisms themselves and does not include, require, or imply access to underlying plaintext data, sourceblocks, or deanonymized representations thereof. Telemetry stream 4810 may be generated and collected according to one or more sampling strategies, wherein in some embodiments telemetry is sampled at fixed time intervals while in other embodiments telemetry is generated in response to events such as detection of compaction failure, threshold crossings, or codebook updates. Adaptive sampling strategies may also be employed in which telemetry generation frequency is increased or decreased based on observed system stability, anomaly likelihood, or available computational resources. Each instance of generated compaction telemetry within telemetry stream 4810 may be associated with contextual metadata such as an endpoint identifier, dataset identifier, session identifier, timestamp, or operational state indicator, wherein such associations enable subsequent aggregation, comparison, and analysis of telemetry across time and across multiple endpoints.

Baseline analyzer 4820 represents a component configured to establish one or more baseline compaction profiles for an endpoint, dataset, or operational context. Baseline analyzer 4820 generates baseline compaction profiles that represent expected ranges or distributions of compaction telemetry vectors under normal or previously observed conditions. Baseline compaction profiles may be established using historical telemetry data, training datasets, configuration parameters, or adaptive learning techniques, wherein baselines may be static, periodically refreshed, or continuously updated to reflect evolving system behavior. Baseline compaction profiles generated by baseline analyzer 4820 are used to evaluate deviations, trends, or anomalies in observed compaction telemetry vectors provided by telemetry stream 4810. In some embodiments, baseline analyzer 4820 may construct multiple baseline profiles for different operational contexts, endpoints, or time periods, thereby enabling context-specific anomaly detection and minimizing false positive detections. Baseline profiles generated by baseline analyzer 4820 may be stored in baseline storage 4890 for subsequent retrieval and comparison operations performed by deviation detector 4830.

Deviation detector 4830 represents a component configured to compare observed compaction telemetry vectors from telemetry stream 4810 against corresponding baseline compaction profiles to detect deviations. Deviations detected by deviation detector 4830 may include absolute differences, proportional differences, or statistically significant departures from expected values established by baseline analyzer 4820. Deviation detection may be performed using threshold-based methods, statistical hypothesis testing, machine learning models, or combinations thereof, wherein detected deviations may be classified according to severity, persistence, or confidence level. In some embodiments, interpretation of compaction telemetry by deviation detector 4830 includes analysis of changes over time through computation of first-order derivatives representing rates of change in telemetry values, second-order derivatives representing acceleration or deceleration of change, or higher-order temporal features. Temporal analysis enables detection of gradual drift, sudden transitions, oscillatory behavior, or other dynamic patterns in compaction behavior that may not be apparent from instantaneous telemetry vectors alone. Changes in compaction telemetry detected by deviation detector 4830 may be interpreted as indicative of changes in characteristics of underlying datasets such as schema evolution, content distribution shifts, or changes in data generation processes, wherein such inferences are made without access to underlying data values and rely solely on observed compaction behavior.

Encryption detector 4840 represents a component configured to detect encrypted or pre-compressed data through analysis of compaction telemetry. In some embodiments, encryption detector 4840 interprets persistent or systematic compaction failure as indicative of encrypted or pre-compressed data, wherein because encrypted data typically exhibits high entropy and resists dictionary-based compaction, sustained deviation from baseline compaction efficiency may signal presence of encryption. Detection by encryption detector 4840 may be based on one or more criteria including sustained high mismatch rates relative to baseline, abnormal growth of codebooks without corresponding compaction gains, persistent residual entropy measurements exceeding configured thresholds, or repeated invocation of fallback or hybrid encoding mechanisms. Such detection is performed without decrypting or inspecting payload data and does not require access to cryptographic keys. Encryption detector 4840 may also detect localized or message-specific variations in compaction telemetry that may be interpreted as indicative of steganographic techniques or covert communication channels, wherein intentional modulation of entropy or compaction efficiency across selected data segments may be detected through analysis of telemetry vector variance and clustering. Detection techniques implemented by encryption detector 4840 may include identifying statistically improbable fluctuations in compaction efficiency, repeated anomalous patterns aligned with message boundaries, or correlated telemetry deviations across multiple endpoints or sessions.

Threat classifier 4850 represents a component configured to classify detected deviations and anomalies according to threat types, severity levels, or attack patterns. Threat classifier 4850 receives inputs from deviation detector 4830, encryption detector 4840, and exfiltration detector 4870 to perform comprehensive threat assessment and categorization. Detected deviations may be classified according to severity, persistence, or confidence level, wherein threat classifier 4850 may employ machine learning models, rule-based systems, or hybrid approaches to distinguish between benign anomalies and genuine security threats. In some embodiments, threat classifier 4850 may identify specific attack patterns such as distributed denial of service attacks, data tampering attempts, or unauthorized access attempts based on characteristic telemetry signatures. Threat classifier 4850 may also assess confidence scores associated with detected threats, wherein confidence scores may be based on multiple factors including magnitude of deviation, duration of anomalous behavior, correlation across multiple telemetry metrics, or consistency with known attack patterns. Classification results from threat classifier 4850 are provided to response system 4860 and alert generator 4880 to enable appropriate responsive actions.

Response system 4860 represents a component configured to initiate automated or semi-automated control actions in response to interpretations of compaction telemetry and threat classifications. Response system 4860 forms closed-loop control mechanisms in which observations of anonymized compaction behavior directly influence subsequent system operation. Upon detection of security-relevant conditions such as encryption anomalies, steganographic patterns, or suspected data exfiltration, response system 4860 may initiate automated security responses including rate limiting or throttling of data flows associated with an endpoint, isolation or sandboxing of affected endpoints or sessions, dynamic key rotation or rekeying of encoding mechanisms, enforcement of stricter encoding or monitoring policies, or generation of alerts or notifications to security systems or operators. These actions may be executed without accessing underlying data content and may be reversible or adaptive based on subsequent telemetry observations. In some embodiments, response system 4860 drives adaptive modification of encoding behavior through dynamic adjustment of selected sourceblock lengths, choice of codebooks or encoding strategies, frequency of codebook updates, or sampling rates for telemetry generation. Trigger conditions implemented by response system 4860 may be defined based on absolute telemetry values, rates of change, persistence of anomalies, confidence scores, or combinations thereof, wherein trigger conditions may be endpoint-specific, workload-specific, or globally defined and may be adjusted dynamically based on system learning or operator input. Closed-loop control actions may be governed by policy rules that map interpreted telemetry conditions to specific responses, wherein policies may be locally enforced, centrally managed, or distributed across multiple system components.

Exfiltration detector 4870 represents a component configured to detect data exfiltration attempts through analysis of compaction telemetry. Exfiltration detector 4870 analyzes transmission of encrypted or high-entropy payloads embedded within otherwise compressible traffic to identify characteristic telemetry signatures distinguishable from normal operation. In some embodiments, telemetry analysis performed by exfiltration detector 4870 identifies exfiltration attempts by detecting sudden increases in compaction failure localized to specific endpoints, divergence between expected and observed compaction behavior for known workloads, or sustained telemetry anomalies consistent with outbound-only data flow. Exfiltration detector 4870 may also detect intentional use of compaction behavior as a signaling mechanism, wherein such control signaling may involve deliberate manipulation of data characteristics to induce detectable compaction patterns. By monitoring structured changes in compaction telemetry vectors, exfiltration detector 4870 may infer presence of non-payload control channels embedded within anonymized data streams. Detection of exfiltration attempts by exfiltration detector 4870 enables response system 4860 to implement appropriate countermeasures such as isolation of affected endpoints, throttling of suspicious data flows, or escalation to security operators for further investigation.

Alert generator 4880 represents a component configured to generate alerts or notifications to security systems or operators based on detected anomalies, threats, and exfiltration attempts. Alert generator 4880 receives inputs from deviation detector 4830, encryption detector 4840, threat classifier 4850, and exfiltration detector 4870 to generate comprehensive alerts containing relevant context about detected conditions. Alerts generated by alert generator 4880 may include information about affected endpoints, characteristics of detected anomalies, confidence levels, severity assessments, and recommended responsive actions. In some embodiments, alert generator 4880 may implement alert prioritization and escalation mechanisms, wherein alerts may be classified according to urgency and routed to appropriate personnel or systems based on severity and confidence levels. Alert generator 4880 may also implement deduplication and aggregation of related alerts to prevent alert fatigue and enable efficient triage of security events. In some embodiments, alert generator 4880 may integrate with existing security information and event management systems or network control platforms to provide unified visibility into security posture across multiple systems and administrative domains.

Baseline storage 4890 represents a repository component configured to persistently store baseline compaction profiles generated by baseline analyzer 4820. Baseline storage 4890 maintains historical baseline profiles, training datasets, configuration parameters, and adaptive learning models that enable establishment and refinement of baseline compaction profiles over time. In some embodiments, baseline storage 4890 maintains multiple versions of baseline profiles corresponding to different operational contexts, time periods, or system configurations, thereby enabling temporal analysis and comparison of system behavior evolution. Baseline storage 4890 may implement efficient indexing and retrieval mechanisms to enable rapid access to relevant baseline profiles during real-time anomaly detection operations performed by deviation detector 4830. In some embodiments, baseline storage 4890 may store metadata associated with baseline profiles including creation timestamps, update history, performance metrics, and validation results, thereby enabling audit trails and quality assurance of anomaly detection operations. Baseline profiles stored in baseline storage 4890 may be periodically refreshed or continuously updated to reflect evolving system behavior, wherein updates may be triggered by scheduled refresh operations, detection of significant system changes, or manual intervention by system operators.

Collectively, components of anomaly detection system 4800 enable comprehensive security monitoring and threat detection capabilities while preserving privacy guarantees of anonymized compaction systems. Following execution of control actions by response system 4860, subsequent compaction telemetry from telemetry stream 4810 is monitored to assess effectiveness of responses, wherein telemetry-driven feedback enables systems to confirm resolution of detected conditions, escalate responses if anomalies persist, or restore normal operation when conditions stabilize. This feedback mechanism completes a closed-loop control cycle in which compaction telemetry observation, interpretation, response, and validation are continuously linked, thereby enabling adaptive security posture that evolves in response to emerging threats and changing operational conditions.

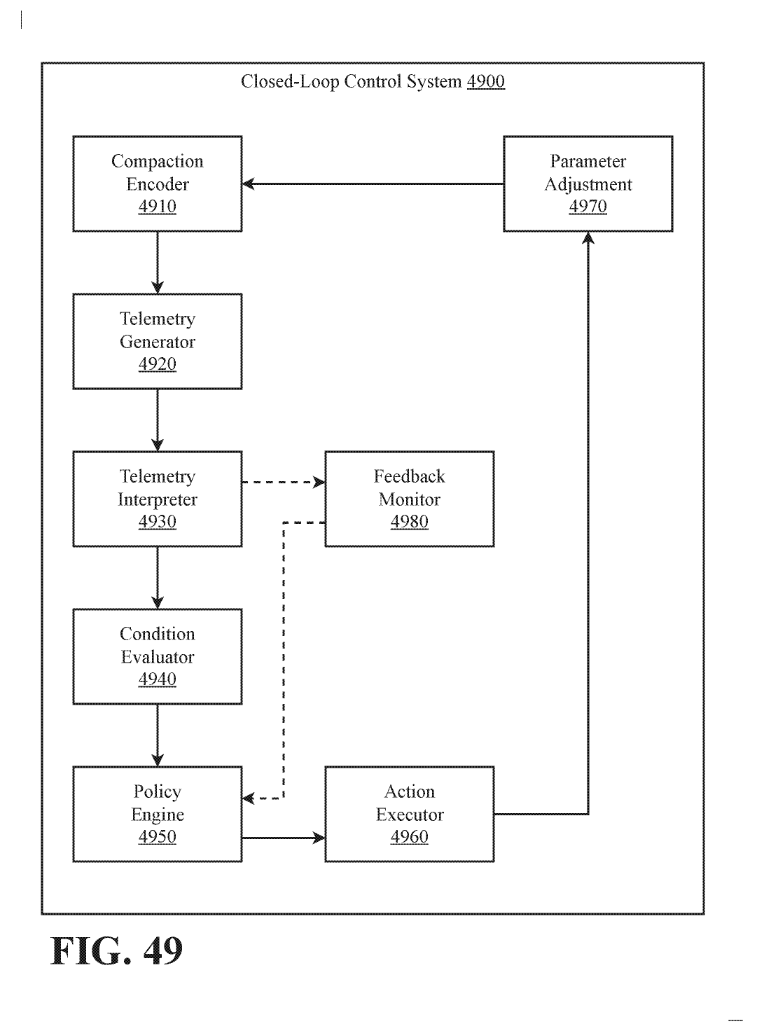

FIG. 49 is a block diagram illustrating an exemplary closed-loop control system 4900 aspect of a compaction telemetry system for initiating automated or semi-automated control actions in response to interpretations of compaction telemetry. Closed-loop control system 4900 forms closed-loop control mechanisms in which observations of anonymized compaction behavior directly influence subsequent system operation, thereby forming a feedback loop between compaction telemetry observation and system operation. Closed-loop control refers to automated or semi-automated system actions initiated in response to interpreted compaction telemetry, wherein such actions may modify system behavior, security posture, or encoding parameters based on detected conditions. Closed-loop control actions implemented by closed-loop control system 4900 may be implemented locally at an endpoint, centrally across multiple endpoints, or in a distributed or federated manner. All control actions executed by closed-loop control system 4900 may be performed without accessing underlying data content and may be reversible or adaptive based on subsequent telemetry observations, thereby preserving privacy, confidentiality, and regulatory compliance while enabling adaptive system control.

Compaction encoder 4910 represents a component configured to perform encoding and decoding operations on anonymized data using existing codebooks. Compaction encoder 4910 processes incoming data units using codebooks to perform live encoding and decoding operations, wherein as data units are processed, operational metrics associated with encoding and decoding behavior are generated. During operation, compaction encoder 4910 observes and records operational metrics including frequency of successful codeword matches, frequency and distribution of mismatches, rate of invocation of hybrid or fallback encoding mechanisms, encoding latency or throughput measurements, residual data sizes following encoding, and effectiveness of selected sourceblock lengths during live operation. Compaction encoder 4910 receives adaptive control inputs from parameter adjustment 4970 that may dynamically modify encoding behavior including selected sourceblock lengths, choice of codebooks or encoding strategies, frequency of codebook updates, or sampling rates for telemetry generation. Such adaptations enable compaction encoder 4910 to maintain optimal compaction performance, enhance security sensitivity, or reduce computational overhead in response to changing conditions detected through telemetry analysis.

Telemetry generator 4920 represents a component configured to generate compaction telemetry during operation of compaction encoder 4910. Telemetry generator 4920 generates quantitative and qualitative measurements during operation of anonymized data compaction systems, including during tally parsing, codebook construction, codeword assignment, encoding, decoding, and optimization processes. Compaction telemetry generated by telemetry generator 4920 is derived from behavior and performance of compaction mechanisms themselves and does not include, require, or imply access to underlying plaintext data, sourceblocks, or deanonymized representations thereof. Telemetry generator 4920 may generate and collect compaction telemetry according to one or more sampling strategies, wherein in some embodiments telemetry is sampled at fixed time intervals while in other embodiments telemetry is generated in response to events such as detection of compaction failure, threshold crossings, or codebook updates. Adaptive sampling strategies may also be employed in which telemetry generation frequency is increased or decreased based on observed system stability, anomaly likelihood, or available computational resources. Each instance of generated compaction telemetry may be associated with contextual metadata such as an endpoint identifier, dataset identifier, session identifier, timestamp, or operational state indicator, wherein such associations enable subsequent aggregation, comparison, and analysis of telemetry across time and across multiple endpoints.

Telemetry interpreter 4930 represents a component configured to interpret compaction telemetry vectors generated by telemetry generator 4920 in order to infer operational, behavioral, and security-relevant conditions associated with anonymized data processing without reconstructing or accessing underlying data content. Telemetry interpreter 4930 establishes one or more baseline compaction profiles for endpoints, datasets, or operational contexts, wherein baseline compaction profiles represent expected ranges or distributions of compaction telemetry vectors under normal or previously observed conditions. Baseline compaction profiles may be established using historical telemetry data, training datasets, configuration parameters, or adaptive learning techniques, wherein baselines may be static, periodically refreshed, or continuously updated to reflect evolving system behavior. Telemetry interpreter 4930 compares observed compaction telemetry vectors against corresponding baseline compaction profiles to detect deviations including absolute differences, proportional differences, or statistically significant departures from expected values. In some embodiments, interpretation of compaction telemetry by telemetry interpreter 4930 includes analysis of changes over time through computation of first-order derivatives representing rates of change in telemetry values, second-order derivatives representing acceleration or deceleration of change, or higher-order temporal features. All interpretation and analysis performed by telemetry interpreter 4930 operate exclusively on compaction telemetry vectors and derived representations, wherein no step requires reconstruction, inspection, or inference of underlying plaintext data.

Condition evaluator 4940 represents a component configured to evaluate whether compaction telemetry vectors deviate from baseline compaction profiles beyond configured thresholds, thereby determining trigger conditions for control actions. Condition evaluator 4940 defines trigger conditions based on absolute telemetry values, rates of change, persistence of anomalies, confidence scores, or combinations thereof, wherein trigger conditions may be endpoint-specific, workload-specific, or globally defined and may be adjusted dynamically based on system learning or operator input. In some embodiments, condition evaluator 4940 detects security-relevant conditions such as encryption anomalies, steganographic patterns, or suspected data exfiltration based on interpreted telemetry from telemetry interpreter 4930. Condition evaluator 4940 may also detect dataset evolution, wherein changes in compaction telemetry may be interpreted as indicative of changes in characteristics of underlying datasets such as schema evolution, content distribution shifts, or changes in data generation processes. Detected deviations may be classified according to severity, persistence, or confidence level using threshold-based methods, statistical hypothesis testing, machine learning models, or combinations thereof. Evaluation results from condition evaluator 4940 are provided to policy engine 4950 to determine appropriate responsive actions.

Policy engine 4950 represents a component configured to govern closed-loop control actions through policy rules that map interpreted telemetry conditions to specific responses. Policy engine 4950 implements policies that may be locally enforced, centrally managed, or distributed across multiple system components, wherein in some embodiments compaction telemetry-driven policies are integrated with existing security, compliance, or operational management frameworks such as security information and event management systems or network control platforms. Policy engine 4950 receives condition evaluations from condition evaluator 4940 and determines appropriate responsive actions including automated security responses or adaptive encoding modifications. Upon detection of security-relevant conditions, policy engine 4950 may specify automated security responses including rate limiting or throttling of data flows associated with an endpoint, isolation or sandboxing of affected endpoints or sessions, dynamic key rotation or rekeying of encoding mechanisms, enforcement of stricter encoding or monitoring policies, or generation of alerts or notifications to security systems or operators. Policy engine 4950 may also specify adaptive modifications of encoding behavior including dynamic adjustment of selected sourceblock lengths, choice of codebooks or encoding strategies, frequency of codebook updates, or sampling rates for telemetry generation. Policy decisions from policy engine 4950 are provided to action executor 4960 for implementation.

Action executor 4960 represents a component configured to execute control actions specified by policy engine 4950 in response to detected conditions and policy determinations. Action executor 4960 implements automated security responses including rate limiting or throttling of data flows, isolation or sandboxing of affected endpoints or sessions, dynamic key rotation or rekeying of encoding mechanisms, enforcement of stricter encoding or monitoring policies, and generation of alerts or notifications to security systems or operators. These actions may be executed without accessing underlying data content and may be reversible or adaptive based on subsequent telemetry observations monitored by feedback monitor 4980. Action executor 4960 may also coordinate with parameter adjustment 4970 to implement adaptive modifications of encoding behavior in response to changing conditions. In some embodiments, action executor 4960 maintains logs of executed actions, including timestamps, affected endpoints, action types, and rationale based on triggering conditions, thereby enabling audit trails and post-incident analysis of control actions.

Parameter adjustment 4970 represents a component configured to implement adaptive modification of encoding behavior based on control actions specified by policy engine 4950 and executed by action executor 4960. Parameter adjustment 4970 dynamically adjusts operational parameters of compaction encoder 4910 including selected sourceblock lengths, choice of codebooks or encoding strategies, frequency of codebook updates, and sampling rates for telemetry generation. Such adaptations enable systems to maintain optimal compaction performance, enhance security sensitivity, or reduce computational overhead in response to changing conditions detected through telemetry analysis. In some embodiments, parameter adjustment 4970 may implement gradual or stepped parameter changes to minimize disruption to ongoing encoding operations while achieving desired performance or security objectives. Parameter adjustment 4970 may also maintain historical records of parameter changes, including timestamps, rationale, and observed effects on compaction telemetry, thereby enabling analysis of parameter tuning effectiveness and refinement of adaptive control strategies. Effectiveness of parameter adjustments is monitored by feedback monitor 4980 through analysis of subsequent compaction telemetry generated by telemetry generator 4920.

Feedback monitor 4980 represents a component configured to monitor subsequent compaction telemetry following execution of control actions to assess effectiveness of responses. Feedback monitor 4980 implements telemetry-driven feedback that enables systems to confirm resolution of detected conditions, escalate responses if anomalies persist, or restore normal operation when conditions stabilize. This feedback mechanism completes a closed-loop control cycle in which compaction telemetry observation, interpretation, response, and validation are continuously linked through interactions among telemetry generator 4920, telemetry interpreter 4930, condition evaluator 4940, policy engine 4950, action executor 4960, parameter adjustment 4970, and feedback monitor 4980. In some embodiments, feedback monitor 4980 compares post-action telemetry against pre-action telemetry and baseline profiles to quantify effectiveness of control actions, wherein effectiveness metrics may include measures of anomaly reduction, restoration of baseline compaction performance, or elimination of security-relevant indicators. Feedback monitor 4980 may provide feedback to condition evaluator 4940 and policy engine 4950 to enable refinement of trigger conditions, policy rules, and adaptive control strategies based on observed outcomes of prior control actions. In some embodiments, feedback monitor 4980 may implement escalation mechanisms that trigger more aggressive control actions if initial responses prove insufficient to resolve detected conditions, or de-escalation mechanisms that restore normal operational parameters once stability is confirmed.

Collectively, components of closed-loop control system 4900 enable automated adaptive control of anonymized data compaction systems based on real-time telemetry analysis without requiring access to underlying data content. Through continuous cycles of telemetry observation by telemetry generator 4920, interpretation by telemetry interpreter 4930, condition evaluation by condition evaluator 4940, policy-based decision making by policy engine 4950, action execution by action executor 4960, parameter adjustment by parameter adjustment 4970, and feedback monitoring by feedback monitor 4980, closed-loop control system 4900 enables systems to respond dynamically to changing operational conditions, security threats, and dataset evolution while preserving privacy guarantees of anonymized encoding systems. This closed-loop approach transforms anonymized data compaction systems from passive encoding mechanisms into active, self-regulating platforms capable of maintaining optimal performance and security posture in response to evolving conditions and emerging threats.

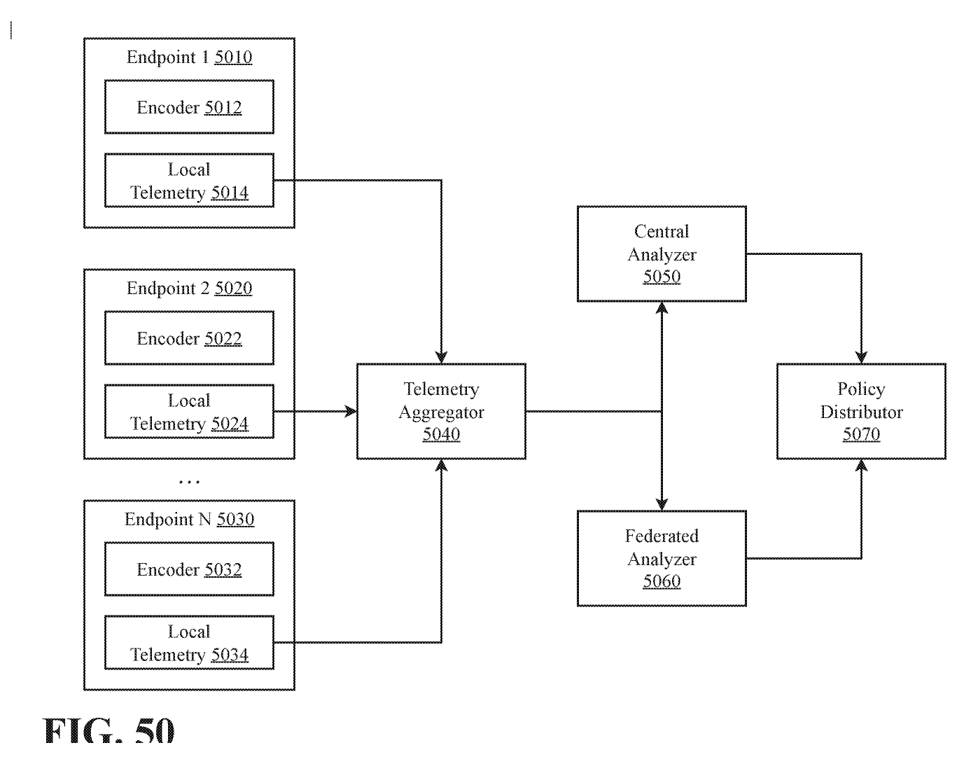

FIG. 50 is a block diagram illustrating an exemplary distributed and federated telemetry aspect of a compaction telemetry system in which compaction telemetry generation, analysis, and control are performed across multiple endpoints, administrative domains, or tenants while preserving isolation and privacy guarantees. The distributed architecture enables centralized visibility into compaction behavior across large deployments without requiring centralized access to underlying data, wherein compaction telemetry vectors are generated locally at endpoints and transmitted to one or more remote analysis systems. Telemetry transmission may occur periodically, event-driven, or adaptively based on detected conditions, wherein distributed collection enables collaborative detection of coordinated behaviors across endpoints without exposing individual telemetry streams or underlying data content.

Endpoints 5010, 5020, 5030 represent data processing endpoints configured to perform anonymized data compaction operations and generate local compaction telemetry. Endpoints 5010, 5020, 5030 may include any identifiable source, sink, or locus of data processing associated with anonymized compaction systems, including without limitation a physical device, virtual machine, containerized application instance, network node, user context, software process, or logical communication channel. Endpoints 5010, 5020, 5030 each comprise encoder 5012, 5022, 5032 and local telemetry 5014, 5024, 5034 components that enable local generation and collection of compaction telemetry. Endpoints 5010, 5020, 5030 may be monitored individually or in aggregate through compaction telemetry vectors transmitted to telemetry aggregator 5040, wherein telemetry transmission occurs over secure channels and may be subject to additional anonymization or aggregation prior to transmission. In some embodiments, endpoints 5010, 5020, 5030 perform local analysis of generated telemetry and shares only derived telemetry summaries, anomaly indicators, or aggregated statistics with remote analysis systems, thereby reducing bandwidth consumption and preserving data locality.

Encoders 5012, 5022, 5032 represent compaction encoding components within endpoints 5010, 5020, 5030 configured to perform live encoding and decoding operations on anonymized data using existing codebooks. Encoders 5012, 5022, 5032 process incoming data units using codebooks to perform compaction operations, wherein as data units are processed, operational metrics associated with encoding and decoding behavior are observed and recorded. During operation, encoders 5012, 5022, 5032 generate telemetry including frequency of successful codeword matches, frequency and distribution of mismatches, rate of invocation of hybrid or fallback encoding mechanisms, encoding latency or throughput measurements, residual data sizes following encoding, and effectiveness of selected sourceblock lengths during live operation. Encoders 5012, 5022, 5032 provide operational metrics to local telemetry 5014, 5024, 5034 for aggregation and transmission to telemetry aggregator 5040. Encoders 5012, 5022, 5032 may receive adaptive control inputs from policy distributor 5070 that dynamically modify encoding behavior including selected sourceblock lengths, choice of codebooks or encoding strategies, frequency of codebook updates, or sampling rates for telemetry generation.

Local telemetry 5014, 5024, 5034 represents a telemetry collection and aggregation component within endpoints 5010, 5020, 5030 configured to generate compaction telemetry vectors from operational metrics produced by encoders 5012, 5022, 5032. Local telemetry 5014, 5024, 5034 aggregates compaction telemetry generated during codebook construction, encoding, and decoding to form one or more compaction telemetry vectors associated with endpoints 5010, 5020, 5030, wherein each compaction telemetry vector may represent telemetry collected over a defined time interval, session, workload, or operational phase. Telemetry values contributing to compaction telemetry vectors may be normalized, weighted, or transformed prior to aggregation through transformations including scaling, smoothing, binning, or dimensionality reduction, provided that transformations do not introduce any dependency on underlying plaintext data. Local telemetry 5014, 5024, 5034 may store compaction telemetry vectors locally at endpoints 5010, 5020, 5030, transmit vectors to telemetry aggregator 5040, or both, wherein because telemetry vectors do not contain underlying data content or reconstructive information, their storage and transmission pose reduced privacy and security risks relative to traditional data analytics. In some embodiments, local telemetry 5014, 5024, 5034 may perform preliminary analysis of telemetry vectors to detect local anomalies or deviations before transmitting telemetry to remote analysis systems.

In multi-tenant deployments, compaction telemetry vectors associated with different endpoints or tenants are logically isolated, wherein aggregation or comparative analysis across endpoints may be performed only on anonymized or normalized telemetry representations that prevent inference of endpoint-specific or tenant-specific data characteristics. Such isolation enables analytics-as-a-service offerings while maintaining contractual and regulatory separation between endpoints and tenants. Endpoints 5010, 5020, 5030 contributes telemetry vectors to telemetry aggregator 5040 for aggregated analysis across multiple endpoints to identify correlated behavior, detect coordinated anomalies, or establish population-level baselines.

Encoders 5012, 5022, 5032 process incoming data units using codebooks specific to their respective endpoints, wherein operational metrics generated during encoding operations reflect compaction behavior specific to data characteristics and workloads associated with their respective endpoints. Encoders 5012, 5022, 5032 provides telemetry to local telemetry 5014, 5024, 5034 and may receive adaptive control inputs from policy distributor 5070 to modify encoding behavior in response to detected conditions or policy determinations applicable to endpoint 25020.

Endpoint N 5030 represents an arbitrary Nth data processing endpoint in a scalable distributed architecture configured to perform anonymized data compaction operations and generate local compaction telemetry. Endpoint N 5030 demonstrates extensibility of distributed telemetry collection to support large-scale deployments comprising numerous endpoints across distributed geographic locations, administrative domains, or organizational boundaries. Endpoint N 5030 comprises encoder 5032 and local telemetry 5034 components that operate independently while contributing to collective visibility and analysis capabilities provided by telemetry aggregator 5040, central analyzer 5050, and federated analyzer 5060. Distributed architecture enables systems to scale horizontally by adding additional endpoints without requiring centralized access to underlying data processed by any individual endpoint.

Telemetry aggregator 5040 represents a centralized or distributed component configured to receive compaction telemetry vectors from multiple endpoints including endpoint 15010, endpoint 25020, and endpoint N 5030 and aggregate such vectors to form composite telemetry representations. Telemetry aggregator 5040 performs aggregation that may occur centrally, hierarchically, or in a distributed or federated manner, wherein aggregated telemetry may be used to identify correlated behavior across endpoints, detect coordinated anomalies, or establish population-level baselines. Aggregation may be performed without exposing individual endpoint data beyond anonymized telemetry vectors, thereby preserving privacy and isolation guarantees. In some embodiments, telemetry aggregator 5040 applies normalization, weighting, or statistical transformations to telemetry vectors from different endpoints to enable meaningful comparison and correlation analysis across heterogeneous endpoints with different operational characteristics, workload patterns, or deployment configurations. Telemetry aggregator 5040 provides aggregated telemetry representations to central analyzer 5050 for centralized analysis and to federated analyzer 5060 for distributed analysis approaches. In multi-tenant deployments, telemetry aggregator 5040 maintains logical isolation between telemetry vectors associated with different tenants while enabling cross-tenant analysis on anonymized or normalized representations that prevent inference of tenant-specific data characteristics.

Central analyzer 5050 represents a centralized analysis component configured to interpret aggregated compaction telemetry from telemetry aggregator 5040 to infer operational, behavioral, and security-relevant conditions across multiple endpoints. Central analyzer 5050 establishes baseline compaction profiles representing expected ranges or distributions of compaction telemetry vectors under normal or previously observed conditions across endpoint populations. Central analyzer 5050 compares observed aggregated telemetry against baseline profiles to detect deviations, anomalies, or trends that may indicate coordinated security threats, widespread dataset evolution, or systemic performance issues affecting multiple endpoints. In some embodiments, central analyzer 5050 performs correlation analysis to identify patterns of telemetry deviations across multiple endpoints that may indicate coordinated attacks, distributed anomalies, or infrastructure-level issues not apparent from analysis of individual endpoints. Central analyzer 5050 provides analysis results to policy distributor 5070 to enable coordinated policy decisions and control actions across multiple endpoints. Centralized analysis enables comprehensive visibility into compaction behavior across large deployments while operating exclusively on anonymized telemetry vectors without requiring access to underlying data content processed by any endpoint.

Federated analyzer 5060 represents a distributed analysis component configured to perform compaction telemetry analysis in a federated manner across multiple endpoints or administrative domains. Federated analyzer 5060 enables each endpoint or administrative domain to perform local analysis and share only derived telemetry summaries, anomaly indicators, or aggregated statistics rather than complete telemetry streams, wherein federated analysis reduces bandwidth consumption, preserves data locality, and enables collaborative detection of coordinated behaviors across endpoints without exposing individual telemetry streams. In some embodiments, federated analyzer 5060 implements federated learning techniques wherein analysis models are trained or refined using telemetry from multiple endpoints without centralizing raw telemetry data, thereby enabling knowledge sharing across endpoints while maintaining strict data isolation. Federated analyzer 5060 may coordinate with central analyzer 5050 to provide complementary analysis capabilities, wherein centralized analysis provides comprehensive cross-endpoint visibility while federated analysis preserves local autonomy and reduces centralization risks. Analysis results from federated analyzer 5060 are provided to policy distributor 5070 to inform policy decisions that respect local autonomy while enabling coordinated responses to distributed threats or conditions.

Policy distributor 5070 represents a component configured to govern and distribute closed-loop control policies across multiple endpoints based on analysis results from central analyzer 5050 and federated analyzer 5060. Policy distributor 5070 implements policy rules that map interpreted telemetry conditions to specific responses applicable to individual endpoints or groups of endpoints, wherein policies may be locally enforced, centrally managed, or distributed across multiple system components. In some embodiments, compaction telemetry-driven policies distributed by policy distributor 5070 are integrated with existing security, compliance, or operational management frameworks such as security information and event management systems or network control platforms. Policy distributor 5070 may specify automated security responses including rate limiting or throttling of data flows, isolation or sandboxing of affected endpoints, dynamic key rotation or rekeying of encoding mechanisms, enforcement of stricter encoding or monitoring policies, or generation of alerts or notifications to security systems or operators. Policy distributor 5070 may also specify adaptive modifications of encoding behavior including dynamic adjustment of selected sourceblock lengths, choice of codebooks or encoding strategies, frequency of codebook updates, or sampling rates for telemetry generation. Distributed policies enable coordinated responses to threats or conditions affecting multiple endpoints while respecting local autonomy and administrative boundaries. In multi-tenant deployments, policy distributor 5070 maintains logical isolation of policies applicable to different tenants while enabling cross-tenant policies for systemic threats or conditions requiring coordinated response across tenant boundaries.

Collectively, components illustrated in FIG. 50 enable distributed and federated compaction telemetry systems that provide comprehensive visibility and control across large-scale deployments while preserving privacy, isolation, and data locality guarantees. Through distributed collection of telemetry at endpoints via local telemetry components 5014, 5024, and 5034, aggregation via telemetry aggregator 5040, analysis via central analyzer 5050 and federated analyzer 5060, and policy distribution via policy distributor 5070, the distributed architecture enables scalable monitoring, analysis, and adaptive control of anonymized data compaction systems across diverse deployment scenarios including cloud environments, edge computing deployments, multi-tenant platforms, and geographically distributed infrastructures. This distributed approach transforms anonymized data compaction from isolated endpoint operations into collaborative, coordinated systems capable of detecting and responding to complex threats and conditions that span multiple endpoints, administrative domains, or organizational boundaries while maintaining strict privacy and isolation guarantees essential for regulatory compliance and contractual obligations.

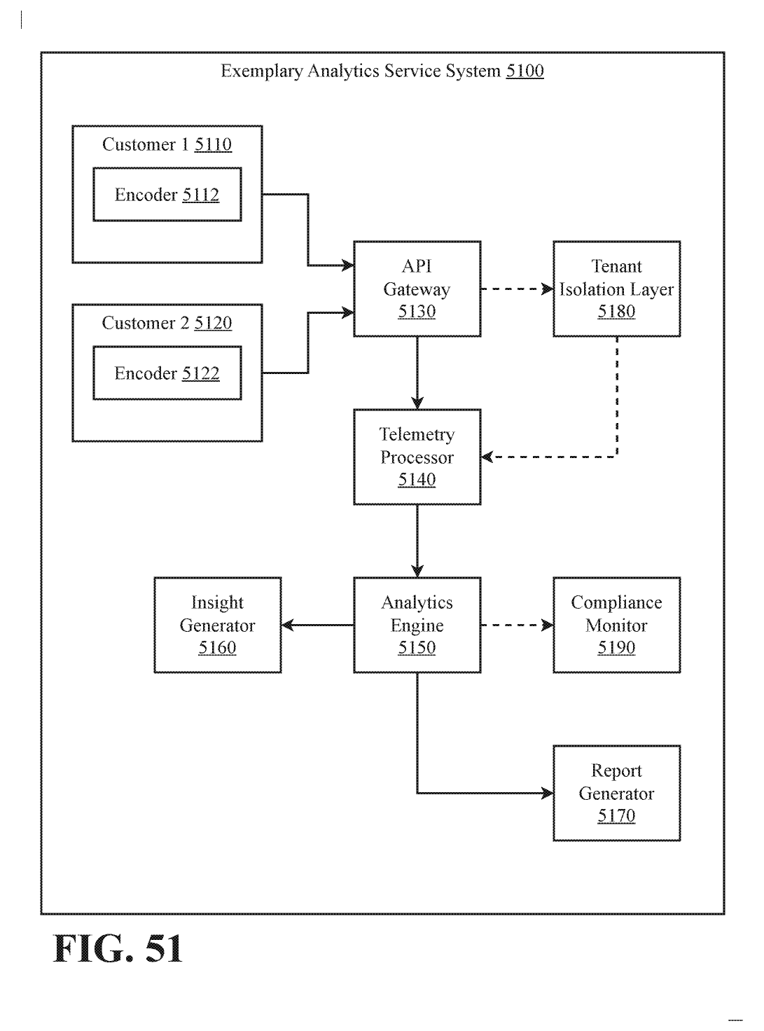

FIG. 51 is a block diagram illustrating an exemplary analytics service system 5100 aspect of a compaction telemetry system configured to offer compaction-derived telemetry as a managed analytics service. Analytics service system 5100 enables customers to obtain operational and security insights derived from compaction behavior without granting service providers access to underlying data, wherein this model enables monetization of analytics while preserving customer data sovereignty. In such embodiments, compaction telemetry vectors or derived analytic results are exposed through application programming interfaces (APIs) that provide access to telemetry streams, anomaly indicators, trend summaries, or control recommendations, wherein APIs may be secured, rate-limited, and permissioned according to deployment requirements. Analytics service system 5100 implements multi-tenant isolation wherein compaction telemetry vectors associated with different tenants are logically isolated, wherein aggregation or comparative analysis across tenants may be performed only on anonymized or normalized telemetry representations that prevent inference of tenant-specific data characteristics. Because compaction telemetry does not include personal data or reconstructive representations, analytics service system 5100 facilitates compliance with data protection regulations such as General Data Protection Regulation and California Consumer Privacy Act, wherein telemetry-based analytics may be performed on regulated data without triggering obligations associated with data inspection or processing.

Customer 15110 represents an arbitrary first customer or tenant utilizing analytics service system 5100 to obtain operational and security insights from compaction telemetry generated during anonymized data processing operations. Customer 1 5110 operates encoder 5112 to perform local compaction operations on customer-controlled data, wherein encoder 5112 generates compaction telemetry that is transmitted to analytics service system 5100 for analysis without exposing underlying data content. Customer 1 5110 interacts with analytics service system 5100 through API gateway 5130 to submit telemetry, retrieve analytic results, configure analysis parameters, and access generated reports. In multi-tenant deployments, telemetry and analytic results associated with customer 15110 are logically isolated from other tenants through tenant isolation layer 5180, thereby maintaining contractual and regulatory separation while enabling shared infrastructure for analytics processing. Customer 1 5110 benefits from sophisticated analytic capabilities including anomaly detection, security monitoring, and performance optimization without requiring investment in dedicated analytics infrastructure or granting service providers access to sensitive underlying data.

Encoder 5112 represents a compaction encoding component operated by customer 15110 configured to perform anonymized data compaction operations on customer-controlled data and generate compaction telemetry for submission to analytics service system 5100. Encoder 5112 processes incoming data units using codebooks to perform live encoding and decoding operations, wherein as data units are processed, operational metrics associated with encoding and decoding behavior are observed and recorded. During operation, encoder 5112 generates telemetry including frequency of successful codeword matches, frequency and distribution of mismatches, rate of invocation of hybrid or fallback encoding mechanisms, encoding latency or throughput measurements, residual data sizes following encoding, and effectiveness of selected sourceblock lengths during live operation. Compaction telemetry generated by encoder 5112 is derived from behavior and performance of compaction mechanisms themselves and does not include, require, or imply access to underlying plaintext data, sourceblocks, or deanonymized representations thereof. Encoder 5112 transmits compaction telemetry vectors to API gateway 5130 for processing by telemetry processor 5140, wherein transmission occurs over secure channels and may be subject to authentication, authorization, and encryption to protect telemetry in transit. Encoder 5112 may receive control recommendations or adaptive parameter adjustments from analytics service system 5100 through API gateway 5130 to optimize encoding behavior based on analytic insights derived from telemetry analysis.

Customer 25120 represents an arbitrary second customer or tenant utilizing analytics service system 5100 independently from customer 15110. Customer 2 5120 operates encoder 5122 to generate compaction telemetry from local encoding operations, wherein tenant isolation layer 5180 ensures that telemetry and analytic results associated with customer 25120 remain logically isolated from customer 15110 and all other tenants. Multi-tenant isolation enables analytics service system 5100 to provide analytics-as-a-service to multiple customers using shared infrastructure while maintaining strict separation to prevent cross-tenant information leakage or unauthorized access to customer-specific telemetry or insights. Customer 2 5120 receives customized analytic results, reports, and recommendations specific to telemetry generated by encoder 5122 without exposure to telemetry or insights associated with other customers.

Encoder 5122 represents a compaction encoding component operated by customer 25120 configured to perform anonymized data compaction operations and generate compaction telemetry for submission to analytics service system 5100. Encoder 5122 operates independently from encoder 5112 and may process different types of data, employ different codebook strategies, or operate under different performance characteristics while utilizing shared analytics infrastructure provided by analytics service system 5100. Encoder 5122 transmits compaction telemetry vectors to API gateway 5130 using customer 25120 credentials and tenant identifiers that enable tenant isolation layer 5180 to properly segregate telemetry and ensure that analytic results are delivered only to authorized customer 25120 representatives.

API gateway 5130 represents a service interface component configured to expose compaction telemetry vectors and derived analytic results through application programming interfaces that provide programmatic access to analytics service system 5100 capabilities. API gateway 5130 receives telemetry submissions from encoder 5112 and encoder 5122, authenticates and authorizes requests based on customer credentials and permissions, and routes telemetry to telemetry processor 5140 for processing. APIs provided by API gateway 5130 may include endpoints for telemetry submission, query interfaces for retrieving analytic results, configuration interfaces for adjusting analysis parameters, and notification interfaces for receiving alerts or recommendations. API gateway 5130 implements security controls including authentication mechanisms to verify customer identity, authorization policies to enforce access controls based on tenant permissions, rate limiting to prevent abuse or denial of service attacks, and encryption to protect data in transit. In some embodiments, API gateway 5130 maintains API versioning to enable backward compatibility as analytics capabilities evolve, provides documentation and developer resources to facilitate integration, and implements monitoring to track API usage patterns and performance metrics. API gateway 5130 coordinates with tenant isolation layer 5180 to ensure that API requests are properly segregated by tenant and that responses contain only information authorized for the requesting customer.

Telemetry processor 5140 represents a component configured to receive compaction telemetry vectors from API gateway 5130 and perform preprocessing, normalization, validation, and aggregation operations to prepare telemetry for analysis by analytics engine 5150. Telemetry processor 5140 validates incoming telemetry vectors to ensure conformance with expected formats, data types, and value ranges, wherein invalid or malformed telemetry may be rejected or flagged for manual review. Telemetry processor 5140 may normalize telemetry values to enable meaningful comparison across customers with different operational characteristics, scale factors, or deployment configurations, wherein normalization may include scaling, smoothing, binning, or dimensionality reduction provided that transformations do not introduce dependencies on underlying plaintext data. In some embodiments, telemetry processor 5140 aggregates telemetry vectors over time intervals or operational phases to form temporal representations suitable for trend analysis and change detection. Telemetry processor 5140 associates telemetry with appropriate tenant identifiers to enable tenant isolation layer 5180 to maintain logical separation of telemetry across customers. Processed telemetry is provided to analytics engine 5150 for interpretation and analysis to generate operational and security insights.

Analytics engine 5150 represents a component configured to interpret processed compaction telemetry from telemetry processor 5140 to infer operational, behavioral, and security-relevant conditions associated with anonymized data processing without reconstructing or accessing underlying data content. Analytics engine 5150 establishes baseline compaction profiles representing expected ranges or distributions of compaction telemetry vectors under normal or previously observed conditions for each customer or tenant, wherein baselines may be static, periodically refreshed, or continuously updated to reflect evolving system behavior. Analytics engine 5150 compares observed telemetry vectors against corresponding baseline profiles to detect deviations including absolute differences, proportional differences, or statistically significant departures from expected values, wherein deviation detection may be performed using threshold-based methods, statistical hypothesis testing, machine learning models, or combinations thereof. In some embodiments, analytics engine 5150 performs temporal analysis including computation of first-order derivatives representing rates of change in telemetry values, second-order derivatives representing acceleration or deceleration of change, or higher-order temporal features to detect gradual drift, sudden transitions, or oscillatory behavior. Analytics engine 5150 detects security-relevant conditions such as encryption anomalies, steganographic patterns, or suspected data exfiltration based on characteristic telemetry signatures, wherein detection is performed without decrypting or inspecting payload data and does not require access to cryptographic keys. Analysis results generated by analytics engine 5150 are provided to insight generator 5160 for synthesis into actionable recommendations and to report generator 5170 for incorporation into customer-facing reports.

Insight generator 5160 represents a component configured to synthesize analysis results from analytics engine 5150 into actionable insights, recommendations, and control suggestions that customers can apply to optimize compaction performance, enhance security posture, or address detected anomalies. Insight generator 5160 translates technical telemetry analysis results into business-relevant insights that non-technical stakeholders can understand and act upon, wherein insights may include identification of performance degradation causes, recommendations for codebook optimization, alerts regarding potential security threats, or suggestions for adaptive parameter adjustments. In some embodiments, insight generator 5160 prioritizes insights based on severity, confidence levels, and potential business impact to enable customers to focus on most critical issues requiring immediate attention. Insight generator 5160 may generate control recommendations specifying adaptive modifications to encoding behavior including dynamic adjustment of selected sourceblock lengths, choice of codebooks or encoding strategies, frequency of codebook updates, or sampling rates for telemetry generation. Generated insights are provided to report generator 5170 for inclusion in customer reports and may be exposed through API gateway 5130 for programmatic consumption by customer applications or automation systems. Insights generated by insight generator 5160 maintain tenant isolation through coordination with tenant isolation layer 5180 to ensure that insights are based solely on telemetry from authorized customers and do not inadvertently leak information across tenant boundaries.

Report generator 5170 represents a component configured to generate comprehensive reports consolidating analysis results from analytics engine 5150 and actionable insights from insight generator 5160 into customer-facing documents suitable for executive review, compliance documentation, or technical analysis. Report generator 5170 produces reports in various formats including portable document format files, hypertext markup language dashboards, comma-separated value data exports, or application programming interface responses depending on customer preferences and intended use cases. Reports generated by report generator 5170 may include executive summaries highlighting key findings and recommendations, detailed technical analyses of telemetry patterns and anomalies, trend visualizations showing temporal evolution of compaction behavior, security assessments identifying potential threats or vulnerabilities, and compliance attestations documenting adherence to regulatory requirements. In some embodiments, report generator 5170 supports customizable reporting templates enabling customers to configure report content, format, and delivery schedules according to organizational requirements. Report generator 5170 coordinates with tenant isolation layer 5180 to ensure that generated reports contain only information authorized for specific customers and are delivered through secure channels to prevent unauthorized access or disclosure. Reports may be delivered through API gateway 5130 for programmatic retrieval, transmitted via secure email, or made available through secure web portals depending on customer preferences and security requirements.

Tenant isolation layer 5180 represents a component configured to maintain logical isolation of compaction telemetry vectors, analysis results, insights, and reports associated with different customers or tenants throughout analytics service system 5100. Tenant isolation layer 5180 implements access controls ensuring that telemetry submitted by customer 15110 through encoder 5112 is segregated from telemetry submitted by customer 25120 through encoder 5122 and all other tenants. Tenant isolation layer 5180 enforces tenant-specific permissions throughout processing pipeline including telemetry processor 5140, analytics engine 5150, insight generator 5160, and report generator 5170 to prevent cross-tenant information leakage. In some embodiments, tenant isolation layer 5180 enables aggregation or comparative analysis across tenants performed only on anonymized or normalized telemetry representations that prevent inference of tenant-specific data characteristics, wherein such cross-tenant analysis may be used to establish population-level baselines or detect coordinated threats affecting multiple tenants while maintaining strict separation of customer-specific details. Tenant isolation layer 5180 maintains audit logs documenting all access to tenant-specific telemetry and analytic results to enable compliance verification and incident investigation. Such isolation enables analytics-as-a-service offerings while maintaining contractual and regulatory separation between tenants, thereby facilitating compliance with data protection regulations that mandate tenant data segregation in shared infrastructure environments.

Compliance monitor 5190 represents a component configured to verify and document adherence of analytics service system 5100 to data protection regulations such as General Data Protection Regulation and California Consumer Privacy Act. Compliance monitor 5190 verifies that compaction telemetry does not include personal data or reconstructive representations, thereby enabling telemetry-based analytics to be performed on regulated data without triggering obligations associated with data inspection or processing. In some embodiments, compliance monitor 5190 performs automated scans of telemetry vectors to detect potential inclusion of personally identifiable information, sensitive personal data, or reconstructive content that could enable inference of underlying data values, wherein detection of non-compliant content triggers alerts and remediation workflows. Compliance monitor 5190 generates compliance attestations documenting that analytics operations operate exclusively on anonymized telemetry vectors and derived representations without requiring reconstruction, inspection, or inference of underlying plaintext data or sourceblocks. Such attestations may be provided to customers for inclusion in regulatory filings, audit responses, or privacy impact assessments demonstrating compliance with applicable data protection requirements. Compliance monitor 5190 coordinates with tenant isolation layer 5180 to verify proper segregation of tenant data and with API gateway 5130 to ensure appropriate security controls are enforced for API access. In some embodiments, compliance monitor 5190 maintains records of data processing activities, consent management for analytics operations, and documentation of technical and organizational measures implemented to protect customer telemetry throughout analytics service system 5100 processing pipeline.

Collectively, components of analytics service system 5100 enable delivery of compaction telemetry analytics as a managed service while preserving customer data sovereignty, maintaining strict tenant isolation, and ensuring regulatory compliance. Through secure API interfaces provided by API gateway 5130, processing of telemetry by telemetry processor 5140, analysis by analytics engine 5150, synthesis of insights by insight generator 5160, generation of reports by report generator 5170, isolation enforcement by tenant isolation layer 5180, and compliance verification by compliance monitor 5190, analytics service system 5100 enables customers to obtain operational and security insights without requiring dedicated analytics infrastructure or granting service providers access to sensitive underlying data. This service model transforms anonymized data compaction from an encoding technology into a platform for privacy-preserving analytics that generates business value while maintaining regulatory compliance and customer trust.

### Exemplary Computing Environment

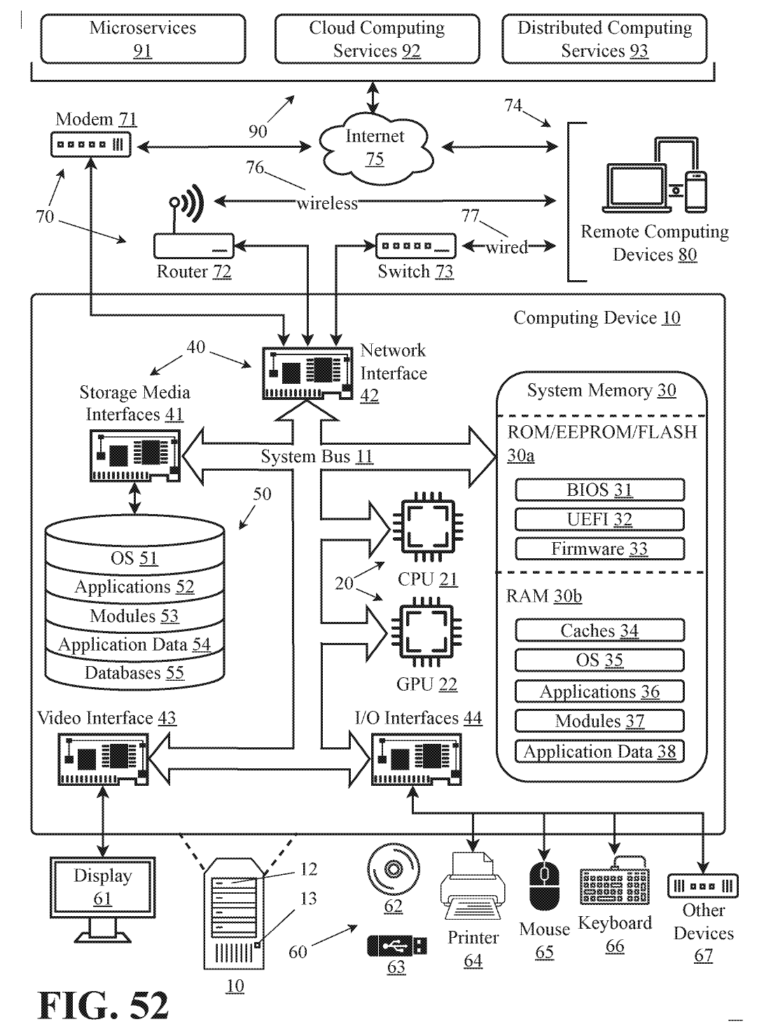

FIG. 52 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 13 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A computer system configured to execute software instructions stored on nontransitory machine-readable storage media, wherein the software instructions comprise instructions that cause the computer system to:
receive one or more sourcepackets for encoding;
encode the one or more sourcepackets using a codebook;
for each sourcepacket encoded:
generate compaction telemetry during the encoding, the compaction telemetry comprising one or more metrics selected from a group consisting of: compaction ratio, sourceblock length used, encoding time, codebook identifier, and compaction failure count; and
construct a compaction telemetry vector comprising the generated compaction telemetry associated with a timestamp, wherein the compaction telemetry vector does not include reconstructive information about underlying data content; and
store or transmit the compaction telemetry vector or vectors for analysis.

2. The computer system of claim 1, further comprising software instructions that cause the computer system to perform telemetry analysis by analyzing the compaction telemetry vector or vectors to detect anomalies in compaction behavior.

3. The computer system of claim 2, further comprising software instructions that cause the computer system to:
identify conditions from the telemetry analysis requiring an automated response;
compare the identified conditions against trigger conditions defined by a policy engine;
initiate control actions when trigger conditions are met, the control actions including one or more of: adjusting sourceblock lengths, modifying codebook selection, changing encoding parameters, and generating security alerts;
modify encoding parameters based on executed control actions; and
observe subsequent compaction telemetry using a feedback monitor to assess effectiveness of the control actions, wherein the feedback monitor confirms resolution of detected conditions or escalates responses if anomalies persist.

4. The computer system of claim 3, wherein the control actions include automated security responses selected from a group consisting of: rate limiting data flows associated with an endpoint exhibiting anomalous compaction behavior, isolating affected endpoints, enforcing stricter encoding policies, and dynamic key rotation.

5. The computer system of claim 4, wherein the parameter adjustment subsystem adaptively modifies encoding behavior by dynamically adjusting one or more of: selected sourceblock lengths, choice of codebooks, frequency of codebook updates, and sampling rates for telemetry generation.

6. The computer system of claim 2, further comprising software instructions that cause the computer system to:
establish a baseline compaction profile representing expected compaction behavior from the telemetry analysis; and
detect deviations from the baseline compaction profile by comparing observed compaction telemetry vectors against the baseline compaction profile.

7. The computer system of claim 6, further comprising software instructions that cause the computer system to perform threat classification by:
classifying detected deviations from the baseline compaction profile as security-relevant conditions using a threat classifier; and
generating an alert using an alert generator when a security-relevant condition is classified, wherein the security-relevant condition is detected without reconstructing or inspecting underlying data content.

8. The computer system of claim 7, wherein the security-relevant conditions include detection of encrypted data based on sustained increases in compaction failure count, wherein encrypted data exhibits high entropy and fails to compact at normal rates.

9. The computer system of claim 8, wherein the security-relevant conditions include detection of steganography or covert channels based on identification of repeated anomalous compaction patterns aligned with message boundaries.

10. The computer system of claim 9, wherein the security-relevant conditions include detection of data exfiltration based on sudden increases in compaction failure localized to specific endpoints or sustained telemetry anomalies consistent with outbound-only data flow.

11. A computer-implemented method comprising the steps of:
receiving one or more sourcepackets for encoding;
encoding the one or more sourcepackets using a codebook;
for each sourcepacket encoded:
generating compaction telemetry during the encoding, the compaction telemetry comprising one or more metrics selected from a group consisting of: compaction ratio, sourceblock length used, encoding time, codebook identifier, and compaction failure count; and
constructing a compaction telemetry vector comprising the generated compaction telemetry associated with a timestamp, wherein the compaction telemetry vector does not include reconstructive information about underlying data content; and
storing or transmitting the compaction telemetry vector or vectors for analysis.

12. The method of claim 11, further comprising the step of performing telemetry analysis by analyzing the compaction telemetry vector or vectors to detect anomalies in compaction behavior.

13. The method of claim 12, further comprising the steps of:
identifying conditions from the telemetry analysis requiring an automated response;
comparing the identified conditions against trigger conditions defined by a policy engine;
initiating control actions when trigger conditions are met, the control actions including one or more of: adjusting sourceblock lengths, modifying codebook selection, changing encoding parameters, and generating security alerts;
modifying encoding parameters based on executed control actions; and
observing subsequent compaction telemetry using a feedback monitor to assess effectiveness of the control actions, wherein the feedback monitor confirms resolution of detected conditions or escalates responses if anomalies persist.

14. The method of claim 13, wherein the control actions include automated security responses selected from a group consisting of: rate limiting data flows associated with an endpoint exhibiting anomalous compaction behavior, isolating affected endpoints, enforcing stricter encoding policies, and dynamic key rotation.

15. The method of claim 14, wherein the parameter adjustment subsystem adaptively modifies encoding behavior by dynamically adjusting one or more of: selected sourceblock lengths, choice of codebooks, frequency of codebook updates, and sampling rates for telemetry generation.

16. The method of claim 12, further comprising the steps of:
establishing a baseline compaction profile representing expected compaction behavior from the telemetry analysis; and
detecting deviations from the baseline compaction profile by comparing observed compaction telemetry vectors against the baseline compaction profile.

17. The method of claim 16, further comprising the step of performing threat classification by:
classifying detected deviations from the baseline compaction profile as security-relevant conditions using a threat classifier; and
generating an alert using an alert generator when a security-relevant condition is classified, wherein the security-relevant condition is detected without reconstructing or inspecting underlying data content.

18. The method of claim 17, wherein the security-relevant conditions include detection of encrypted data based on sustained increases in compaction failure count, wherein encrypted data exhibits high entropy and fails to compact at normal rates.

19. The method of claim 18, wherein the security-relevant conditions include detection of steganography or covert channels based on identification of repeated anomalous compaction patterns aligned with message boundaries.

20. The method of claim 19, wherein the security-relevant conditions include detection of data exfiltration based on sudden increases in compaction failure localized to specific endpoints or sustained telemetry anomalies consistent with outbound-only data flow.
